(19) United States
(12) Patent Application Publication
(10) Pub. No.: US 2025/0031402 A1
(43) Pub. Date: Jan. 23, 2025

(54) HYBRID TYPE AlGaN/GaN HEMT DEVICE

(71) Applicant: CHIH-SHU HUANG, Taipei City (TW)

(72) Inventor: CHIH-SHU HUANG, Taipei City (TW)

(21) Appl. No.: 18/774,429

(22) Filed: Jul. 16, 2024

(30) Foreign Application Priority Data
Jul. 19, 2023 (TW) 112126909

(51) Int. Cl. H01L 29/778; H01L 27/06; H01L 29/20

(52) U.S. Cl. CPC H01L 29/7786; H01L 27/0629; H01L 29/2003

(57) ABSTRACT

The present invention relates to a structure of hybrid type AlGaN/GaN high electron mobility transistor (HEMT) Device, which comprises a silicon substrate structure, and both of a depletion-mode (D-mode) AlGaN/GaN HEMT and a p-GaN gate enhancement-mode (E-mode) AlGaN/GaN HEMT disposed on the silicon substrate structure. By connecting the depletion-mode (D-mode) AlGaN/GaN HEMT to the p-GaN gate structure of the p-GaN gate enhancement-mode (E-mode) AlGaN/GaN HEMT in device design, the p-GaN gate E-mode AlGaN/GaN HEMT may be protected under any gate voltage.

### FIELD OF THE INVENTION

The application related to a transistor device, in particular to a hybrid type AlGaN/GaN HEMT device, which is to form a protection element by its own structure, for operating a p-GaN gate E-mode AlGaN/GaN HEMT under any gate voltage and under protection, and the protection delay may be avoided.

### BACKGROUND OF THE INVENTION

According to the prior art, the most common method to fabricate an enhancement-mode (E-mode) AlGaN/GaN high electron mobility transistor (HEMT) using an epitaxy structure is: 1. Ga-face p-GaN gate E-mode HEMT structure; and 2. N-face Al(x)GaN gate E-mode HEMT structure. As indicated by the nomenclature, only the gate region will exists p-GaN or Al(x)GaN.

The most common type of E-mode HEMT is the p-GaN gate E-mode HEMT. Theepitaxy structure is based on the conventional depletion-mode (D-Mode) with an additional p-GaN layer above the top AlGaN barrier layer. The first step of the fabrication is dry etching the p-GaN layer outside the defined gate region and maintaining the completeness of the thickness of the AlGaN layer below as much as possible. If the AlGaN layer below is etched excessively, the two-dimensional electron gas (2DEG) at the AlGaN/GaN interface of the Ga-face p-GaN gate E-mode HEMT structure cannot be formed. Dry etching is extremely difficult because of: 1. Difficulty in controlling the etching depth; and 2. The thickness of eAlGaN layer on a wafer is nonuniform.

Accordingly, to solve the above problems, the present invention provides a hybrid type AlGaN/GaN HEMT device such that under any gate voltages, the p-GaN gate E-mode AlGaN/GaN HEMT may be protected and the protection delay may be avoided.

### SUMMARY OF THE INVENTION

A major objective of the present invention is to provide a novel hybrid type AlGaN/GaN HEMT device for protecting the p-GaN gate E-mode AlGaN/GaN HEMT at any gate bias. In addition, multiple types of high-voltage high-speed active devices may be formed simultaneously on the Ga-face Group III/Nitride epitaxy structure of the present invention.

To achieve the above objective, the present invention provides a hybrid type AlGaN/GaN HEMT device, which comprises a first D-mode AlGaN/GaN HEMT coupled to a p-GaN gate E-mode AlGaN/GaN HEMT. The p-GaN gate E-mode AlGaN/GaN HEMT is disposed on one side of the first D-mode AlGaN/GaN HEMT. In particular, a gate of the D-mode AlGaN/GaN HEMT is coupled to a source of the p-GaN gate E-mode AlGaN/GaN HEMT. According to the present invention, all of the AlGaN/GaN HEMTs described above are further disposed on a silicon substrate structure.

According to an embodiment of the present invention, the p-GaN gate structure is a p-GaN inverted-trapezoidal gate structure or a p-GaN etched gate structure.

According to an embodiment of the present invention, the silicon substrate structure includes a silicon substrate, a C-doped buffer layer, and a C-doped intrinsic GaN layer. The C-doped buffer layer is disposed on the silicon substrate; and the C-doped intrinsic GaN layer is disposed on the C-doped buffer layer.

According to an embodiment of the present invention, the first D-mode AlGaN/GaN HEMT includes an i-Al_{y}GaN buffer layer, an intrinsic GaN channel layer, and an i-Al_{y}GaN blocking layer. The i-Al_{y}GaN buffer layer is disposed on the C-doped intrinsic GaN layer. The intrinsic GaN channel layer is disposed on the i-Al_{y}GaN buffer layer. The 2DEG is formed in the intrinsic GaN channel layer. The i-AlₓGaN blocking layer is disposed on the intrinsic GaN channel layer, where x=0.1-0.3 and y=0.05-0.75.

According to an embodiment of the present invention, the p-GaN gate E-mode AlGaN/GaN HEMT further includes an i-Al_{y}GaN buffer layer, an intrinsic GaN channel layer, and an i-AlₓGaN blocking layer. The i-Al_{y}GaN buffer layer is disposed on the C-doped intrinsic GaN layer. The intrinsic GaN channel layer is disposed on the i-Al_{y}GaN buffer layer. The 2DEG is formed in the intrinsic GaN channel layer. The i-AlₓGaN blocking layer is disposed on the intrinsic GaN channel layer, where x=0.1-0.3 and y=0.05-0.75.

According to an embodiment of the present invention, a gate voltage of the p-GaN gate E-mode AlGaN/GaN HEMT in a voltage rising stage is between a threshold voltage Vth and a cutoff voltage Vgs(off) of the first D-mode AlGaN/GaN HEMT.

According to an embodiment of the present invention, an i-Al_{z}GaN grading buffer layer is further disposed between the C-doped intrinsic GaN layer and the i-Al_{y}GaN buffer layer, where z=0.01-0.75.

According to an embodiment of the present invention, a source of the first D-mode AlGaN/GaN HEMT is coupled to the p-GaN gate structure of the p-GaN gate E-mode AlGaN/GaN HEMT.

According to an embodiment of the present invention, the first D-mode AlGaN/GaN HEMT further includes a gate dielectric layer disposed below the gate of the first D-mode AlGaN/GaN HEMT.

According to an embodiment of the present invention, the first D-mode AlGaN/GaN HEMT further includes an AlGaN micro-etched structure disposed below the gate of the first D-mode AlGaN/GaN HEMT.

According to an embodiment of the present invention, the hybrid type AlGaN/GaN HEMT device further comprises a discharging device coupled to the source and the drain of the first D-mode AlGaN/GaN HEMT.

According to an embodiment of the present invention, the discharging device is a Schottky barrier diode or a discharging transistor. The gate and the source of the discharging transistor are short-circuited. The source and the drain of the discharging transistor is coupled to the source and the drain of the first D-mode AlGaN/GaN HEMT, respectively.

According to an embodiment of the present invention, the hybrid type AlGaN/GaN HEMT device further comprises a bypass circuit coupled to the drain of the first D-mode AlGaN/GaN HEMT and the source of the p-GaN gate E-mode AlGaN/GaN HEMT.

According to an embodiment of the present invention, the bypass circuit includes a plurality of first bypass diodes and a second bypass diode coupled in parallel and in opposite polarity. The plurality of first bypass diodes are coupled in series.

According to an embodiment of the present invention, the bypass circuit includes a plurality of first bypass units and a second bypass unit coupled in parallel and in opposite polarity. The plurality of first bypass units are coupled in series. The plurality of first bypass units include a first bypass diode and a first bypass transistor, respectively. The plurality of second bypass units include a second bypass diode and a second bypass transistor. The first bypass diode and the second bypass diode are in opposite polarity.

According to an embodiment of the present invention, the hybrid type AlGaN/GaN HEMT device further comprises a second D-mode AlGaN/GaN HEMT disposed in a third region of the Ga-face AlGaN/GaN epitaxy structure. The second D-mode AlGaN/GaN HEMT is coupled to the p-GaN gate E-mode AlGaN/GaN HEMT and forming a cascode circuit.

According to an embodiment of the present invention, the second D-mode AlGaN/GaN HEMT includes an i-Al_{y}GaN buffer layer, an intrinsic GaN channel layer, and an i-AlₓGaN blocking layer. The i-Al_{y}GaN buffer layer is disposed on the C-doped intrinsic GaN layer. The intrinsic GaN channel layer is disposed on the i-Al_{y}GaN buffer layer. The 2DEG is formed in the intrinsic GaN channel layer. The i-AlₓGaN blocking layer is disposed on the intrinsic GaN channel layer, where x=0.1-0.3 and y=0.05-0.75.

According to an embodiment of the present invention, a gate of the second D-mode AlGaN/GaN HEMT further includes a gate dielectric layer there below.

### BRIEF DESCRIPTION OF DRAWINGS

FIG. 1 shows a schematic diagram of the distribution of ESP and EPZ for Ga-face and N-face under different epitaxy stress (AlGaN/GaN and GaN/InGaN systems);

FIG. 2 shows a schematic diagram of Ga-face and N-face GaN grown on a substrate according to the present invention;

FIG. 3 shows a schematic diagram of different locations of the 2DEG formed at the AlGaN/GaN junction owing to different polarities;

FIG. 4A shows an energy band diagram of a p-GaN layer grown on an AlGaN/GaN epitaxy structure;

FIG. 4B to FIG. 4D show the operations of a p-GaN gate E-mode AlGaN/GaN HEMT with a fixed drain voltage Vd and a varying gate voltage Vg;

FIG. 4E shows the voltage and current operating curve of the SBD shown in the equivalent circuit of FIG. 4D;

FIG. 4F and FIG. 4G show equivalent circuits of the source of the first D-mode AlGaN/GaN HEMT connected to the gate of the p-GaN gate E-mode AlGaN/GaN HEMT;

FIG. 4H shows the voltage and current operating curve corresponding to the devices in the equivalent circuits of FIG. 4F and FIG. 4G;

FIG. 5A shows the epitaxy structure of the Ga-face AlGaN/GaN HEMT according to the present invention;

FIG. 5B shows the epitaxy structure of the Ga-face AlGaN/GaN HEMT improved from FIG. 5A according to the present invention;

FIG. 6A and FIG. 6B show cross-sectional views of the first D-mode AlGaN/GaN HEMT without gate dielectric layer as the gate protection device and the SEG p-GaN gate E-mode AlGaN/GaN HEMT;

FIG. 6C and FIG. 6D show cross-sectional views of the first D-mode AlGaN/GaN HEMT without gate dielectric layer and with a gate AlGaN micro-etched structure as the gate protection device and the SEG p-GaN gate E-mode AlGaN/GaN HEMT;

FIG. 7A and FIG. 7B show cross-sectional views of the SEG p-GaN

inverted-trapezoidal gate structure;

FIG. 7C shows cross-sectionals views after completion of the metal layer corresponding to the drain and source Ohmic contacts in FIG. 7A and FIG. 7B;

FIG. 7D shows a cross-sectional view of device isolation by dry etching to the high-resistivity C-doped intrinsic GaN buffer layer;

FIG. 7E shows a cross-sectional view of device isolation by adopting multiple-energy destructive ion implantation from the surface to the high-resistivity C-doped intrinsic GaN buffer layer;

FIG. 7F and FIG. 7G show cross-sectional views of forming the gate metal and the bonding pads or interconnection metals for drain and source corresponding to FIG. 7D and FIG. 7E;

FIG. 7H and FIG. 7I show cross-sectional views of forming and patterning a passivation layer for exposing the drain and source bonding pad regions corresponding to FIG. 7F and FIG. 7G;

FIG. 7J and FIG. 7K show cross-sectional views of the first D-mode AlGaN/GaN HEMT after the gate field-plate metal is fabricated corresponding to FIG. 7H and FIG. 7I;

FIG. 7L shows a top view of the first D-mode AlGaN/GaN HEMT without gate dielectric layer as the gate protection device and the SEG p-GaN gate E-mode AlGaN/GaN HEMT;

FIG. 7M shows a cross-sectional view of fabricating the gate AlGaN micro-etched structure;

FIG. 8A and FIG. 8B show cross-sectional views of the first D-mode AlGaN/GaN HEMT without gate dielectric layer as the gate protection device and the p-GaN etched gate E-mode AlGaN/GaN HEMT;

FIG. 8C and FIG. 8D show cross-sectional views of the first D-mode AlGaN/GaN HEMT without gate dielectric layer and with a gate AlGaN micro-etched structure as the gate protection device and the p-GaN etched gate E-mode AlGaN/GaN HEMT;

FIG. 9A and FIG. 9B show cross-sectional views of fabricating the p-GaN etched gate structure;

FIG. 9C to FIG. 9K show cross-sectional views of fabricating the p-GaN etched gate E-mode AlGaN/GaN HEMT using the first D-mode AlGaN/GaN HEMT without gate dielectric layer as the gate protection device;

FIG. 9L shows a top view of the first D-mode AlGaN/GaN HEMT without gate dielectric layer as the gate protection device and the p-GaN etched gate E-mode AlGaN/GaN HEMT;

FIG. 9M shows a cross-sectional view of fabricating the gate AlGaN micro-etched structure;

FIG. 10A and FIG. 10B show cross-sectional views of the first D-mode AlGaN/GaN HEMT with gate dielectric layer as the gate protection device and the SEG p-GaN gate E-mode AlGaN/GaN HEMT;

FIG. 10C shows a cross-sectional view of the first D-mode AlGaN/GaN HEMT with gate dielectric layer as the gate protection device and the SEG p-GaN gate E-mode AlGaN/GaN HEMT;

FIG. 11A and FIG. 11B show cross-sectional views of the first D-mode AlGaN/GaN HEMT with gate dielectric layer as the gate protection device and the p-GaN etched gate E-mode AlGaN/GaN HEMT;

FIG. 11C shows a cross-sectional views of the first D-mode AlGaN/GaN HEMT with gate dielectric layer as the gate protection device and the p-GaN etched gate E-mode AlGaN/GaN HEMT;

FIG. 12A to FIG. 12D show equivalent circuits of the source of the first D-mode AlGaN/GaN HEMT with discharging device connected to the gate of the p-GaN gate E-mode AlGaN/GaN HEMT;

FIG. 13A and FIG. 13B show equivalent circuits of the source of the first D-mode AlGaN/GaN HEMT with discharging device connected to the gate of the p-GaN gate E-mode AlGaN/GaN HEMT and overall paralleled with a bypass circuit;

FIG. 14A to FIG. 14D show equivalent circuits of the source of the first D-mode AlGaN/GaN HEMT with discharging device connected to the gate of the p-GaN gate E-mode AlGaN/GaN HEMT and overall paralleled with another bypass circuit;

FIG. 15A shows an equivalent circuit of the source of the first D-mode AlGaN/GaN HEMT without gate dielectric layer connecting to a p-GaN gate E-mode AlGaN/GaN HEMT and cascoding to the second D-mode AlGaN/GaN HEMT without gate dielectric layer;

FIG. 15B shows an equivalent circuit of the source of the first D-mode AlGaN/GaN HEMT without gate dielectric layer connecting to a p-GaN gate E-mode AlGaN/GaN HEMT and cascoding to the second D-mode AlGaN/GaN HEMT with gate dielectric layer;

FIG. 15C shows an equivalent circuit of the source of the first D-mode AlGaN/GaN HEMT with gate dielectric layer connecting to a p-GaN gate E-mode AlGaN/GaN HEMT and cascoding to the second D-mode AlGaN/GaN HEMT without gate dielectric layer;

FIG. 15D shows an equivalent circuit of the source of the first D-mode AlGaN/GaN HEMT with gate dielectric layer connecting to a p-GaN gate E-mode AlGaN/GaN HEMT and cascoding to the second D-mode AlGaN/GaN HEMT with gate dielectric layer;

FIG. 16A and FIG. 16B show cross-sectional views of the first D-mode AlGaN/GaN HEMT without gate dielectric layer as the gate protection device and the SEG p-GaN gate E-mode AlGaN/GaN HEMT cascoding to a second D-mode AlGaN/GaN HEMT without gate dielectric layer;

FIG. 16C and FIG. 16D show cross-sectional views of the first D-mode AlGaN/GaN HEMT with gate AlGaN micro-etched structure as the gate protection device and the SEG p-GaN gate E-mode AlGaN/GaN HEMT cascoding to a second D-mode AlGaN/GaN HEMT without gate dielectric layer;

FIG. 17A and FIG. 17B show cross-sectional views of the inverted trapezoidal gate structure for the SEG p-GaN gate;

FIG. 17C shows a cross-sectional view after the drain and source metals corresponding to FIG. 17A and FIG. 17B are fabricated;

FIG. 17D shows a cross-sectional view of adopting multiple-energy destructive ion implantation to the high-resistivity C-doped intrinsic GaN buffer layer for isolating devices;

FIG. 17E shows a cross-sectional view of dry-etching to the high-resistivity C-doped intrinsic GaN buffer layer for isolating devices;

FIG. 17F and FIG. 17G show cross-sectional views of forming the gate metal and the bonding pads or interconnection metals for drain and source corresponding to FIG. 17D and FIG. 17E;

FIG. 17H and FIG. 17I show cross-sectional views of forming and patterning a passivation layer for exposing the drain and source bonding pad regions corresponding to FIG. 17F and FIG. 17G;

FIG. 17J and FIG. 17K show cross-sectional views after the gate field-plate metal is fabricated corresponding to FIG. 17H and FIG. 17I;

FIG. 17L shows a top view corresponding to FIG. 17A and FIG. 17B;

FIG. 18A and FIG. 18B show cross-sectional views of the first D-mode AlGaN/GaN HEMT without gate dielectric layer as the gate protection device and the SEG p-GaN gate E-mode AlGaN/GaN HEMT cascoding to the second D-mode AlGaN/GaN HEMT without gate dielectric layer;

FIG. 18C and FIG. 18D show cross-sectional views of the first D-mode AlGaN/GaN HEMT with gate AlGaN micro-etched structure as the gate protection device and the SEG p-GaN gate E-mode AlGaN/GaN HEMT cascoding to the second D-mode AlGaN/GaN HEMT without gate dielectric layer;

FIG. 19A shows a cross-sectional view of dry-etching to the high-resistivity C-doped intrinsic GaN buffer layer for isolating devices and forming the inverted trapezoidal gate structure for the SEG p-GaN gate and the drain and source metals;

FIG. 19B shows a cross-sectional view of adopting multiple-energy destructive ion implantation to the high-resistivity C-doped intrinsic GaN buffer layer for isolating devices and forming the inverted trapezoidal gate structure for the SEG p-GaN gate and the drain and source metals;

FIG. 19C and FIG. 19D show cross-sectional views of forming the gate metal and the bonding pads or interconnection metals for drain and source corresponding to FIG. 19A and FIG. 19B;

FIG. 19E and FIG. 19F show cross-sectional views of forming and patterning a passivation layer for exposing the drain and source bonding pad regions corresponding to FIG. 19C and FIG. 19D;

FIG. 19G and FIG. 19H show cross-sectional views after the gate field-plate metal is fabricated corresponding to FIG. 19E and FIG. 19F;

FIG. 19I shows a top view corresponding to FIG. 18A and FIG. 18B;

FIG. 20A and FIG. 20B show cross-sectional views of the hybrid type AlGaN/GaN HEMT device formed by the first D-mode AlGaN/GaN HEMT without gate dielectric layer as the gate protection device and the p-GaN etched gate E-mode AlGaN/GaN HEMT cascoding to the second D-mode AlGaN/GaN HEMT without gate dielectric layer;

FIG. 20C and FIG. 20D show cross-sectional views of the hybrid type AlGaN/GaN HEMT device formed by the first D-mode AlGaN/GaN HEMT with gate AlGaN micro-etched structure as the gate protection device and the p-GaN etched gate E-mode AlGaN/GaN HEMT cascoding to the second D-mode AlGaN/GaN HEMT without gate dielectric layer;

FIG. 21A shows a cross-sectional view of the SEG region with photoresist;

FIG. 21B shows a cross-sectional view after the p-GaN etched gate is fabricated in the SEG region;

FIG. 21C shows a cross-sectional view after the drain and source metals corresponding to FIG. 21B are fabricated;

FIG. 21D shows a cross-sectional view of dry-etching to the high-resistivity C-doped intrinsic GaN buffer layer for isolating devices;

FIG. 21E shows a cross-sectional view of adopting multiple-energy destructive ion implantation to the high-resistivity C-doped intrinsic GaN buffer layer for isolating devices;

FIG. 21F and FIG. 21G show cross-sectional views of forming the gate metal and the bonding pads or interconnection metals for drain and source corresponding to FIG. 21D and FIG. 21E;

FIG. 21H and FIG. 21I show cross-sectional views of forming and patterning a passivation layer for exposing the drain and source bonding pad regions corresponding to FIG. 21F and FIG. 21G;

FIG. 21J and FIG. 21K show cross-sectional views after the gate field-plate metal is fabricated corresponding to FIG. 21H and FIG. 21I;

FIG. 21L shows a top view corresponding to FIG. 20A and FIG. 20B;

FIG. 22A and FIG. 22B show cross-sectional views of the first D-mode AlGaN/GaN HEMT without gate dielectric layer as the gate protection device and the p-GaN gate E-mode AlGaN/GaN HEMT cascoding to the second D-mode AlGaN/GaN HEMT with gate dielectric layer;

FIG. 22C and FIG. 22D show cross-sectional views of the first D-mode AlGaN/GaN HEMT with gate AlGaN micro-etched structure and without gate dielectric layer as the gate protection device and the p-GaN etched gate E-mode AlGaN/GaN HEMT cascoding to the second D-mode AlGaN/GaN HEMT with gate dielectric layer;

FIG. 23A shows a cross-sectional view of dry-etching to the high-resistivity C-doped intrinsic GaN buffer layer for isolating devices and forming the inverted trapezoidal gate structure for the SEG p-GaN etched gate structure and the drain and source metals;

FIG. 23B shows a cross-sectional view of adopting multiple-energy destructive ion implantation to the high-resistivity C-doped intrinsic GaN buffer layer for isolating devices and forming the inverted trapezoidal gate structure for the SEG p-GaN etched gate structure and the drain and source metals;

FIG. 23C and FIG. 23D show cross-sectional views of forming the gate metal and the bonding pads or interconnection metals for drain and source corresponding to FIG. 23A and FIG. 23B;

FIG. 23E and FIG. 23F show cross-sectional views of forming and patterning a passivation layer for exposing the drain and source bonding pad regions corresponding to FIG. 23C and FIG. 23D;

FIG. 23G and FIG. 23H show cross-sectional views after the gate field-plate metal is fabricated corresponding to FIG. 23E and FIG. 23F;

FIG. 23I shows a top view corresponding to FIG. 22A and FIG. 22B;

FIG. 24A and FIG. 24B show cross-sectional views of the first D-mode AlGaN/GaN HEMT with gate dielectric layer as the gate protection device and the SEG p-GaN gate E-mode AlGaN/GaN HEMT cascoding to a second D-mode AlGaN/GaN HEMT without gate dielectric layer;

FIG. 24C shows a top view of the first D-mode AlGaN/GaN HEMT with gate dielectric layer as the gate protection device and the SEG p-GaN gate E-mode AlGaN/GaN HEMT cascoding to a second D-mode AlGaN/GaN HEMT without gate dielectric layer;

FIG. 25A and FIG. 25B show cross-sectional views of the first D-mode AlGaN/GaN HEMT with gate dielectric layer as the gate protection device and the SEG p-GaN gate E-mode AlGaN/GaN HEMT cascoding to a second D-mode AlGaN/GaN HEMT with gate dielectric layer;

FIG. 25C shows a top view of the first D-mode AlGaN/GaN HEMT with gate dielectric layer as the gate protection device and the SEG p-GaN gate E-mode AlGaN/GaN HEMT cascoding to a second D-mode AlGaN/GaN HEMT with gate dielectric layer;

FIG. 26A and FIG. 26B show cross-sectional views of the first D-mode AlGaN/GaN HEMT with gate dielectric layer as the gate protection device and the p-GaN etched gate E-mode AlGaN/GaN HEMT cascoding to a second D-mode AlGaN/GaN HEMT without gate dielectric layer;

FIG. 26C shows a top view of the first D-mode AlGaN/GaN HEMT with gate dielectric layer as the gate protection device and the p-GaN etched gate E-mode AlGaN/GaN HEMT cascoding to a second D-mode AlGaN/GaN HEMT without gate dielectric layer;

FIG. 27A and FIG. 27B show cross-sectional views of the first D-mode AlGaN/GaN HEMT with gate dielectric layer as the gate protection device and the p-GaN etched gate E-mode AlGaN/GaN HEMT cascoding to a second D-mode AlGaN/GaN HEMT with gate dielectric layer;

FIG. 27C shows a top view of the first D-mode AlGaN/GaN HEMT with gate dielectric layer as the gate protection device and the p-GaN etched gate E-mode AlGaN/GaN HEMT cascoding to a second D-mode AlGaN/GaN HEMT with gate dielectric layer;

FIG. 28A to FIG. 28D show equivalent circuits of the discharging device connected to the first D-mode AlGaN/GaN HEMT with and without gate dielectric layer, respectively, and the source of the first D-mode AlGaN/GaN HEMT connected to the gate of the p-GaN gate E-mode AlGaN/GaN HEMT cascoding to a second D-mode AlGaN/GaN HEMT with gate dielectric layer;

FIG. 29A and FIG. 29B show equivalent circuits of the discharging device connected to the first D-mode AlGaN/GaN HEMT with and without gate dielectric layer, respectively, and the source of the first D-mode AlGaN/GaN HEMT connected to the gate of the p-GaN gate E-mode AlGaN/GaN HEMT cascoding to a second D-mode AlGaN/GaN HEMT with gate dielectric layer and overall paralleled with a bypass circuit; and

FIG. 30A to FIG. 30D show equivalent circuits of the discharging device connected to the first D-mode AlGaN/GaN HEMT with and without gate dielectric layer, respectively, and the source of the first D-mode AlGaN/GaN HEMT connected to the gate of the p-GaN gate E-mode AlGaN/GaN HEMT cascoding to a second D-mode AlGaN/GaN HEMT with gate dielectric layer and overall paralleled with another bypass circuit.

### DETAILED DESCRIPTION OF THE INVENTION

In order to make the structure and characteristics as well as the effectiveness of the present invention to be further understood and recognized, the detailed description of the present invention is provided as follows along with embodiments and accompanying figures.

In the specifications and subsequent claims, certain words are used for representing specific devices. A person having ordinary skill in the art should know that hardware manufacturers might use different nouns to call the same device. In the specifications and subsequent claims, the differences in names are not used for distinguishing devices. Instead, the differences in functions are the guidelines for distinguishing. In the whole specifications and subsequent claims, the word “comprising” is an open language and should be explained as “comprising but not limited to”. Besides, the word “couple” includes any direct and indirect electrical connection. Thereby, if the description is that a first device is coupled to a second device, it means that the first device is connected electrically to the second device directly, or the first device is connected electrically to the second device via other device or connecting means indirectly.

FIG. 1 shows distributions of EPS and EPZ in Ga-face and N-face AlGaN/GaN and GaN/InGaN systems in different stains according to the present invention, where EPS is the spontaneous polarization (the polarization of the material) while EPZ is the piezoelectric polarization (the polarization formed by the piezoelectric effect of strain). Thereby, EPS is determined by the epitaxy layers while EPZ is determined by the piezoelectric effect of strain.

In the AlGaN/GaN system, the value of EPZ is negative when AlGaN is under tensile strain and is positive when AlGaN is under compressive strain. Contrarily, in the GaN/InGaN system, the signs for the values of EPZ are opposite. In addition, according to Reference [2], it is known that, firstly, in the AlGaN/GaN system, the polarization is determined by ESP, and secondly, in the GaN/InGaN system, the polarization is determined by EPZ.

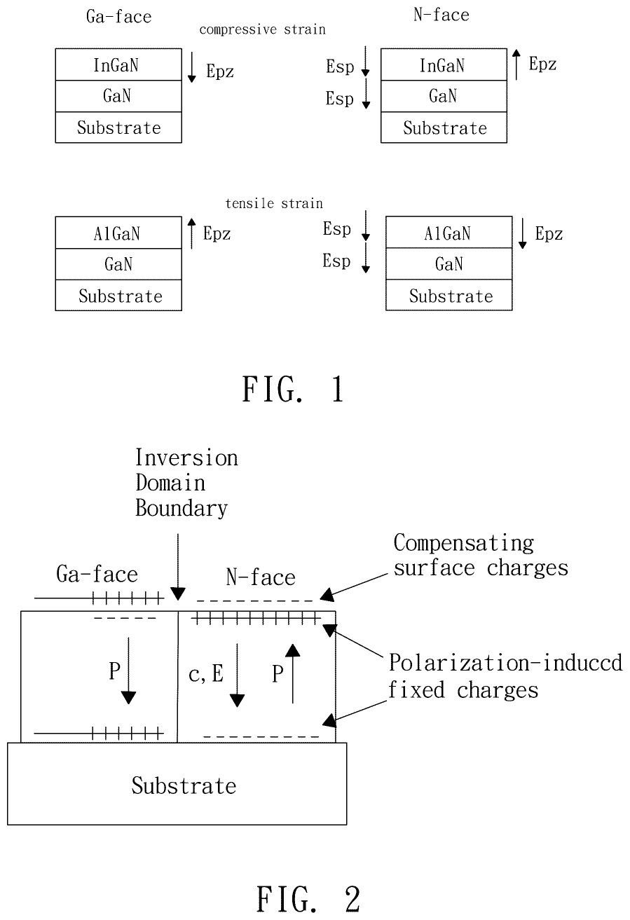

As shown in FIG. 2, P is spontaneous polarization and E is the corresponding electric field. In GaN, the Ga-face/N-face polarization is determined when the Ga atom (N atom) layer of the Ga-N dual-layer faces the surface of epitaxy. As shown in the figure, a schematic diagram of Ga-face/N-face GaN grown on a substrate is illustrated. If it is Ga-face polarization, the internal electric field is away from the substrate and pointing to the surface. Thereby, the polarization is opposite to the direction of the internal electric field. Consequently, the polarization will cause negative charges to accumulate on the surface of lattice and positive charges to accumulate at the junction with the substrate. On the contrary, if it is N-face polarization, the locations of charge accumulation are swapped and the direction of internal electric field is opposite.

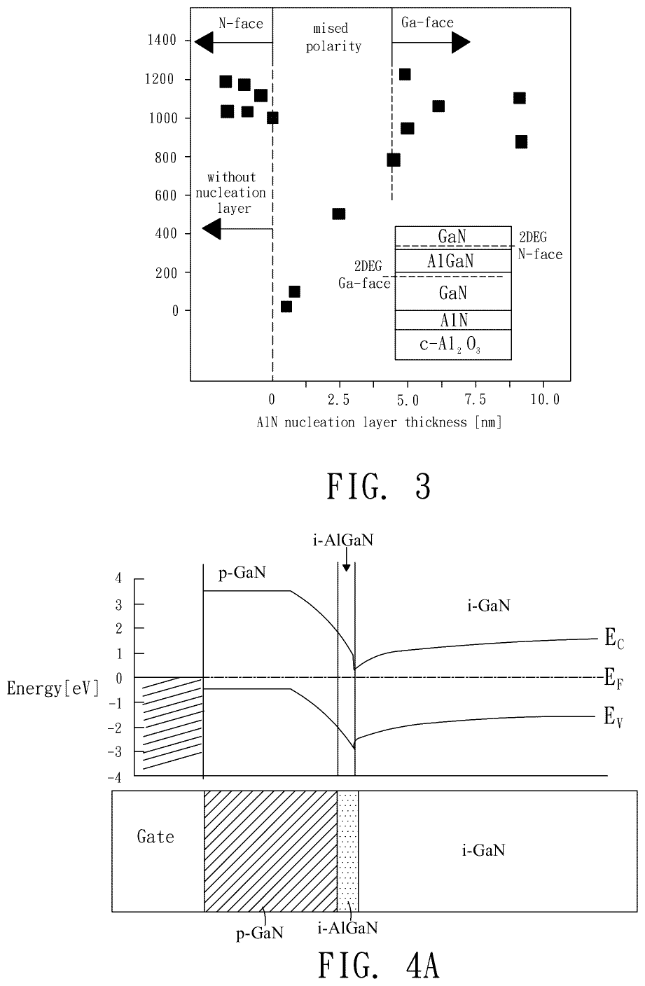

For an AlGaN/GaN HEMT, the most important thing is how the Ga- and N-face polarization influence the device characteristics. FIG. 3 shows a schematic diagram of the different locations of 2DEG generated at the junctions between AlGaN and GaN due to different polarization. In the Ga-face structure, 2DEG exists at the AlGaN/GaN interface while in the N-face structure, 2DEG exists at the GaN/AlGaN interface. The existence of 2DEG indicates accumulation of positive polarization charges at the interface and the 2DEG itself is just the accumulation of free electrons for compensating the polarization charges.

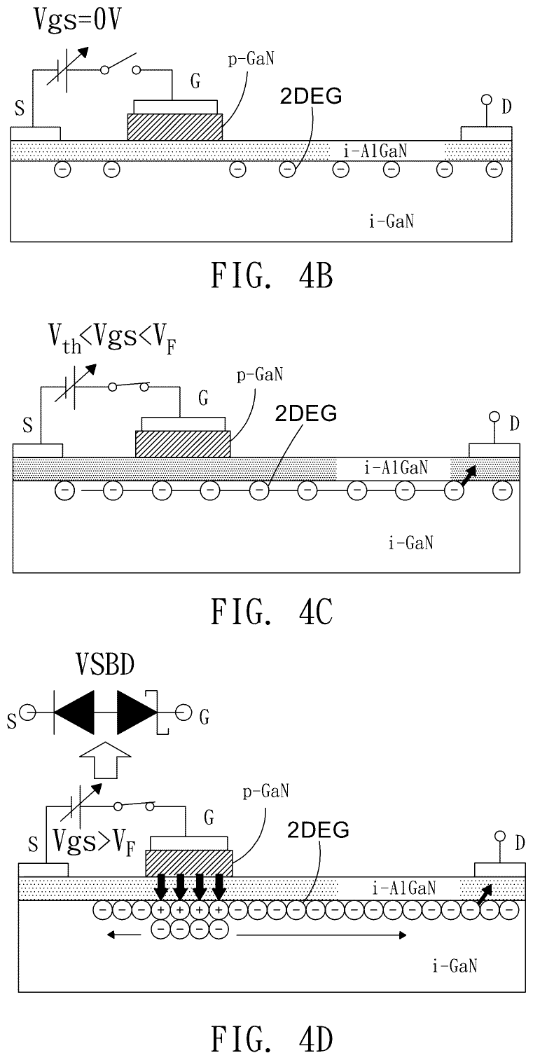

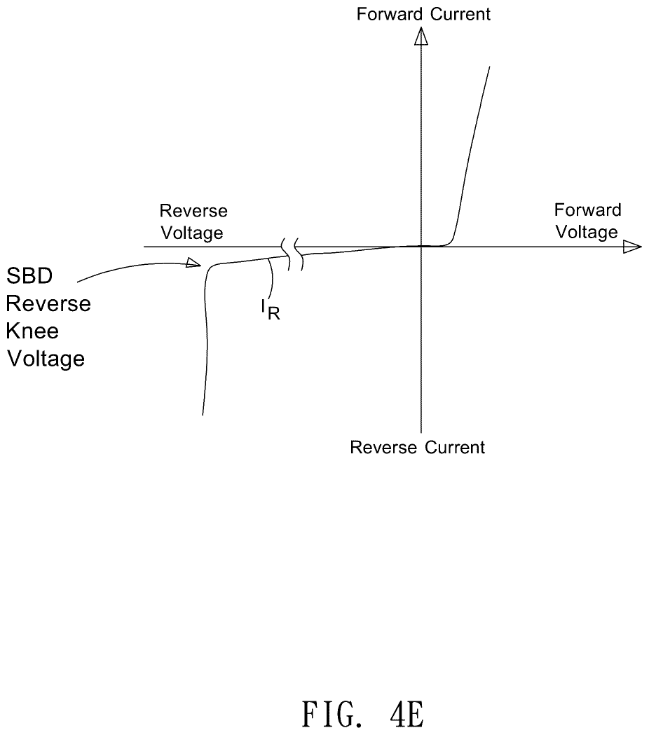

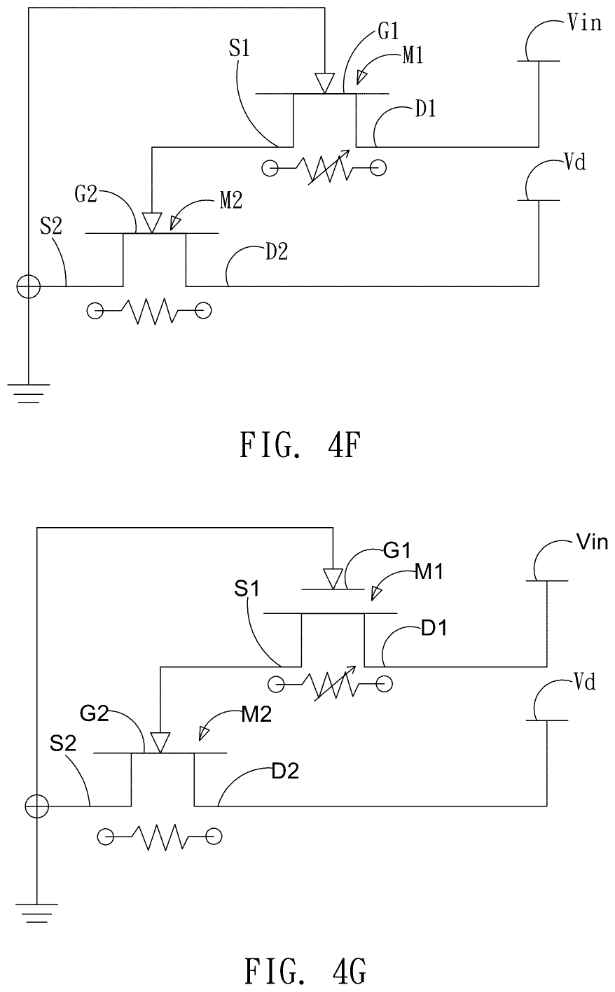

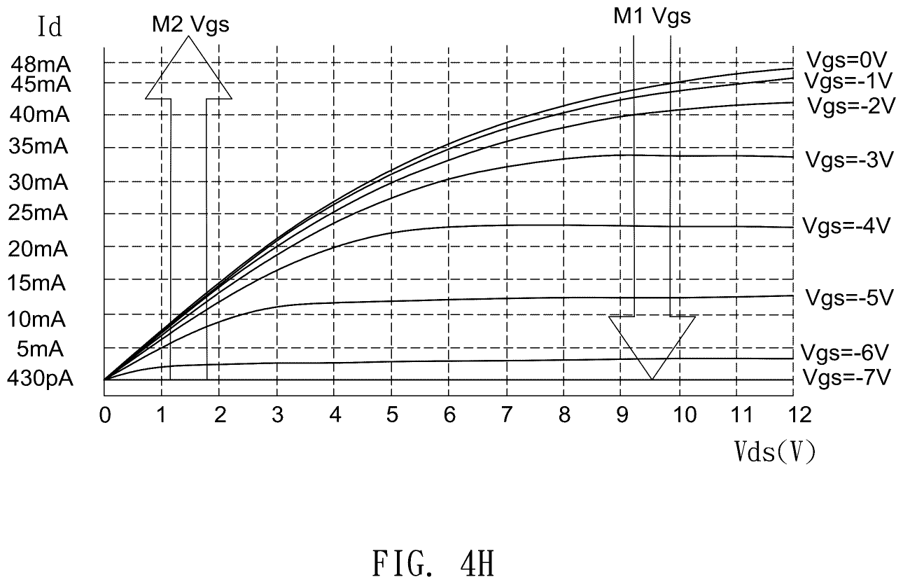

As shown in FIG. 4A to FIG. 4D, the principle of p-GaN gate E-mode AlGaN/GaN HEMT may be viewed from two perspectives. First, by viewing from the polarization electric field, after a p-GaN layer is grown on the epitaxy structure of AlGaN/GaN HEMT and fabricated under the gate metal region, this p-GaN layer will generate a polarization electric field to deplete the 2DEG in the i-GaN channel layer. Secondly, by viewing from the energy band, as shown in FIG. 4A, after a p-GaN layer is grown on the epitaxy structure of AlGaN/GaN HEMT, this p-GaN layer will raise the energy band of the blocking layer i-AlGaN. Thereby, the original potential well at the i-AlGaN/i-GaN junction will be raised above the Fermi energy level EF, and hence disabling 2DEG from forming.

As shown in FIG. 4B, as the voltage of the p-GaN gate G is less than or equal to 0, the 2DEG below is completely depleted. Thereby, the current from the drain D cannot pass the channel to reach the source S. As shown in FIG. 4C, as the voltage of the p-GaN gate G is greater than 0, the potential well at the i-AlGaN/i-GaN junction starts to suppress towards hence below the Fermi energy level. Thereby, electrons will refill the potential well below and forming 2DEG. When the 2DEG is recovered completely, this positive voltage is defined as the threshold voltage Vth. At this moment, the channel is turned on again and the current from the drain D may pass the channel to reach the source S.

In addition, as shown in the equivalent circuit diagram of FIG. 4D, the gate G of the p-GaN gate E-mode AlGaN/GaN HEMT versus the drain D and the gate G versus the source S may be viewed as two SBDs connected back-to-back. This means that when the gate is supplied with a positive voltage, the SBDs are reversed biased. Thereby, when Vgs is greater than VF, the SBD between the gate G and the source S will start to inject holes and form the reverse leakage current. At this time, the holes (positive charges) from the p-GaN gate will be injected into the 2DEG. Consequently, to maintain electrical neutrality of the channel layer, the number of electrons in the channel will be increased, leading to an increase of the concentration of the 2DEG. At this moment, to enable electrons to compensate the injected holes rapidly for maintaining electrical neutrality of the channel layer, the concentration of the 2DEG will be increased. Once the concentration of the 2DEG is increased, the drain current will be increased accordingly, resulting in an increase in the operating current of the whole device.

Besides, because the hole mobility is lower than at least a half of the electron mobility, holes will be confined and accumulated in the channel below the gate G. Thereby, the leakage current of the gate G may be reduced effectively. The gate G electrode, which is an electrode formed by Ni/Au, Pt/Au, Mo, TiN for forming Schottky contacts, of the p-GaN gate HEMT contacts the p-GaN directly and holes will be confined and accumulated in the channel below the gate G. Unfortunately, when Vgs is greater than VSBD (SBD reverse knee voltage), as shown in FIG. 4E, the conduction current of the SBD between the gate G and the drain D is so large that holes cannot be confined and accumulated in the channel below the gate G. Massive holes will be injected into the channel layer and making the gate leakage current increase rapidly. Hence, the transistor may no longer operate in the desired condition. Accordingly, the limited value of Vgs is always the shortcoming of a p-GaN gate E-mode AlGaN/GaN HEMT.

In general, due to different epitaxy and process conditions, Vgs(max) is around 5˜10V. Since the gate trigger voltage of a commercial power control IC is 9˜18V, the gate of the p-GaN gate E-mode AlGaN/GaN HEMT will be punched through directly by the massive gate leakage current Ig generated by the gate trigger voltage and leading to malfunction of the p-GaN gate E-mode AlGaN/GaN HEMT.

To solve the above problem, as shown in the equivalent circuits in FIG. 4F and FIG. 4G, the source of a first D-mode AlGaN/GaN HEMT M1 is connected to the gate of a p-GaN gate E-mode AlGaN/GaN HEMT M2. The source of first D-mode AlGaN/GaN HEMT M1 and the gate of a p-GaN gate E-mode AlGaN/GaN HEMT M2 are connected electrically using a fabrication method. Then the first D-mode AlGaN/GaN HEMT M1 acts as the gate protection device for the p-GaN gate E-mode AlGaN/GaN HEMT M2. It is to be mentioned that the gate of the first D-mode AlGaN/GaN HEMT M1 is connected to the source of the p-GaN gate E-mode AlGaN/GaN HEMT M2.

FIG. 4H shows the voltage and current operating curve corresponding to the devices in the equivalent circuits of FIG. 4F and FIG. 4G. The present invention may be understood as: First, the gate-to-source current Igs of M2 will increase as the gate-to-source voltage Vgs increases. At this moment, the magnitude of increase of the gate-to-source current Igs depends on: (a) the quality of epitaxy; (b) the activated concentration of the p-type dopant (Mg) in the p-GaN layer; and (c) the material of the p-GaN gate, as shown in the figure. Secondly, the power transistor is operating at high-speed switching. Thereby, the parasitic capacitance and inductance become extremely important. The gate input capacitance (Ciss) of the p-GaN gate E-mode AlGaN/GaN HEMT M2 according to the present invention is a substantial parameter. Since the first D-mode AlGaN/GaN HEMT M1 is a normally-on transistor, at the initial condition, the drain of the first D-mode AlGaN/GaN HEMT M1 is regarded shorted to the gate of the p-GaN gate E-mode AlGaN/GaN HEMT M2. Thereby, when the drain (Vin) of M1 is biased, the first D-mode AlGaN/GaN HEMT M1 will charge the input capacitance of the p-GaN gate E-mode AlGaN/GaN HEMT M2 from Vgs=0V and hence increasing the gate-to-source voltage Vgs of the p-GaN gate E-mode AlGaN/GaN HEMT M2. It is noteworthy that M1 should be designed to have a large current so that both Vin and the gate-to-source voltage Vgs of the p-GaN gate E-mode AlGaN/GaN HEMT M2 may be increased almost concurrently.

As shown in FIG. 4H, as the gate-to-source voltage Vgs of the p-GaN gate E-mode AlGaN/GaN HEMT M2 starts to increase, the gate-to-source voltage Vgs of the first D-mode AlGaN/GaN HEMT M1 becomes more negative. The variation of the two gate-to-source voltage Vgs maintains 1:1, only opposite in polarity. In other words, when the gate-to-source voltage Vgs of the p-GaN gate E-mode AlGaN/GaN HEMT M2 reaches 6.5V, the gate-to-source voltage Vgs of the first D-mode AlGaN/GaN HEMT M1 reaches −6.5V. When the gate-to-source voltage Vgs of the first D-mode AlGaN/GaN HEMT M1 becomes more negative, its drain-to-source current Ids becomes smaller. When the drain-to-source current Ids of the first D-mode AlGaN/GaN HEMT M1 is equal to the gate-to-source current Igs of the p-GaN gate E-mode AlGaN/GaN HEMT M2, a balanced state is reached. At this time, the gate-to-source voltage Vgs of the p-GaN gate E-mode AlGaN/GaN HEMT M2 is equal to the negative of the gate-to-source voltage Vgs of the first D-mode AlGaN/GaN HEMT M1. Thereafter, no matter how many the input voltage Vin is increased, since the first D-mode AlGaN/GaN HEMT M1 has entered the saturation region, its drain-to-source current Ids remains constant despite the increase in the drain-to-source voltage Vds. At this moment, the gate-to-source voltage Vgs of the p-GaN gate E-mode AlGaN/GaN HEMT M2 is fixed and the excess voltage will be absorbed by the first D-mode AlGaN/GaN HEMT M1. This is called the bootstrap phenomenon.

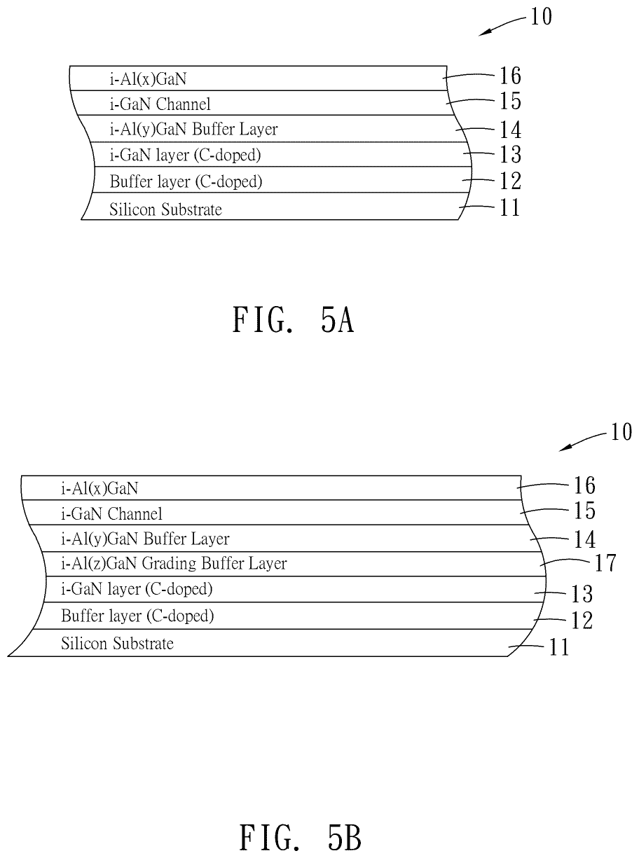

FIG. 5A shows the Ga-face AlGaN/GaN epitaxy structure of the hybrid type AlGaN/GaN HEMT device according to the present invention. This Ga-face AlGaN/GaN epitaxy structure 10 comprises, in order, a silicon substrate structure, an i-Al_{y}GaN buffer layer 14, an i-GaN channel layer 15, and an i-AlₓGaN layer 16. The buffer layer (C-doped) 12 is disposed on the silicon substrate 11. The silicon substrate structure includes a silicon substrate 11, a C-doped buffer layer 12, and a C-doped i-GaN layer 13. This Ga-face AlGaN/GaN epitaxy structure 10 includes the i-Al_{y}GaN buffer layer 14, which is mainly used for blocking the electrons of the buffer traps from entering the i-GaN channel layer 15 and thus avoiding current collapse of the device. FIG. 5B shows another epitaxy structure of the Ga-face AlGaN/GaN HEMT according to the present invention. To avoid the lattice mismatch problem if the i-Al_{y}GaN buffer layer 14 is grown directly on the C-doped i-GaN layer 13 as shown in FIG. 5A, an i-Al_{z}GaN grading buffer layer 17 is added, where Z=0.01-0.75.

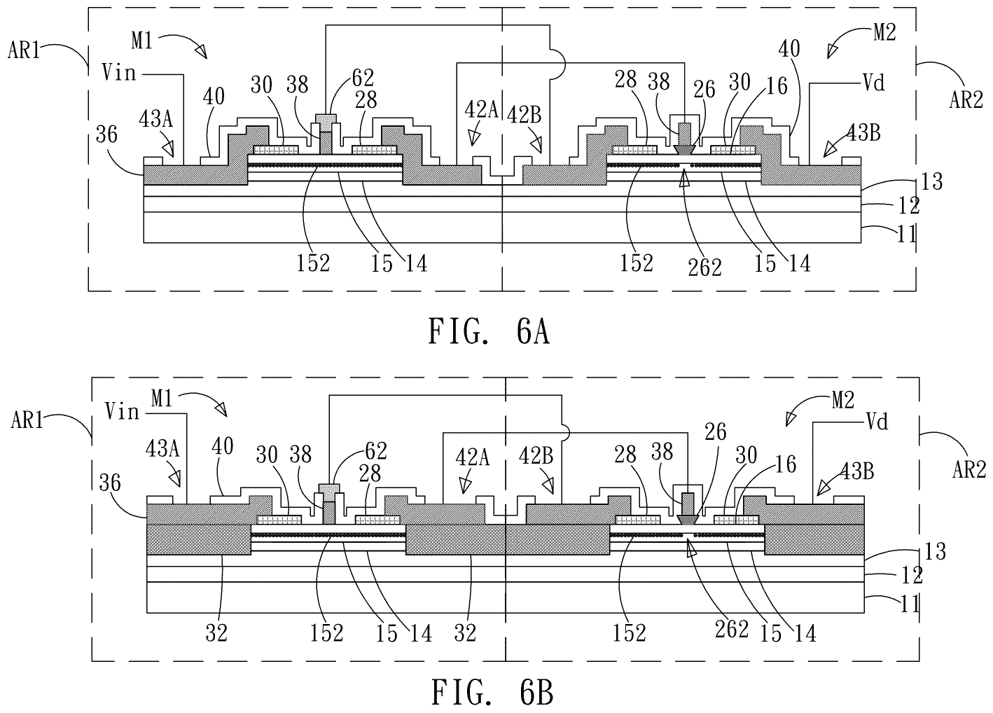

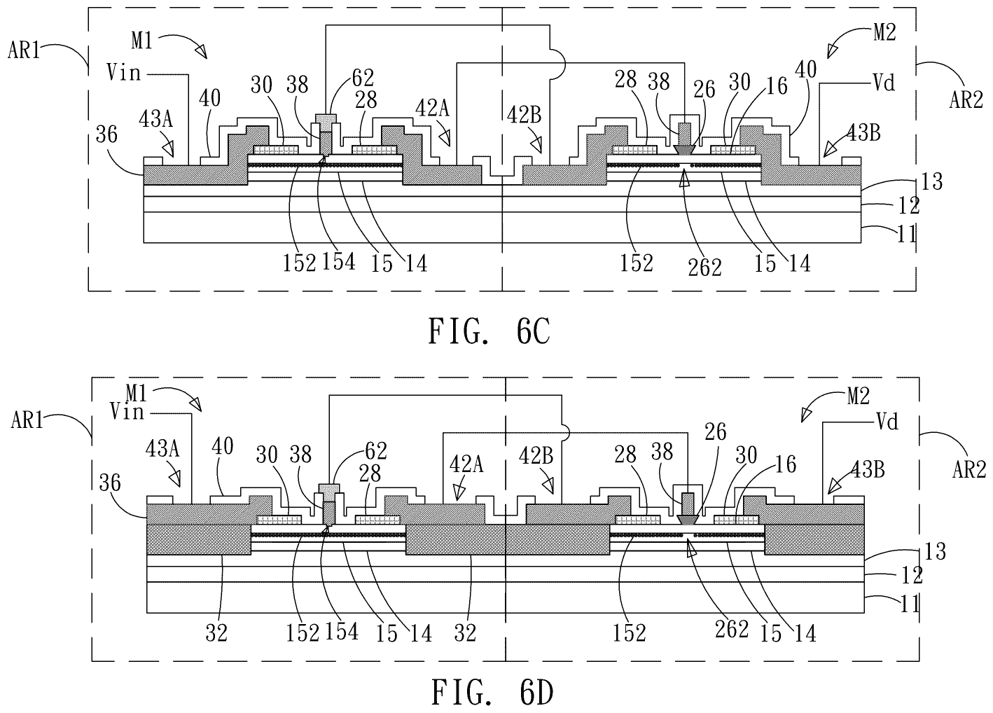

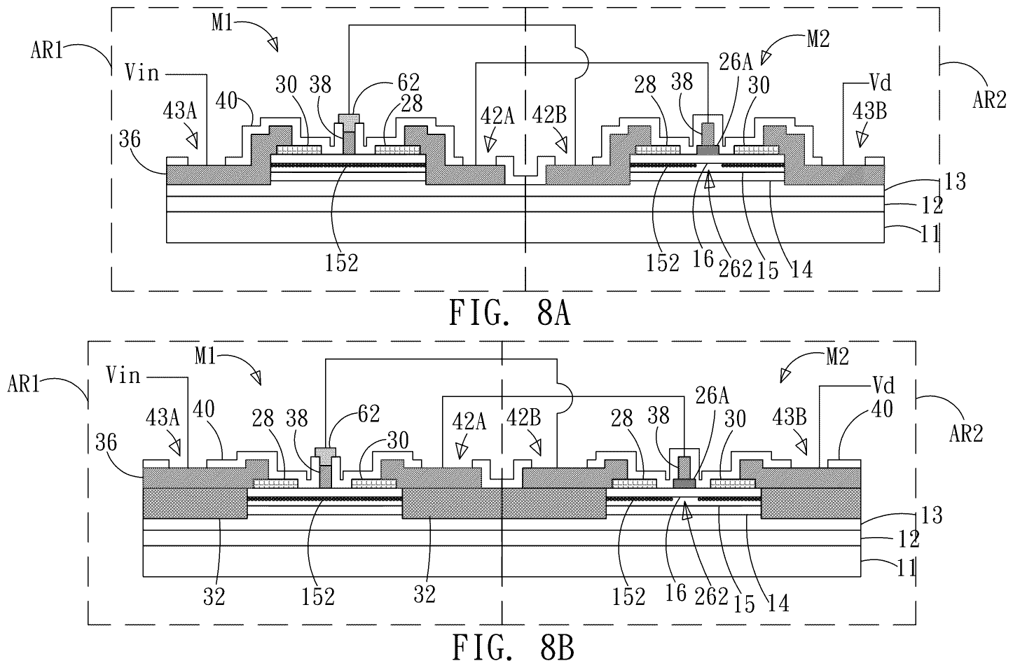

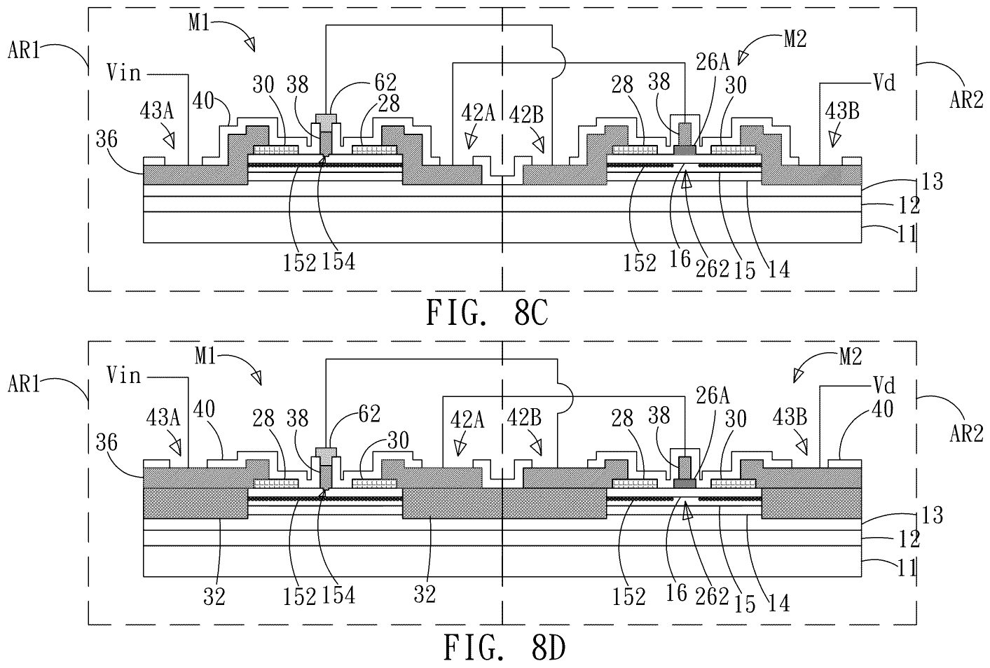

The present invention uses the first D-mode AlGaN/GaN HEMT M1 as the gate protection device for the p-GaN gate E-mode AlGaN/GaN HEMT M2. Thereby, a selective epitaxy growth (SEG) p-GaN gate is formed on Ga-face AlGaN/GaN epitaxy structure according to the present invention for forming an SEG p-GaN gate E-mode AlGaN/GaN HEMT. The present invention adopts an p-GaN inverted trapezoidal gate structure 26 (as shown in FIG. 6A and FIG. 6B) and uses SEG for growing p-GaN structure for the gate on the Ga-face AlGaN/GaN epitaxy structure. Thanks to the region of p-GaN gate structure (p-GaN the inverted trapezoidal gate structure 26), the 2DEG below the region will be depleted. Thereby, a p-GaN gate E-mode AlGaN/GaN HEMT M2 may be fabricated. Alternatively, after a p-GaN epitaxy layer is grown on the Ga-face AlGaN/GaN epitaxy structure according to the present invention, the dryetching method is adopted to etch and form the p-GaN etched gate structure 26A and give an p-GaN etched gate E-mode AlGaN/GaN HEMT M2, as shown in FIG. 8A and FIG. 8B. Accordingly, there are two types of p-GaN gate E-mode AlGaN/GaN HEMT, as described in detail in the following embodiments.

Embodiment 1: A D-mode AlGaN/GaN HEMT M1 without gate dielectric layer as the gate protection device and an SEG p-GaN gate E-mode AlGaN/GaN HEMT M2.

As shown in FIG. 6A and FIG. 6B, the characteristics of a first D-mode AlGaN/GaN HEMT M1 without gate dielectric layer as the gate protection device and the SEG p-GaN gate E-mode AlGaN/GaN HEMT M2 according to the present invention include the Ga-face AlGaN/GaN epitaxy structure 10 designed according to the present invention, namely, the first D-mode AlGaN/GaN HEMT M1 and the SEG p-GaN gate E-mode AlGaN/GaN HEMT M2 disposed on the silicon substrate structure, and a p-GaN inverted-trapezoidal gate structure 26 located on the first i-AlₓGaN layer 16 of the Ga-face AlGaN/GaN epitaxy structure 10. Although the 2DEG is formed in the i-GaN channel layer 15 at the junction between the i-AlₓGaN layer 16 and the i-GaN channel layer 15, due to the existence of the p-GaN inverted-trapezoidal gate structure 26, the 2DEG below the p-GaN inverted-trapezoidal gate structure 26 in the i-GaN channel layer 15 will be depleted. FIG. 6A and FIG. 6B are schematic diagrams after device fabrication using different device isolation processes. In FIG. 6B, multiple-energy destructive ion implantation is adopted. In general, heavy atoms such as boron or oxygen atoms are used for isolating devices. In FIG. 6A, dry etching to the highly resistive C-doped i-GaN buffer layer 13 may be adopted for isolating devices.

The present invention provides the first D-mode AlGaN/GaN HEMT M1 without gate dielectric layer as the gate protection device and the SEG p-GaN gate E-mode AlGaN/GaN HEMT M2. The Ga-face AlGaN/GaN epitaxy structure designed according to the present invention is divided into a first region ARI and a second region AR2. In the first region AR1, a first D-mode AlGaN/GaN HEMT M1 without gate dielectric layer is formed. In the second region AR2, an SEG p-GaN gate E-mode AlGaN/GaN HEMT M2 is formed. This SEG p-GaN gate E-mode AlGaN/GaN HEMT M2 includes a p-GaN inverted-trapezoidal gate structure 26. In addition, although the 2DEG is formed in the i-GaN channel layer 15 at the junction between the i-AlₓGaN layer 16 and the i-GaN channel layer 15, due to the existence of the p-GaN inverted-trapezoidal gate structure 26, the 2DEG below the p-GaN inverted-trapezoidal gate structure 26 in the i-GaN channel layer 15 will be depleted, giving a depletion region 262 without 2DEG below the p-GaN inverted-trapezoidal gate structure 26 and forming no connection.

In addition, a first source bonding pad region 42A of the first D-mode AlGaN/GaN HEMT M1 is connected to the gate metal 38 of the p-GaN E-mode AlGaN/GaN HEMT M2. A gate field-plate metal 62 of the first source bonding pad region 42A of the first D-mode AlGaN/GaN HEMT M1 is connected to a second source bonding pad region 42B of the p-GaN E-mode AlGaN/GaN HEMT M2. The gate field-plate metal 62 of the first D-mode AlGaN/GaN HEMT M1 is disposed on the gate metal 38. A first drain bonding pad region 43A of the first D-mode AlGaN/GaN HEMT M1 is connected to the input voltage Vin. A second drain bonding pad region of the p-GaN E-mode AlGaN/GaN HEMT M2 is connected to the drain voltage Vd.

In the following, the fabrication method for the present embodiment will be described. Nonetheless, a person having ordinary skill in the art should know that the present embodiment and its metal layout is not limited to the fabrication method.

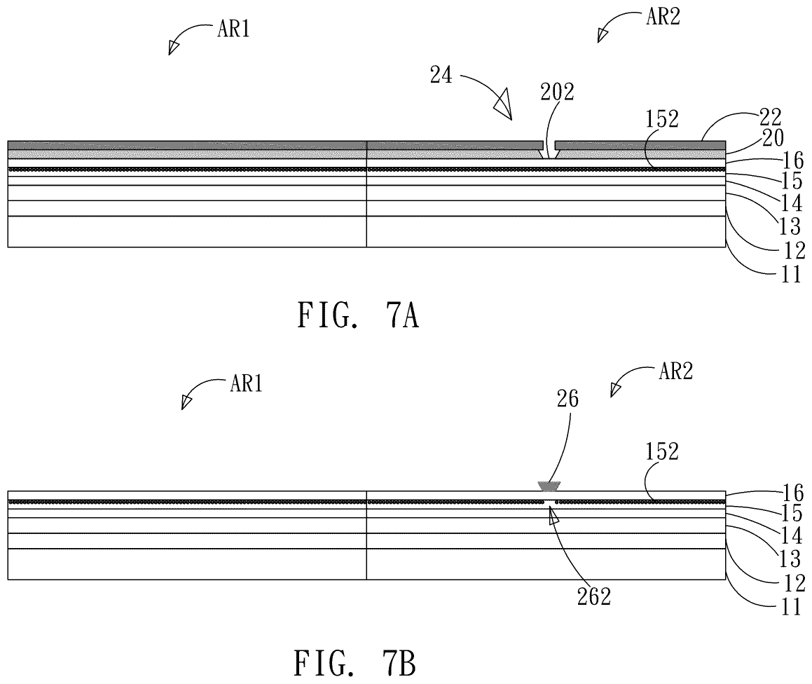

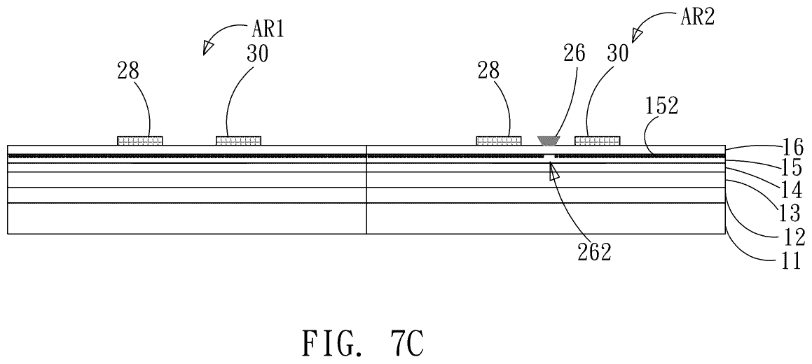

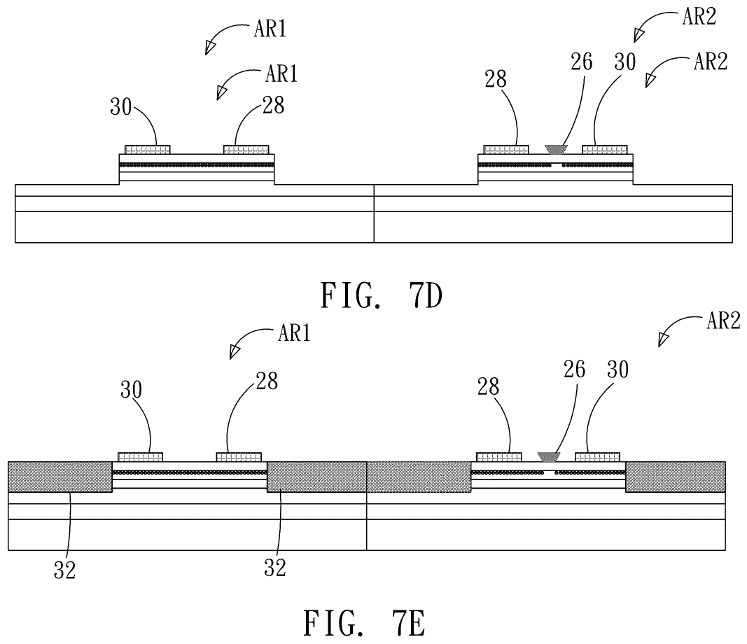

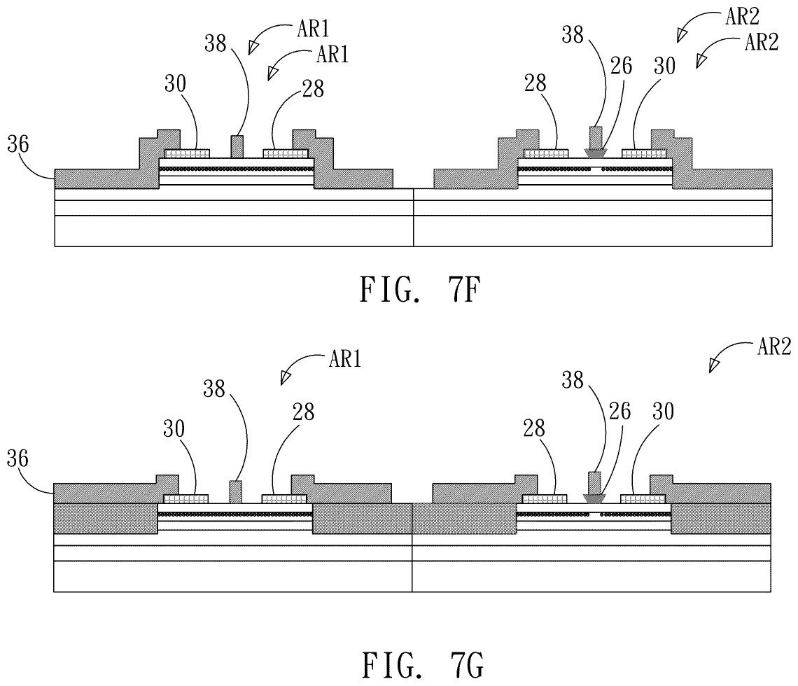

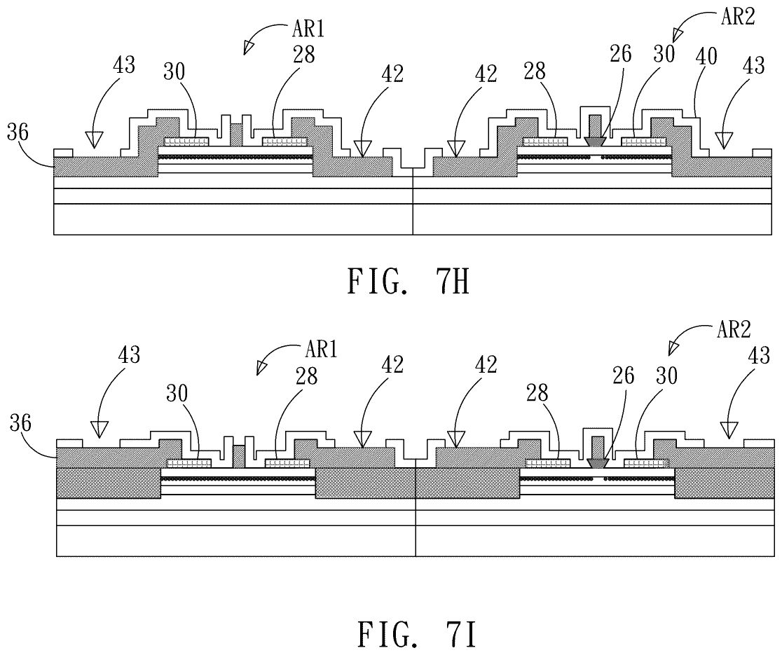

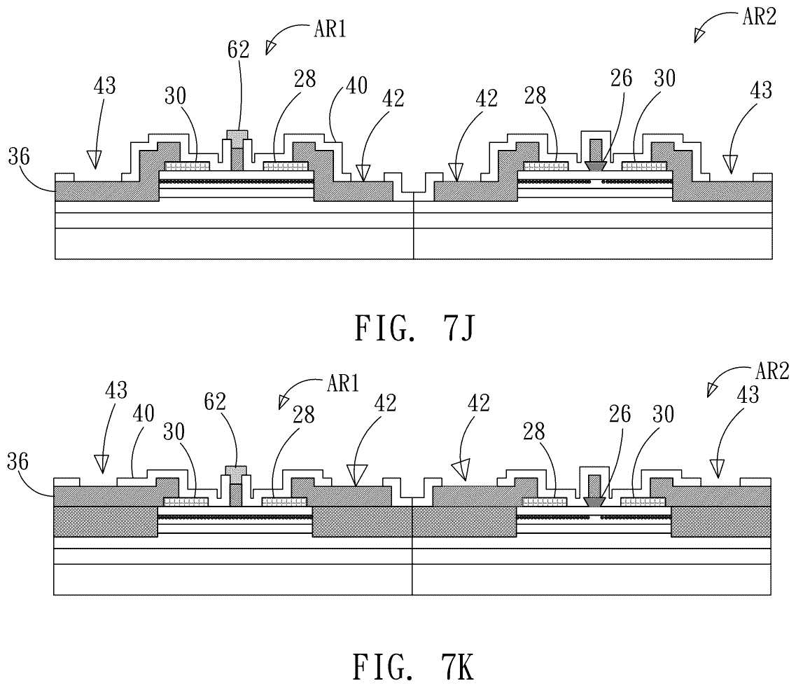

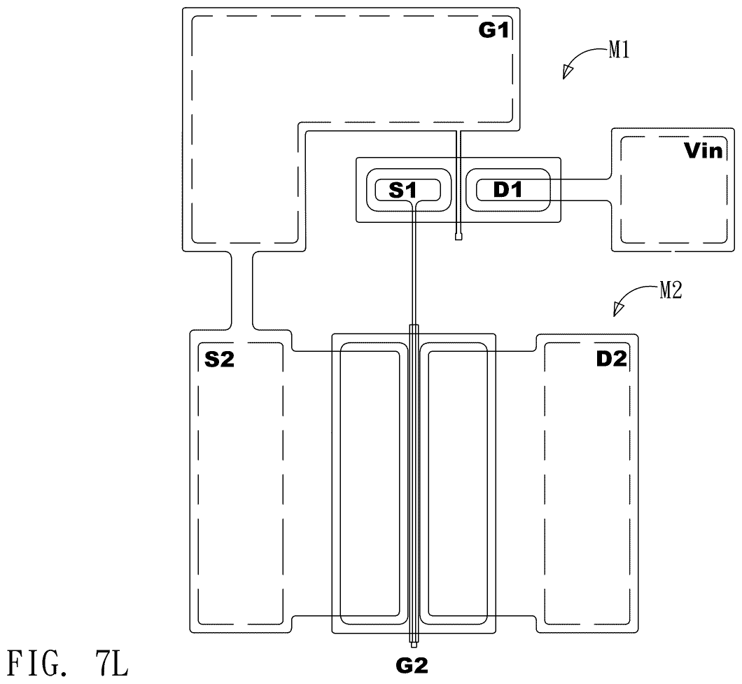

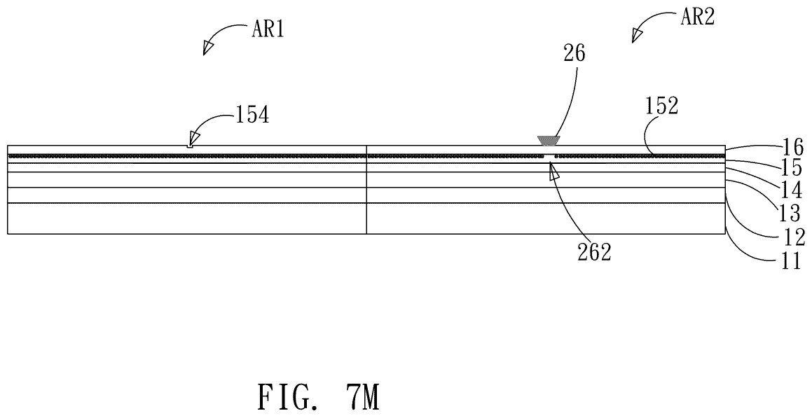

Step S11: Pattern the silicon dioxide mask layer 20. First, as shown in FIG. 7A, deposit a silicon dioxide mask layer 20 on the Ga-face AlGaN/GaN epitaxy structure 10 according to the present invention using plasma-enhanced chemical vapor deposition (PECVD) with a thickness of around 100˜200 nm. Next, define the gate SEG region 24 by using the photoresist 22 and the exposure method. Finally, the silicon dioxide mask layer 20 in the SEG region 24 is etched by a wet etching method using buffered oxide etchant (BOE) to expose the surface of the epitaxy. Then, the photoresist 22 is stripped using stripper. Because the wet etching is isotropic, in addition to etching downward, lateral etching will occur concurrently. Thereby, the opening 202 of the silicon dioxide mask layer 20 in the SEG region 24 will form an inverted trapezoidal structure.

Step S12: Form the p-GaN inverted-trapezoidal gate structure 26 using the SEG region 24. First, the p-GaN SEG region 24 is performed using metal-organic chemical vapor deposition (MOCVD) and only the exposed surface of the epitaxy may grow p-GaN. Because the growth of p-GaN in MOCVD is also isotropic, in addition to growing upward, lateral growth will occur concurrently and thus forming an inverted trapezoidal structure of p-GaN, which is just the p-GaN inverted-trapezoidal gate structure 26. Finally, the silicon dioxide mask layer 20 is etched by a wet etching method using BOE and forming the structure shown in FIG. 7B.

Then, because the p-GaN SEG region 24 occupies only a small portion of the whole epitaxy wafer, the loading effect will occur easily. Namely, the growth rate on the defined region for p-GaN is three to four times the growth rate on the general surface. Thereby, the p-type doping concentration in the p-GaN will be equal to ⅓ to ¼ of the expected.

Step S13: Form a drain ohmic contact 30 and a source ohmic contact 28. A metal layer, for example, a general Ti/Al/Ti/Au or Ti/Al/Ni/Au metal layer, is deposited on the epitaxy wafer using metal vapor deposition. Then a metal lift-off method is adopted to pattern the deposited metal layer for forming the drain and source ohmic contacts 30, 28 on the epitaxy wafer. Afterwards, a thermal treatment is performed at 700˜900° C. for 30 seconds to form the drain and source ohmic contacts 30, 28, as shown in FIG. 7C.

Step S14: Perform device isolation process. In this step, multiple-energy destructive ion implantation is adopted. In general, heavy atoms such as boron or oxygen atoms are used for isolating devices, as shown in FIG. 7E. Alternatively, dry etching to the highly resistive C-doped i-GaN buffer layer may be adopted for isolating devices, as shown in FIG. 7D.

Step S15: Perform the metal wiring process. In this step, metal deposition is performed. The metal vapor deposition and lift-off methods are used for patterning the Ni/Au metal layer and forming the gate metal 38, the bonding pads for the drain and the source ohmic contacts 30, 28, as well as the interconnection metal 36, as shown in FIG. 7F and FIG. 7G. Alternatively, in this step, the gate bonding pad region coupled electrically with the gate metal layer may be formed concurrently, as the gate structures G1, G2 shown in FIG. 7L.

Step S16: Deposit and pattern passivation layer. As shown in FIG. 7H and FIG. 7I, a passivation layer 40 is grown by PECVD. The material may be SiOx, SiOxNy, or SiNx. Finally, the passivation layer 40 is patterned for exposing the bonding pad region. For example, wet etching using BOE is adopted for exposing the drain and source bonding pad regions 42, 43 for subsequent wire bonding, corresponding to the first source bonding pad region 42A, the second source bonding pad region 42B, the first drain bonding pad region 43A, and the second drain bonding pad region 43B described above.

Step S17: Fabricate the gate field-plate metal. The metal vapor deposition and metal left-off methods are adopted to form the gate field-plate metal 62 for the first D-mode AlGaN/GaN HEMT M1, as shown in the final structures in FIG. 7J and FIG. 7K. The gate field-plate metal 62 of the first D-mode AlGaN/GaN HEMT M1 is disposed on the gate metal 38. The region of passivation layer 40 in the step S16 corresponding to the growth region of the gate field-plate metal 62 is etched. In other words, the passivation layer 40 is etched to form a hole at the location corresponding to the gate metal 38 of the first D-mode AlGaN/GaN HEMT M1 for accommodating the gate filed-plate metal 62 formed in the step S17. The gate filed-plate metal 62 according to the present embodiment fills and spills over the hole for covering the surroundings. Alternatively, according to the present invention, the gate filed-plate metal 62 may fill the hole only for meeting various requirements in gate width, for example, in the application with gate width greater than 10 micrometers. The top view of the first D-mode AlGaN/GaN HEMT M1 without gate dielectric layer as the gate protection device and the SEG p-GaN gate E-mode AlGaN/GaN HEMT M2 is shown in FIG. 7L.

Embodiment 2: As shown in FIG. 6C and FIG. 6D, the first D-mode AlGaN/GaN HEMT M1 further includes a gate AlGaN micro-etched structure 154. In the first D-mode AlGaN/GaN HEMT M1 without gate dielectric layer as the gate protection device and the p-GaN gate E-mode AlGaN/GaN HEMT M2, the gate AlGaN micro-etched structure 154 is disposed below the gate metal 38. The difference of the fabrication steps between the present embodiment and Embodiment 1 is that, according to the present embodiment, a step S12B is added between the step S12 and the step S13, as shown in FIG. 7M. The step S12B performs micro-etching on the i-AlₓGaN layer 16 at the location of the gate metal 38 for forming the gate AlGaN micro-etched structure 154. The step S12B is mainly used to create positive shift of the threshold voltage Vth of the first D-mode AlGaN/GaN HEMT M1 without gate dielectric layer.

Embodiment 3: The D-mode AlGaN/GaN HEMT M1 without gate dielectric layer as the gate protection device and the p-GaN gate E-mode AlGaN/GaN HEMT M2 with the p-GaN etched gate structure 26A.

FIG. 8A and FIG. 8B are schematic diagrams after device fabrication using different device isolation processes. In FIG. 8B, multiple-energy destructive ion implantation is adopted. In general, heavy atoms such as boron or oxygen atoms are used for isolating devices. In FIG. 8A, dry etching to the highly resistive C-doped i-GaN buffer layer 13 may be adopted for isolating devices.

As shown in FIG. 8A, the present invention provides the first D-mode AlGaN/GaN HEMT M1 without gate dielectric layer as the gate protection device and the p-GaN gate E-mode AlGaN/GaN HEMT M2. The Ga-face AlGaN/GaN epitaxy structure is divided into the first region AR1 and the second region AR2. In the first region AR1, a first D-mode AlGaN/GaN HEMT M1 without gate dielectric layer is formed. In the second region AR2, a p-GaN E-mode AlGaN/GaN HEMT M2 with the p-GaN etched gate structure 26A is formed. Although the 2DEG is formed in the i-GaN channel layer 15 at the junction between the i-AlₓGaN layer 16 and the i-GaN channel layer 15, due to the existence of the p-GaN etched gate structure 26A, the 2DEG below the p-GaN etched gate structure 26A in the i-GaN channel layer 15 will be depleted, giving a depletion region 262 without 2DEG.

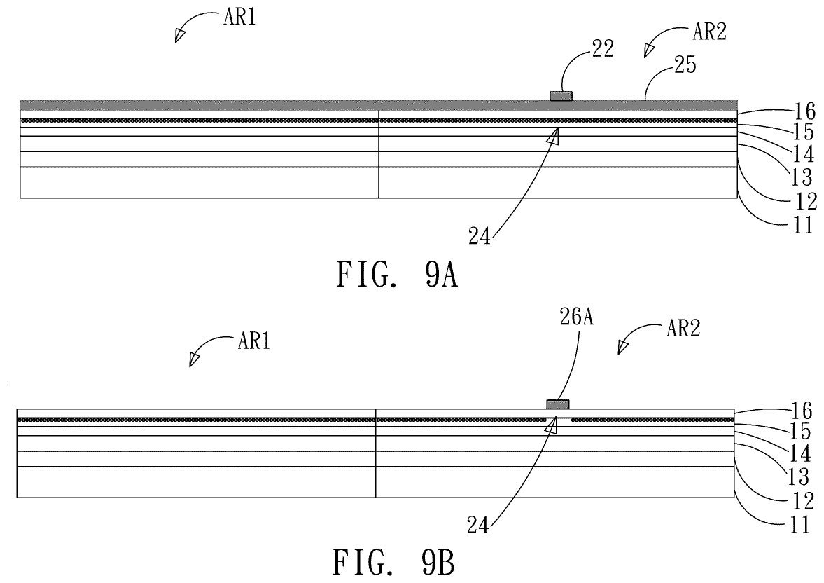

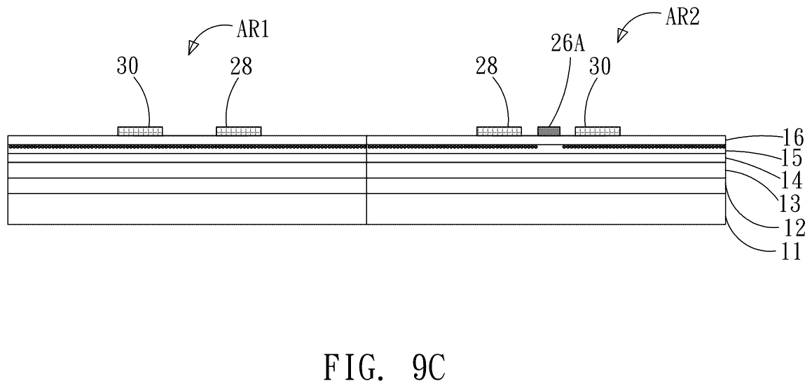

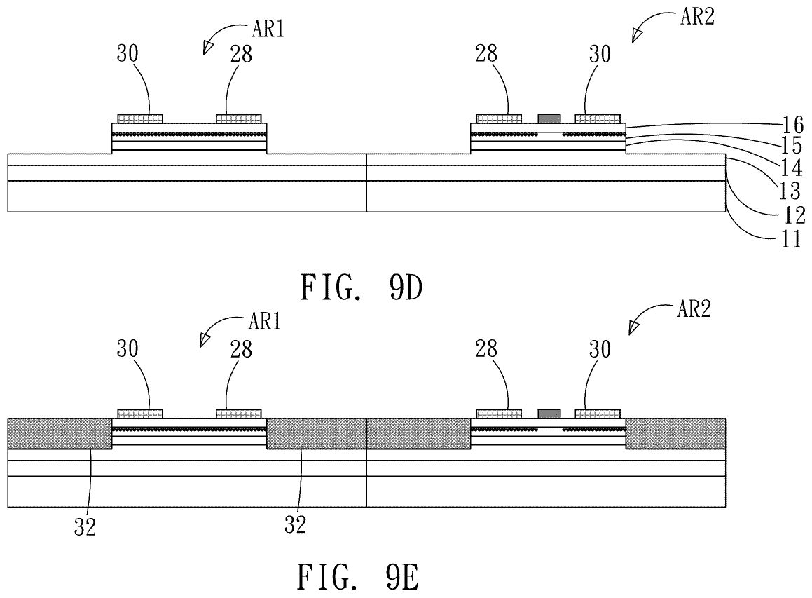

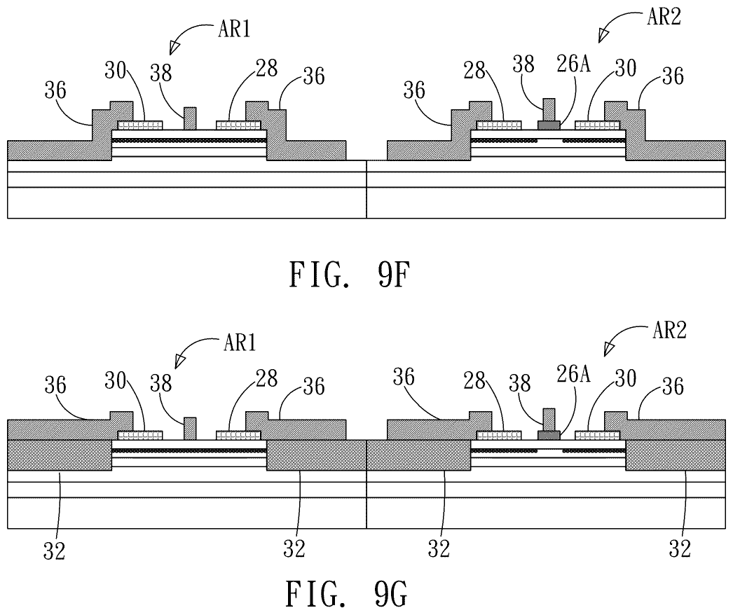

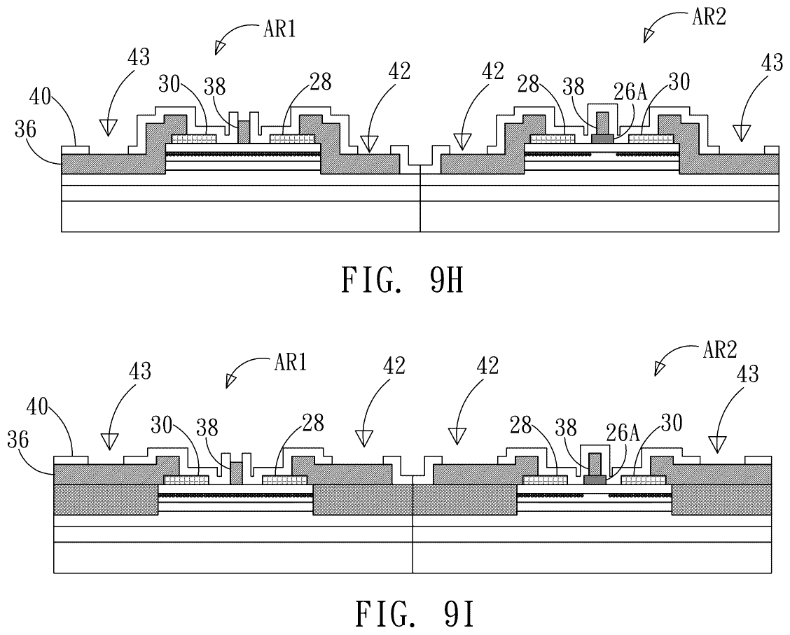

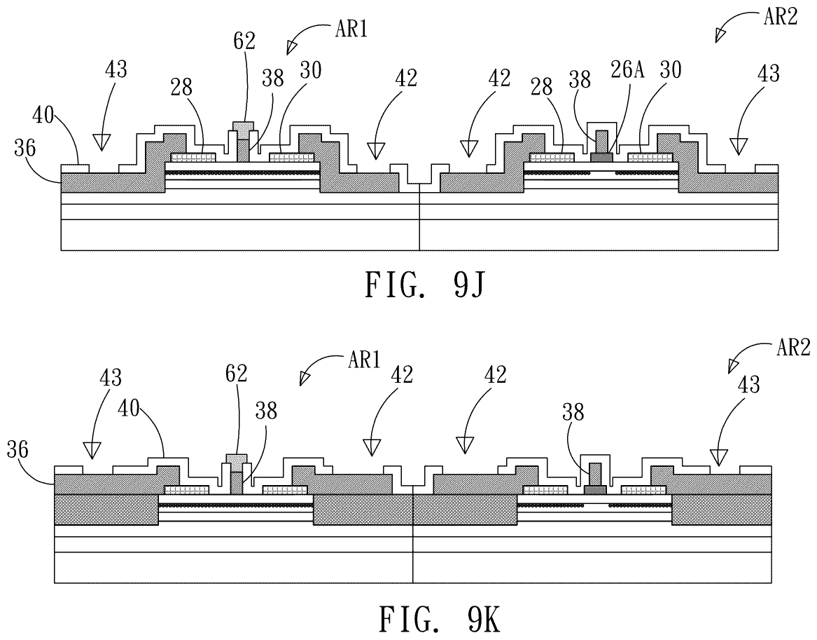

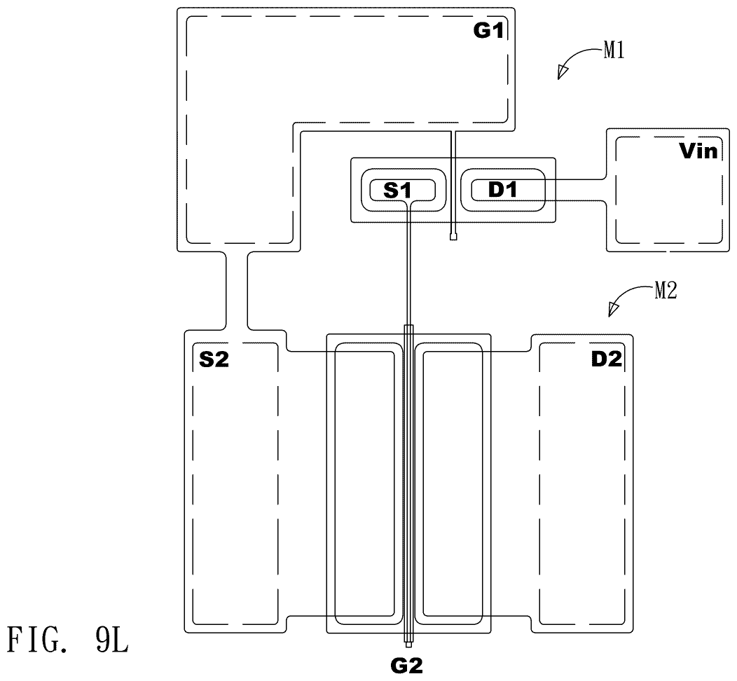

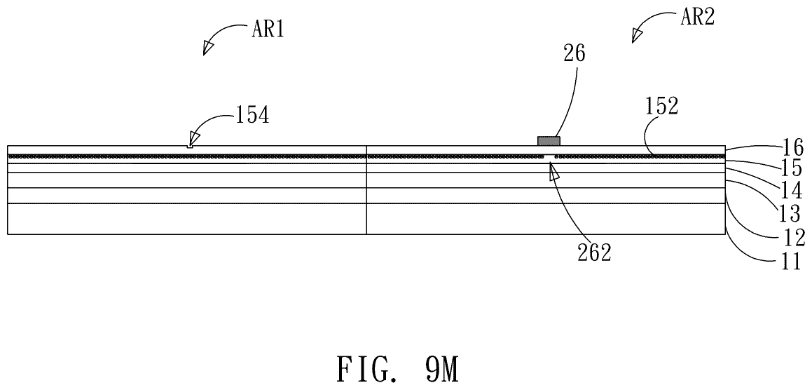

Step S31: Fabricate the p-GaN etched gate structure 26A. First, as shown in FIG. 9A, a p-GaN layer is grown on the Ga-face AlGaN/GaN epitaxy structure according to the present invention using MOCVD. Next, define the p-GaN gate region by using the photoresist 22 and the exposure method. Finally, dry etching is adopted to etch the p-GaN outside the region to the AlGaN blocking layer of the Ga-face AlGaN/GaN epitaxy structure according to the present invention. Then, the photoresist 22 is stripped using stripper. Thereby, the p-GaN etched gate structure 26A is fabricated.

According to Embodiment 3, since the process steps as shown in FIG. 9C to FIG. 9K are identical to those according to Embodiment 1 as shown in FIG. 7C to FIG. 7K, the details will not be repeated. The top view of the first D-mode AlGaN/GaN HEMT M1 without gate dielectric layer as the gate protection device and the p-GaN gate E-mode AlGaN/GaN HEMT M2 with the p-GaN etched gate structure 26A are shown in FIG. 7L.

Embodiment 4: As shown in FIG. 8C and FIG. 8D, the first D-mode AlGaN/GaN HEMT M1 further includes a gate AlGaN micro-etched structure 154 for the first D-mode AlGaN/GaN HEMT M1 without gate dielectric layer as the gate protection device and the p-GaN gate E-mode AlGaN/GaN HEMT M2 with the p-GaN etched gate structure 26A. The difference between the present embodiment and Embodiment 1 is that, according to the present embodiment, a step S12B is added between the step S12 and the step S13, as shown in FIG. 9J. The step S12B performs micro-etching on the i-AlₓGaN layer 16 at the location of the gate metal 38 for forming the gate AlGaN micro-etched structure 154. The step S12B is mainly used to create positive shift of the threshold voltage Vth of the first D-mode AlGaN/GaN HEMT M1 without gate dielectric layer.

The following Embodiment 5 and Embodiment 6 correspond to Embodiment 1 and Embodiment 3, respectively. The difference is that a D-mode AlGaN/GaN HEMT with gate dielectric layer is used as the gate protection device, as shown in the equivalent circuit in FIG. 4G. The difference between a D-mode HEMT without and with the gate dielectric layer 72 is that the threshold voltage Vth of a D-mode HEMT without the gate dielectric layer 72 will be smaller (more positive) than that of one with the gate dielectric layer 72. Contrarily, the advantage of a higher threshold voltage Vth is that the voltage to enter the saturation region is larger. As shown in the equivalent circuit, in the saturation region, the device becomes a variable resistor with high resistance. Accordingly, the total accumulated resistance for a higher threshold voltage Vth is smaller, leading to lower power consumption.

Embodiment 5: A D-mode AlGaN/GaN HEMT with gate dielectric layer as the gate protection device and the SEG p-GaN gate E-mode AlGaN/GaN HEMT.

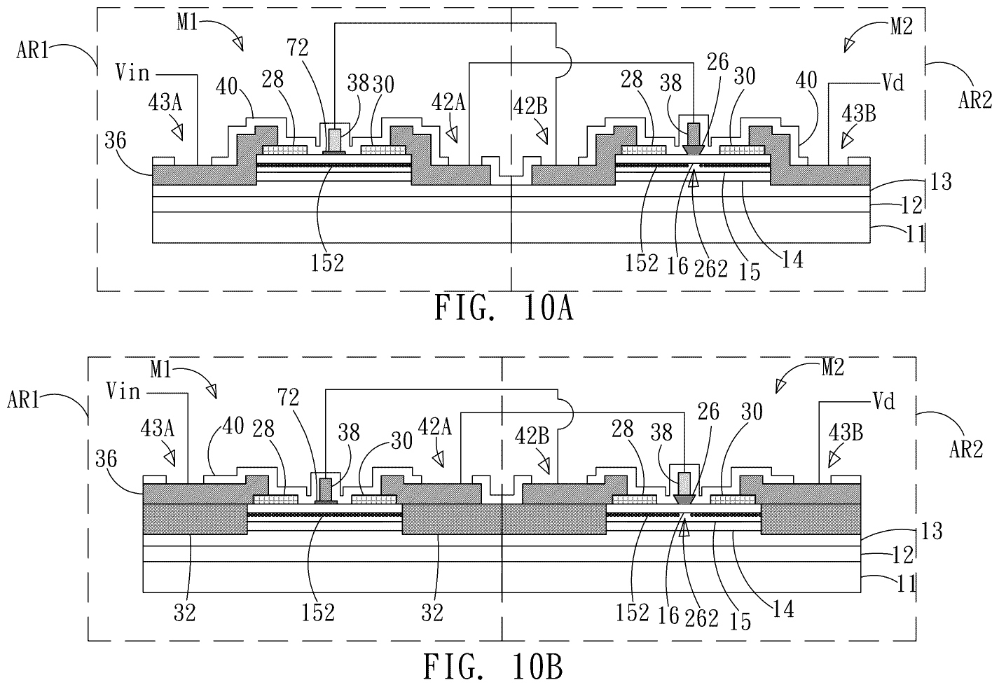

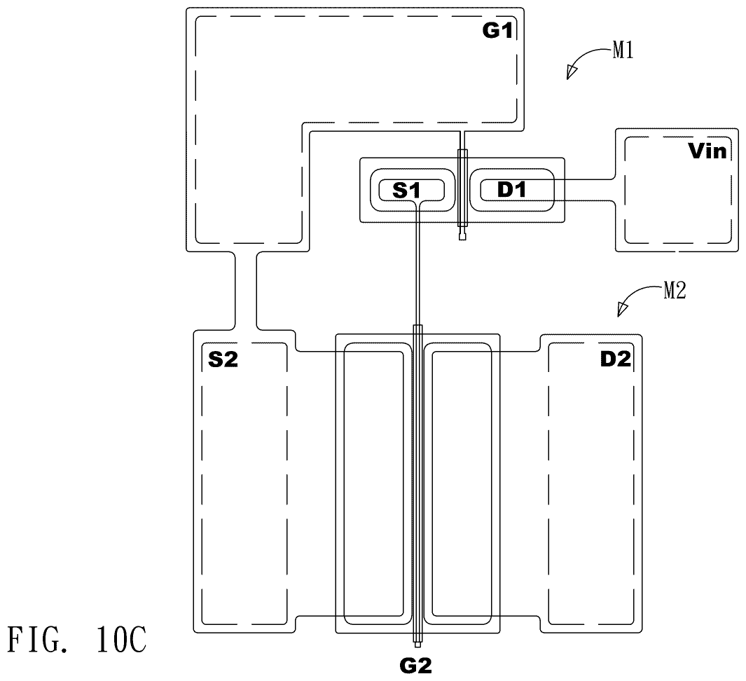

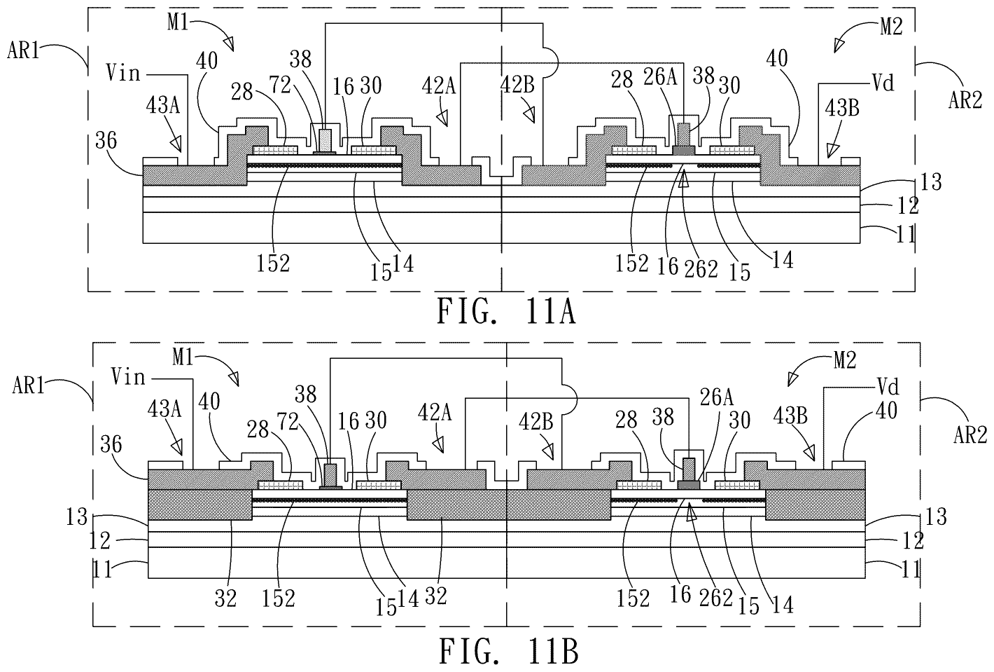

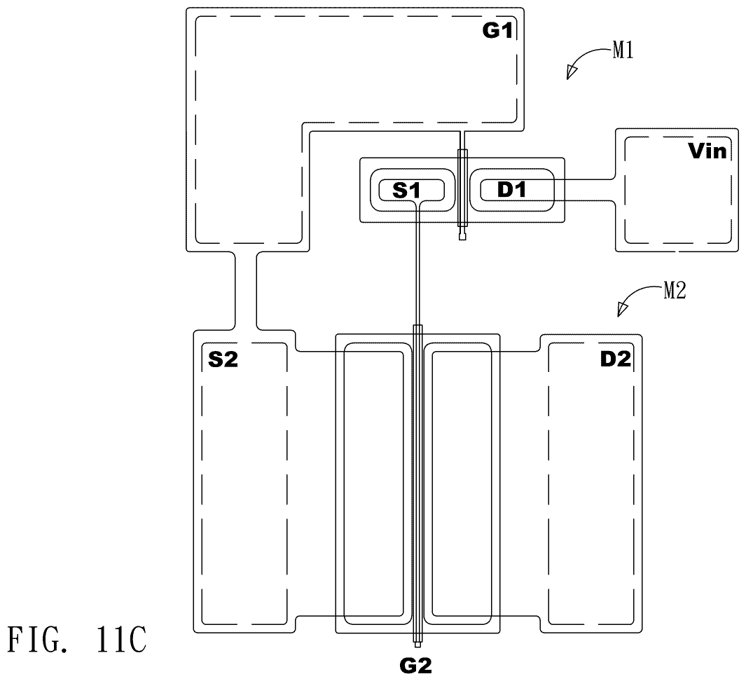

FIG. 10A and FIG. 10B show cross-sectional views of the first D-mode AlGaN/GaN HEMT M1 with the gate dielectric layer 72 as the gate protection device and the SEG p-GaN gate E-mode AlGaN/GaN HEMT M2. The characteristics include the AlGaN/GaN epitaxy structure designed according to the present invention and a p-GaN inverted-trapezoidal gate structure 26 located on a first i-AlₓGaN layer 16. Although the 2DEG is formed in the i-GaN channel layer 15 at the junction between the i-AlₓGaN layer 16 and the i-GaN channel layer 15, due to the existence of the p-GaN inverted-trapezoidal gate structure 26, the 2DEG below the p-GaN inverted-trapezoidal gate structure 26 in the i-GaN channel layer 15 will be depleted. FIG. 10A and FIG. 10B are schematic diagrams after device fabrication using different device isolation processes. In FIG. 10B, multiple-energy destructive ion implantation is adopted. In general, heavy atoms such as boron or oxygen atoms are used for isolating devices. In FIG. 10A, dry etching to the highly resistive C-doped i-GaN buffer layer may be adopted for isolating devices. The top view corresponding to FIG. 10A and FIG. 10B is shown in FIG. 10C.

The first D-mode AlGaN/GaN HEMT M1 with the gate dielectric layer 72 as the gate protection device and the SEG p-GaN gate E-mode AlGaN/GaN HEMT M2 according to the present invention comprises the Ga-face AlGaN/GaN epitaxy structure designed according to the present invention and is divided into the first region AR1 and a second region AR2. In the first region AR1, a first D-mode AlGaN/GaN HEMT M1 with the gate dielectric layer 72 is formed. In the second region AR2, an SEG p-GaN gate E-mode AlGaN/GaN HEMT M2 is formed. This SEG p-GaN gate E-mode AlGaN/GaN HEMT M2 includes a p-GaN inverted-trapezoidal gate structure 26. In addition, although the 2DEG is formed in the i-GaN channel layer 15 at the junction between the i-AlₓGaN layer 16 and the i-GaN channel layer 15, due to the existence of the p-GaN inverted-trapezoidal gate structure 26, the 2DEG below the p-GaN inverted-trapezoidal gate structure 26 in the i-GaN channel layer 15 will be depleted.

The process steps as shown in FIG. 7A to FIG. 7F according to Embodiment 5 are identical to those according to Embodiment 1. The only difference is that between the steps of FIG. 7C and FIG. 7D, a step is added for fabricating the gate dielectric layer 72 of the first D-mode AlGaN/GaN HEMT M1 with gate dielectric layer in the first region AR1.

Embodiment 6: A D-mode AlGaN/GaN HEMT with the gate dielectric layer 72 as the gate protection device and a p-GaN gate E-mode AlGaN/GaN HEMT with p-GaN etched gate structure.

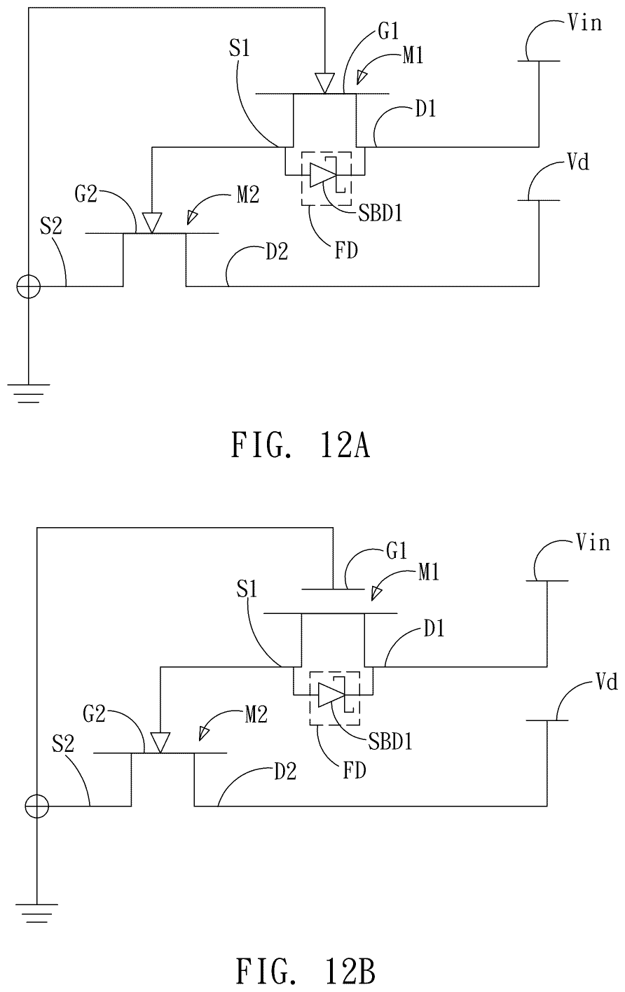

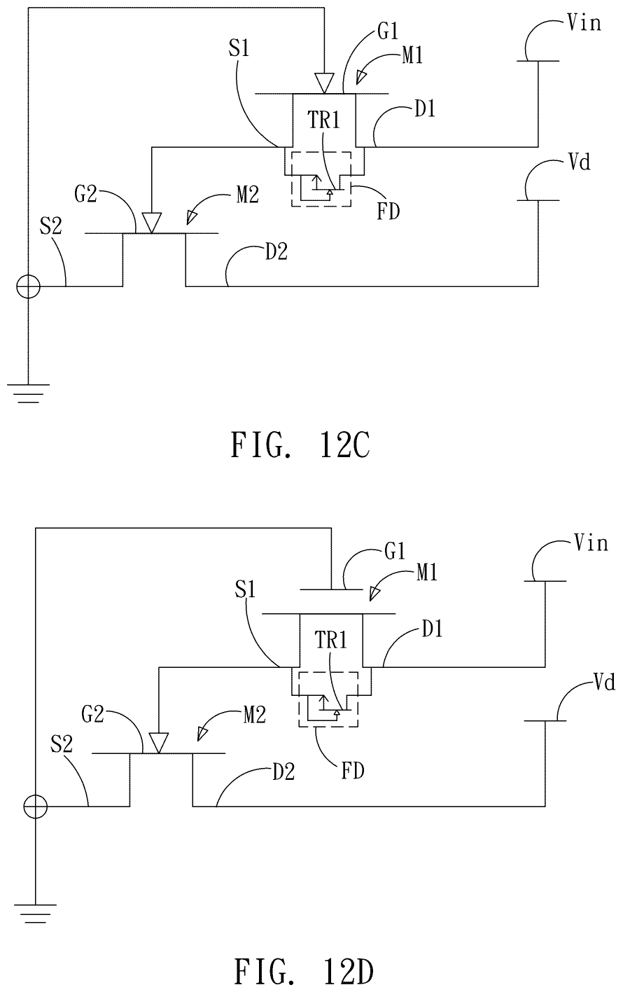

FIG. 11A and FIG. 11B are schematic diagrams after device fabrication using different device isolation processes. In FIG. 11B, multiple-energy destructive ion implantation is adopted. In general, heavy atoms such as boron or oxygen atoms are used for isolating devices. In FIG. 11A, dry etching to the highly resistive C-doped i-GaN buffer layer may be adopted for isolating devices. The top view corresponding to FIG. 11A and FIG. 11B is shown in FIG. 11C.

As shown in FIG. 11A and FIG. 11B, the present invention provides the first D-mode AlGaN/GaN HEMT M1 with gate dielectric layer as the gate protection device and the p-GaN etched gate E-mode AlGaN/GaN HEMT with p-GaN etched gate structure. The Ga-face AlGaN/GaN epitaxy structure and is divided into the first region AR1 and the second region AR2. In the first region AR1, a first D-mode AlGaN/GaN HEMT M1 without gate dielectric layer is formed. In the second region AR2, a p-GaN E-mode AlGaN/GaN HEMT M2 with the p-GaN etched gate structure 26A is formed. Although the 2DEG is formed in the i-GaN channel layer 15 at the junction between the i-AlₓGaN layer 16 and the i-GaN channel layer 15, due to the existence of the p-GaN etched gate structure 26A, the 2DEG below the p-GaN etched gate structure 26A in the i-GaN channel layer 15 will be depleted, giving a depletion region 262 without 2DEG.

Step S61: Fabricate the p-GaN etched gate. First, as shown in FIG. 9A, a p-GaN layer is grown on the Ga-face AlGaN/GaN epitaxy structure according to the present invention using MOCVD. Next, define the p-GaN gate region by using the photoresist 22 and the exposure method. Finally, dry etching is adopted to etch the p-GaN outside the region to the AlGaN blocking layer of the Ga-face AlGaN/GaN epitaxy structure according to the present invention. Then, the photoresist 22 is stripped using stripper. Thereby, the p-GaN etched gate structure 26A is fabricated.

The process steps as shown in FIG. 9A to FIG. 9L according to Embodiment 6 are identical to those according to Embodiment 2. The only difference is that between the steps of FIG. 9D to FIG. 9G, a step is added for fabricating the gate dielectric layer 72 of the first D-mode AlGaN/GaN HEMT M1 with the gate dielectric layer 72 in the first region AR1.

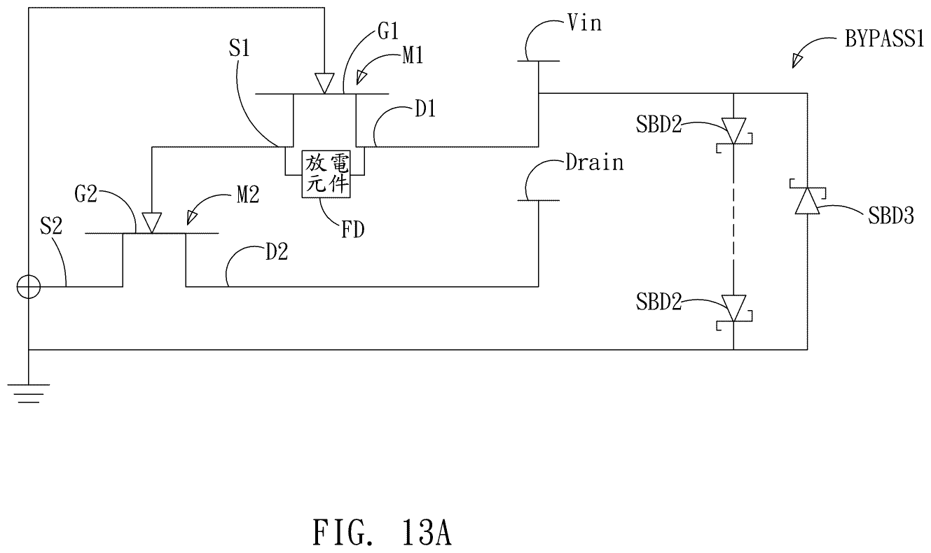

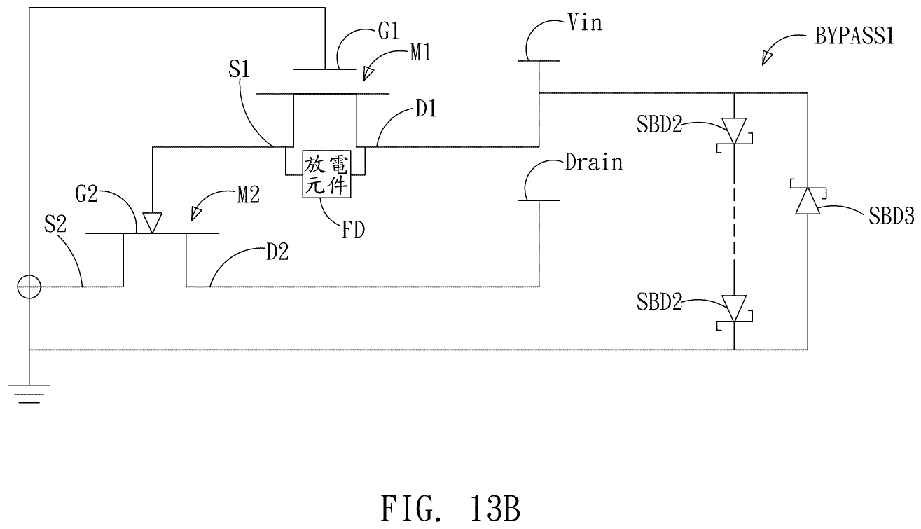

Embodiment 7: As shown in FIG. 12A and FIG. 12B, the hybrid type AlGaN/GaN HEMT device according to the present invention further comprises a discharging device FD. According to the present embodiment, a Schottky barrier diode SBD1 or a discharging transistor TR1 is taken as an example. The discharging device FD is coupled to the source S1 and the drain D1 of the first D-mode AlGaN/GaN HEMT M1. When the discharging device FD is the Schottky barrier diode SBD1, the anode of the Schottky barrier diode SBD1 is coupled to the source S1 of the first D-mode AlGaN/GaN HEMT M1; the cathode of the Schottky barrier diode SBD1 is coupled to the drain D1 of the first D-mode AlGaN/GaN HEMT M1, namely, the input voltage Vin. Thereby, when the first D-mode AlGaN/GaN HEMT M1 of the hybrid type AlGaN/GaN HEMT device is in the off state, the source S1 to the drain D1 of the first D-mode AlGaN/GaN HEMT M1 and to the input voltage Vin will form a preferable discharging path. Fast discharging will be performed by the discharging device FD, for example, the Schottky barrier diode SBD1 or the discharging transistor TR1.

Comparing FIG. 12A and FIG. 12B to FIG. 12C and FIG. 12D, the discharging device FD in FIG. 12A and FIG. 12B is the Schottky barrier diode SBD1 while the discharging device FD in FIG. 12C and FIG. 12D is the discharging transistor TR1. The discharging transistor TR1 may be a p-GaN E-mode AlGaN/GaN HEMT. With better voltage tolerance, the discharging transistor TR1 withstands the input voltage Vin, particularly when it is turned on in a single direction. Thereby, the discharging transistor TR1 according to the present embodiment may be regarded as a device that turns on in a single direction, like the Schottky barrier diode SBD1. The difference between FIG. 12A and FIG. 12B is that the gate G1 of the first D-mode AlGaN/GaN HEMT M1 in FIG. 12B further includes a gate dielectric layer. Similar to FIG. 10A and FIG. 11B, the gate dielectric layer 72 is disposed on the gate of the first D-mode AlGaN/GaN HEMT M1. The difference between FIG. 12C and FIG. 12D is like the difference between FIG. 12A and FIG. 12B. Hence, the details will not be repeated.

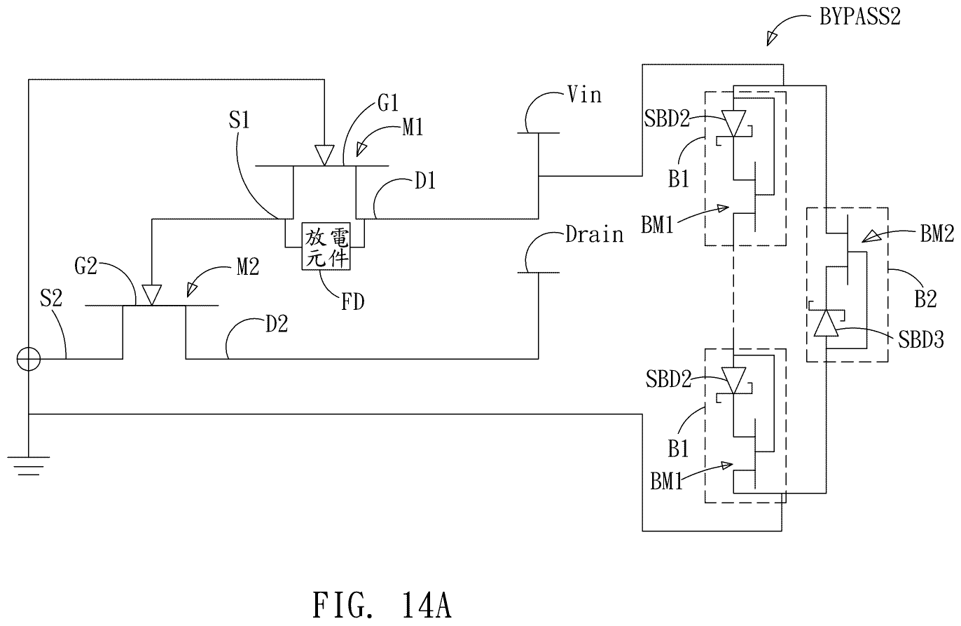

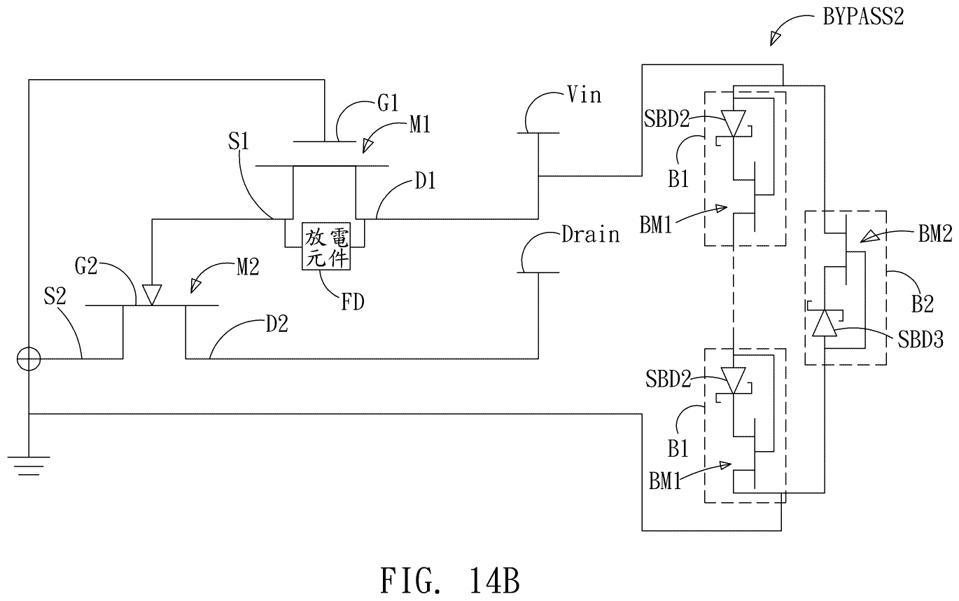

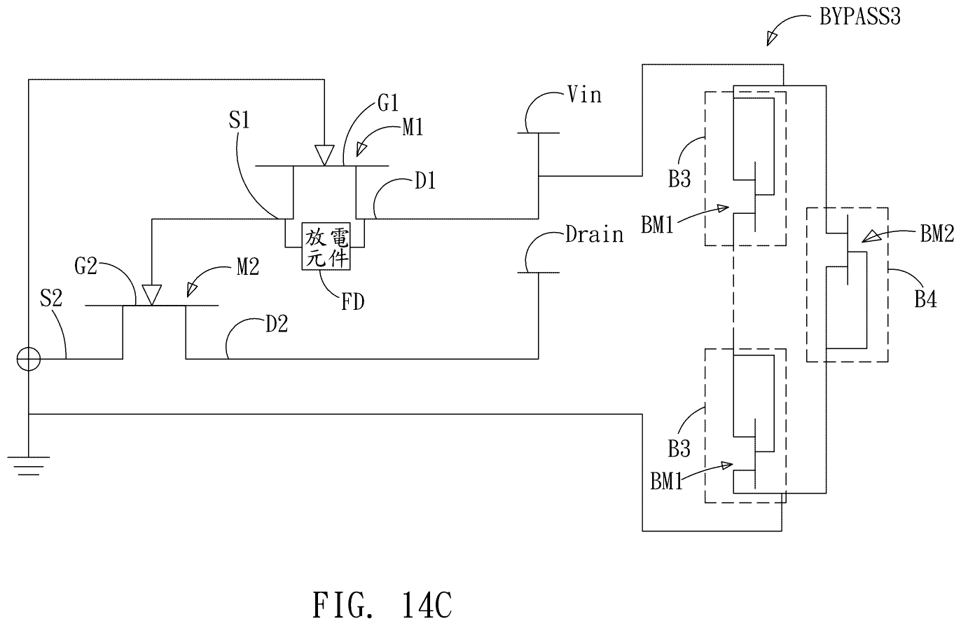

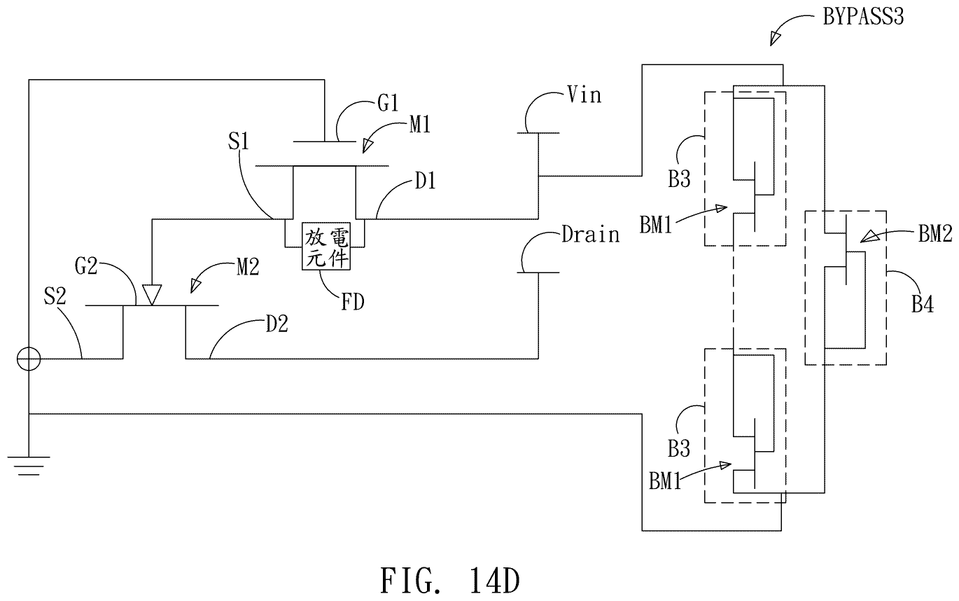

Embodiment 8: As shown in FIG. 13A to FIG. 13B, the hybrid type AlGaN/GaN HEMT device according to the present invention further comprises a bypass circuit, such as the first bypass circuit BYPASS1 shown in FIG. 13A and FIG. 13B, the second bypass circuit BYPASS2 shown in FIG. 14A and FIG. 14B, or the third bypass circuit BYPASS3 shown in FIG. 14C and FIG. 14D. The first bypass circuit BYPASS1 according to the present embodiment is coupled to the drain DI of the first D-mode AlGaN/GaN HEMT M1 and the source S2 of the p-GaN gate E-mode AlGaN/GaN HEMT M2. The first bypass circuit BYPASS1 includes a plurality of first bypass diodes SBD2 and a second bypass diode SBD3. In addition, the plurality of first bypass diodes SBD2 and the second bypass diode SBD3 are SBDs for example. The plurality of first bypass diodes SBD2 are coupled in series. The polarity of the plurality of first bypass diodes SBD2 is opposite to the polarity of the second bypass diode SBD3.

The second bypass circuit BYPASS2 according to the present embodiment is coupled to the drain D1 of the first D-mode AlGaN/GaN HEMT M1 and the source S2 of the p-GaN gate E-mode AlGaN/GaN HEMT M2. The second bypass circuit BYPASS2 includes a plurality of first bypass units B1 and a second bypass unit B2. The plurality of first bypass units B1 includes a first bypass diode SBD2 and a first bypass transistor BM1, respectively. The second bypass unit B2 includes and a second bypass diode SBD3 and a second bypass transistor BM2. The plurality of first bypass diodes SBD2 and the second bypass diode SBD3 shown in FIG. 14A and FIG. 14B are identical to the plurality of first bypass diodes SBD2 and the second bypass diode SBD3 shown in FIG. 13A and FIG. 13B, all being SBDs for example. The plurality of first bypass transistors BM1 and the second bypass transistor BM2 are D-mode AlGaN/GaN HEMT. The plurality of first bypass transistors BMI are coupled to the anode of the corresponding first bypass diode SBD2, respectively. The gate of the second bypass transistor BM2 is coupled to the anode of the second bypass diode SBD3. Besides, the plurality of first bypass transistor BM1 and the second bypass transistor BM2 further may be p-GaN gate E-mode AlGaN/GaN HEMT.

Furthermore, as shown in FIG. 14C and FIG. 14D, the third bypass circuit BYPASS3 includes a plurality of third bypass units B3 and a fourth bypass unit B4.

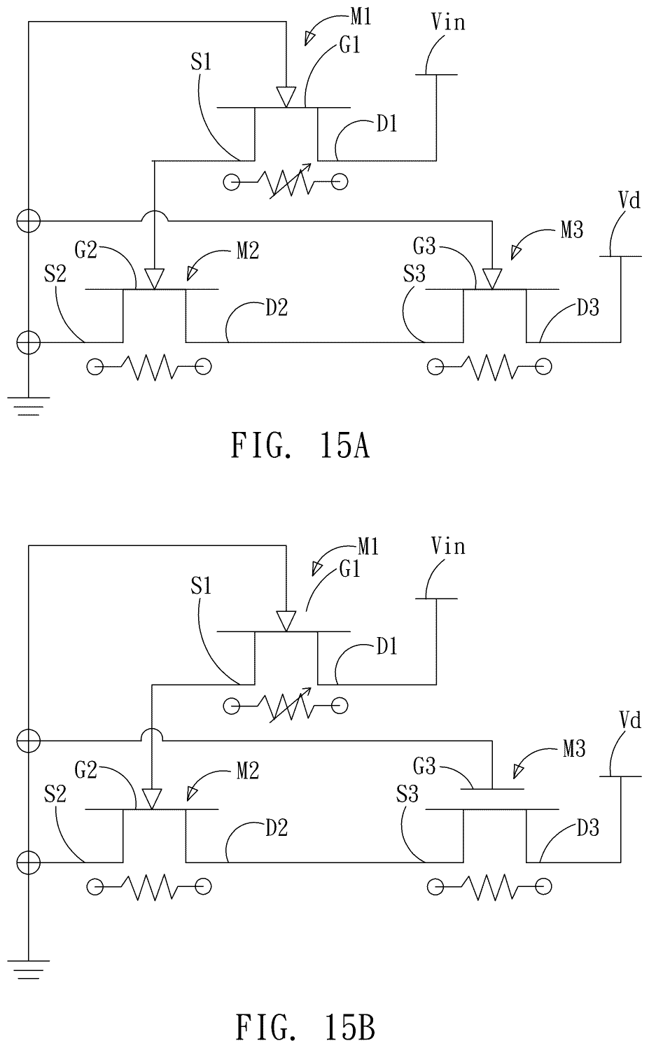

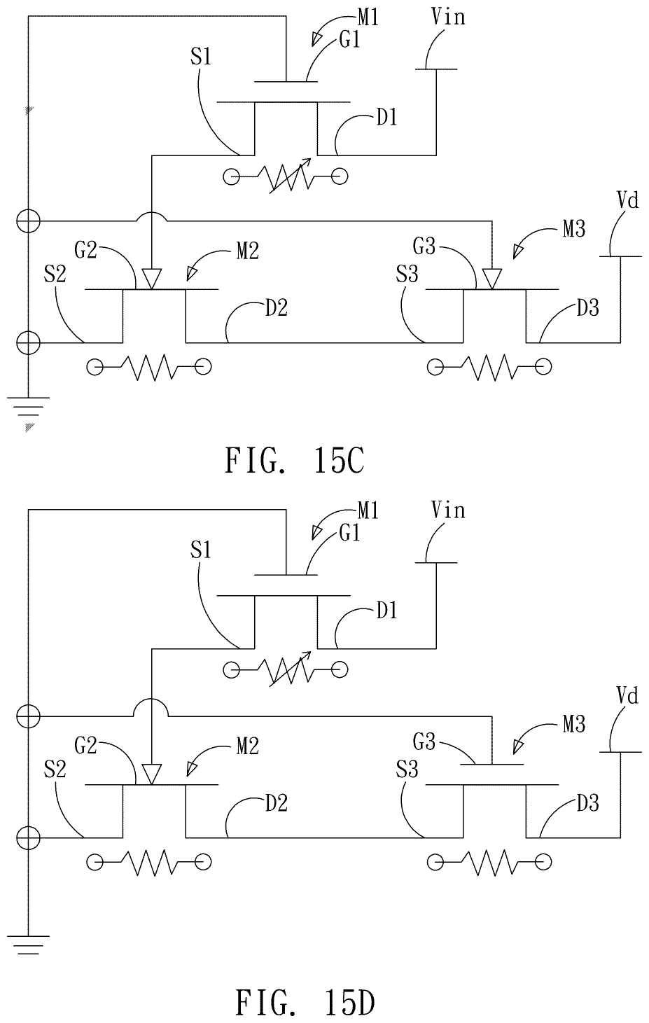

As shown in FIG. 15A and FIG. 15B, which show equivalent circuits of the source S1 of a first D-mode AlGaN/GaN HEMT M1 without gate dielectric layer connecting to the gate G2 of a p-GaN gate E-mode AlGaN/GaN HEMT M2 and cascoding to a second D-mode AlGaN/GaN HEMT M3 (1) without gate dielectric layer and (2) with the gate dielectric layer 72. The source S1 of the first D-mode AlGaN/GaN HEMT M1 without gate dielectric layer and the gate G2 of the p-GaN gate E-mode AlGaN/GaN HEMT M2 are connected electrically using a fabrication method. Then the D-mode AlGaN/GaN HEMT M1 acts as the gate protection device for the p-GaN gate E-mode AlGaN/GaN HEMT M2. The drain D2 of the p-GaN gate E-mode AlGaN/GaN HEMT M2 and the source S3 of the second D-mode AlGaN/GaN HEMT M3 are connected electrically. The source S2 of the p-GaN gate E-mode AlGaN/GaN HEMT M2 is connected electrically to the gate G3 of the second D-mode AlGaN/GaN HEMT M3. The gate G3 of the second D-mode AlGaN/GaN HEMT M3 is connected electrically to the source S2 of the p-GaN gate E-mode AlGaN/GaN HEMT M2 for enabling a greater off-state breakdown voltage at Vin=0V (off-state) for the hybrid type AlGaN/GaN HEMT device of M1+M2+M3. This is because the off-state breakdown voltage of the hybrid type AlGaN/GaN HEMT device is the sum of the off-state breakdown voltage of the p-GaN gate E-mode AlGaN/GaN HEMT M2 and the off-state breakdown voltage of the second D-mode AlGaN/GaN HEMT M3.

As shown in FIG. 15C and FIG. 15D, which show equivalent circuits of the source S1 of a first D-mode AlGaN/GaN HEMT M1 with gate dielectric layer connecting to the gate G2 of a p-GaN gate E-mode AlGaN/GaN HEMT M2 and cascoding to a second D-mode AlGaN/GaN HEMT M3 (1) without gate dielectric layer and (2) with the gate dielectric layer 72. The source S1 of the first D-mode AlGaN/GaN HEMT M1 with gate dielectric layer and the gate G2 of the p-GaN gate E-mode AlGaN/GaN HEMT M2 are connected electrically using a fabrication method. Then the D-mode AlGaN/GaN HEMT M1 acts as the gate protection device for the p-GaN gate E-mode AlGaN/GaN HEMT M2. The drain D2 of the p-GaN gate E-mode AlGaN/GaN HEMT M2 and the source S3 of the second D-mode AlGaN/GaN HEMT M3 are connected electrically. The source S2 of the p-GaN gate E-mode AlGaN/GaN HEMT M2 is connected electrically to the gate G3 of the second D-mode AlGaN/GaN HEMT M3. The hybrid type AlGaN/GaN HEMT device according to the present embodiment also provides a larger off-state breakdown voltage.

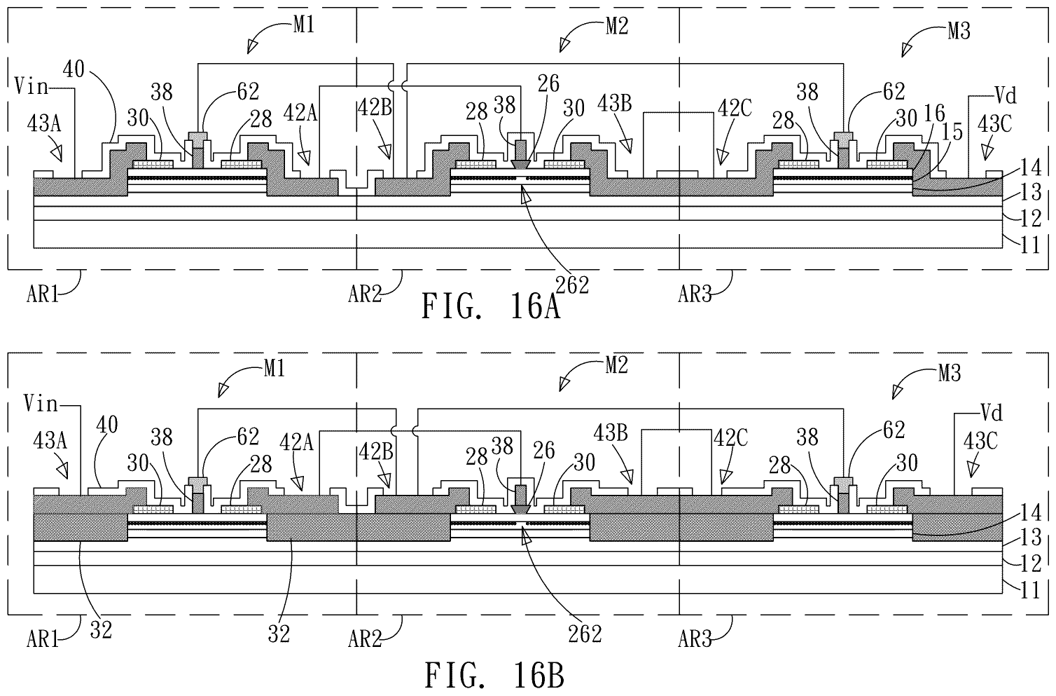

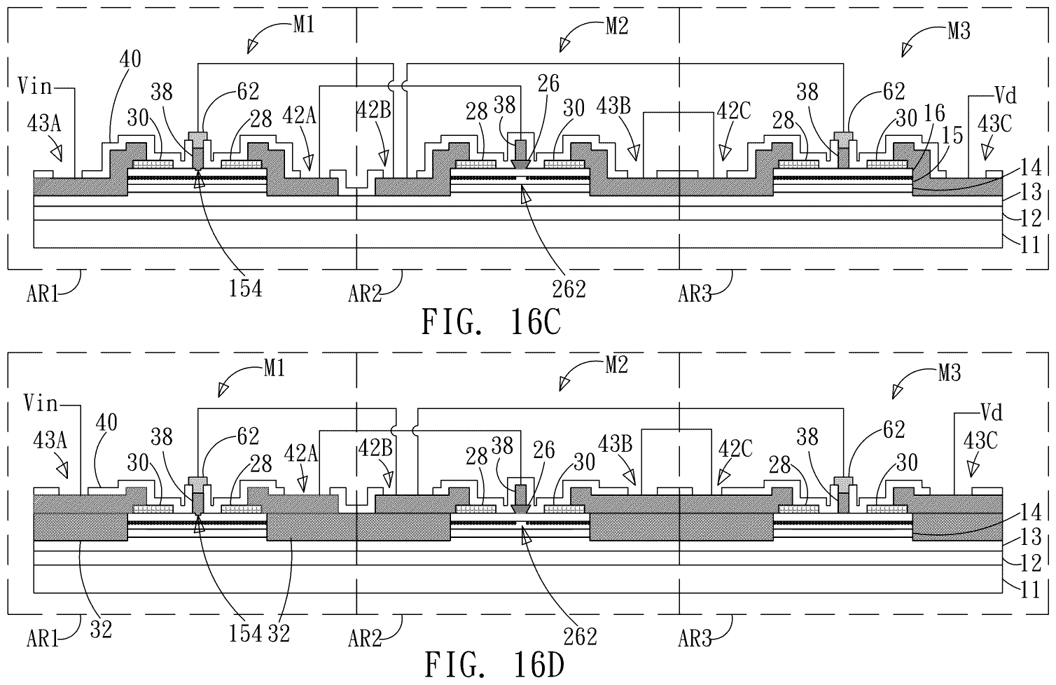

Embodiment 9: As shown in FIG. 16A and FIG. 16B, a hybrid type AlGaN/GaN HEMT device formed by a first D-mode AlGaN/GaN HEMT M1 without gate dielectric layer as the gate protection device and an SEG p-GaN gate E-mode AlGaN/GaN HEMT M2 cascoding to a second D-mode AlGaN/GaN HEMT M3 without gate dielectric layer.

A p-GaN gate E-mode AlGaN/GaN HEMT M2 usually exhibits slight Early effect, which means that the channel cannot be shut off completely and thus leading to increases of the current Ids as Vds increases when the device is operated in the saturation region with the gate voltage Vg fixed. The p-GaN gate E-mode AlGaN/GaN HEMT M2 cascoding to a second D-mode AlGaN/GaN HEMT M3 according to the present invention just may solve this problem.

As shown in FIG. 16A and FIG. 16B, the hybrid type AlGaN/GaN HEMT device according to Embodiment 7 comprises the AlGaN/GaN epitaxy structure designed according to the present invention and is divided into the first region AR1, the second region AR2, and a third region AR3. In the first region AR1, a first D-mode AlGaN/GaN HEMT M1 without gate dielectric layer is formed. In the second region AR2, an SEG p-GaN gate E-mode AlGaN/GaN HEMT M2 is formed. This SEG p-GaN gate E-mode AlGaN/GaN HEMT M2 includes a p-GaN inverted-trapezoidal gate structure 26. In addition, although the 2DEG is formed in the i-GaN channel layer 15 at the junction between the i-AlₓGaN layer 16 and the i-GaN channel layer 15, due to the existence of the p-GaN inverted-trapezoidal gate structure 26, the 2DEG below the p-GaN inverted-trapezoidal gate structure 26 in the i-GaN channel layer 15 will be depleted, giving a depletion region 262 without 2DEG below the p-GaN inverted-trapezoidal gate structure 26. In the third region AR3, a second D-mode AlGaN/GaN HEMT M3 without gate dielectric layer is formed.

According to the present embodiment, the first drain bonding pad region 43A is connected to the input voltage Vin. The second drain bonding pad region 43B is connected to the third source bonding pad region 42C. The third drain bonding pad region 43C is connected to the drain voltage Vd. The first source bonding pad region 42A is connected to the gate metal 38 and the p-GaN inverted-trapezoidal gate structure 26 of the p-GaN gate E-mode AlGaN/GaN HEMT M2. The second source bonding pad region 42B is connected to the gate field-plate metal 62 of the first D-mode AlGaN/GaN HEMT M1.

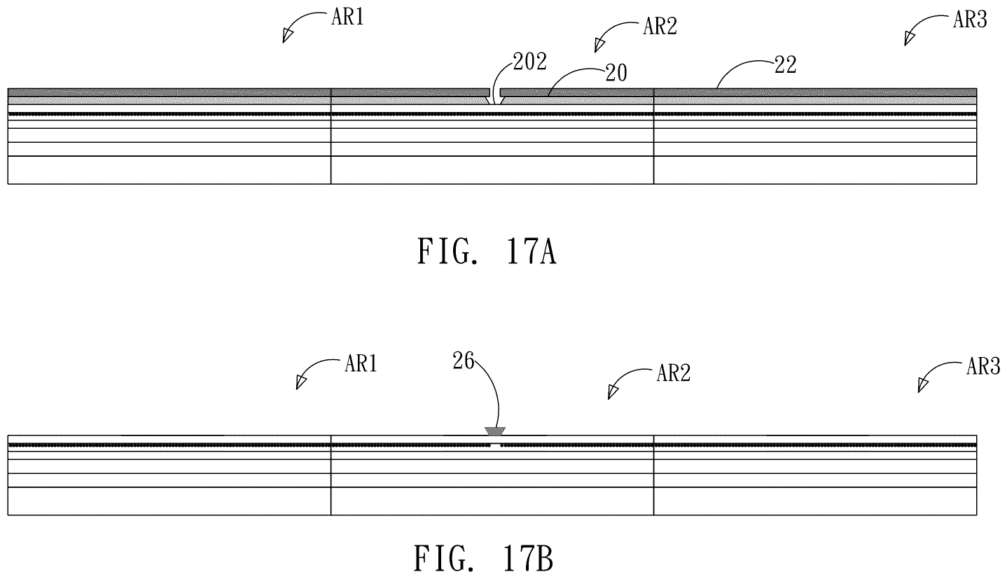

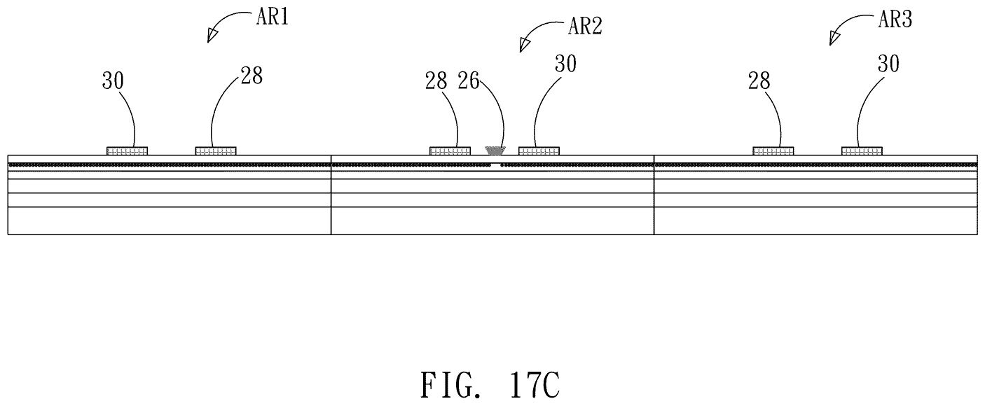

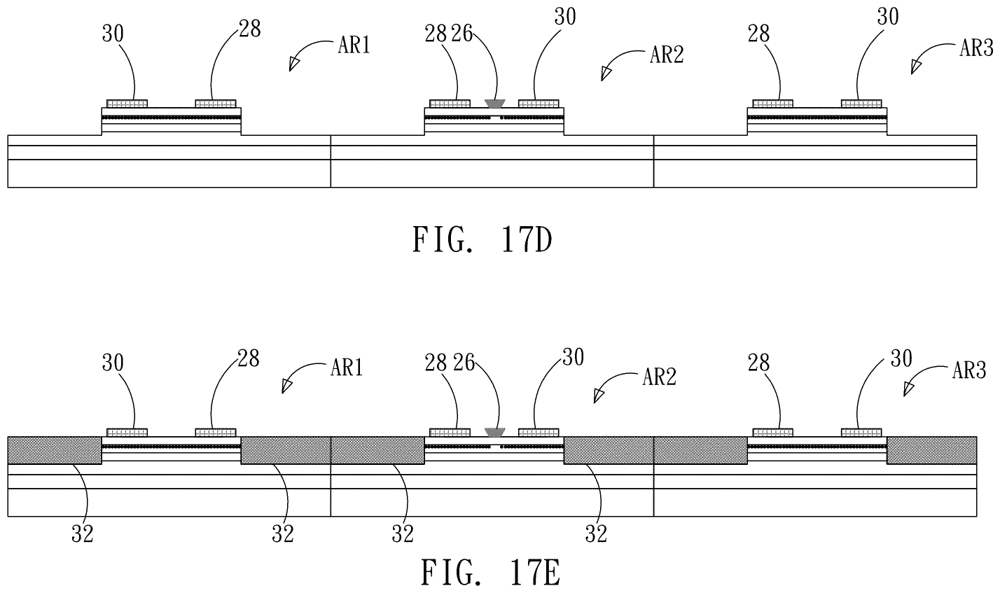

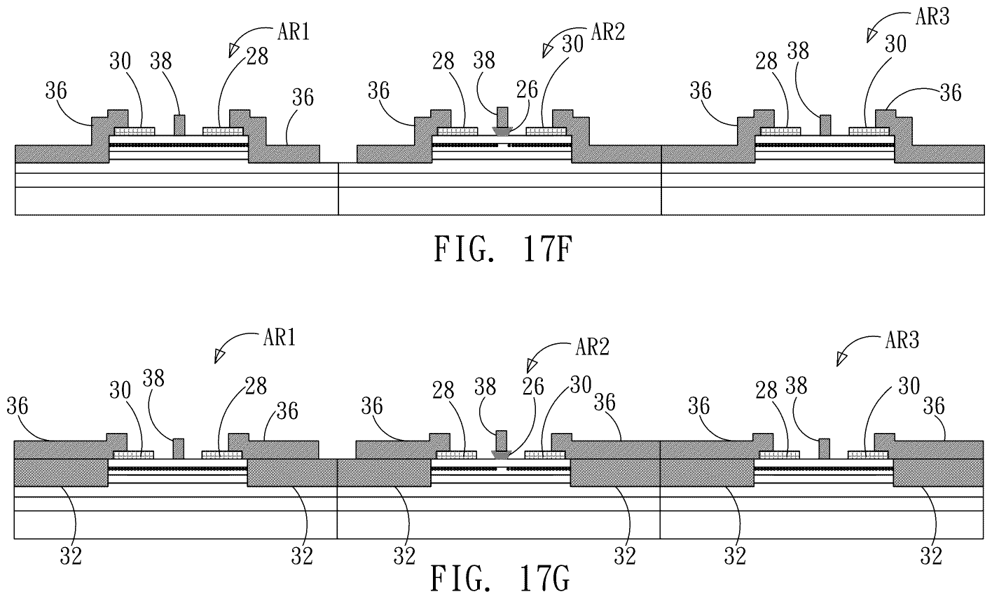

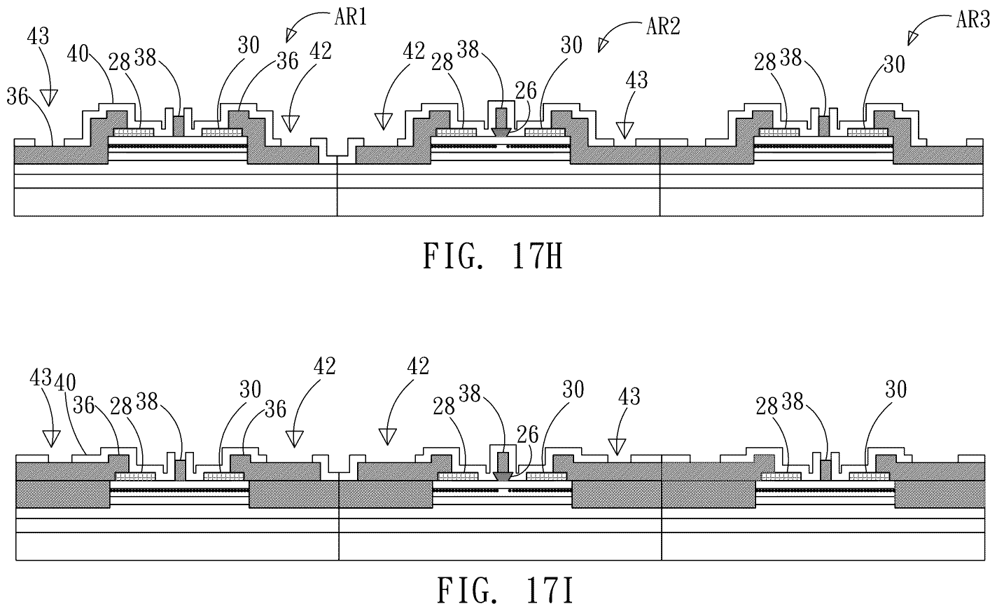

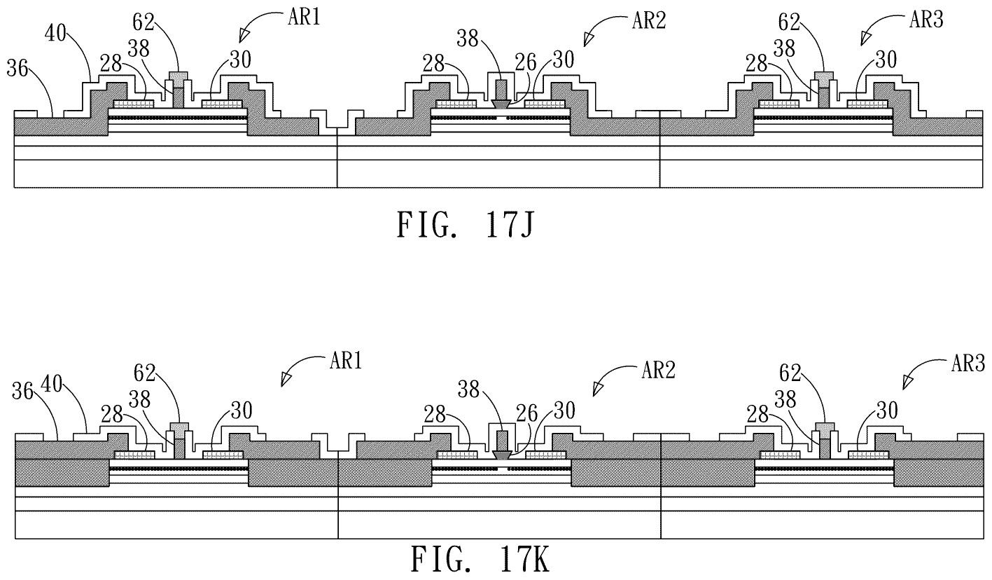

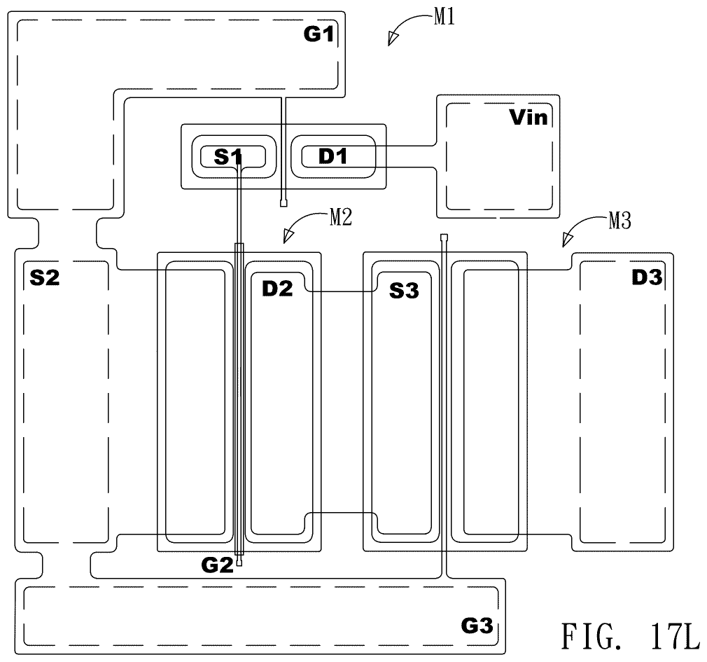

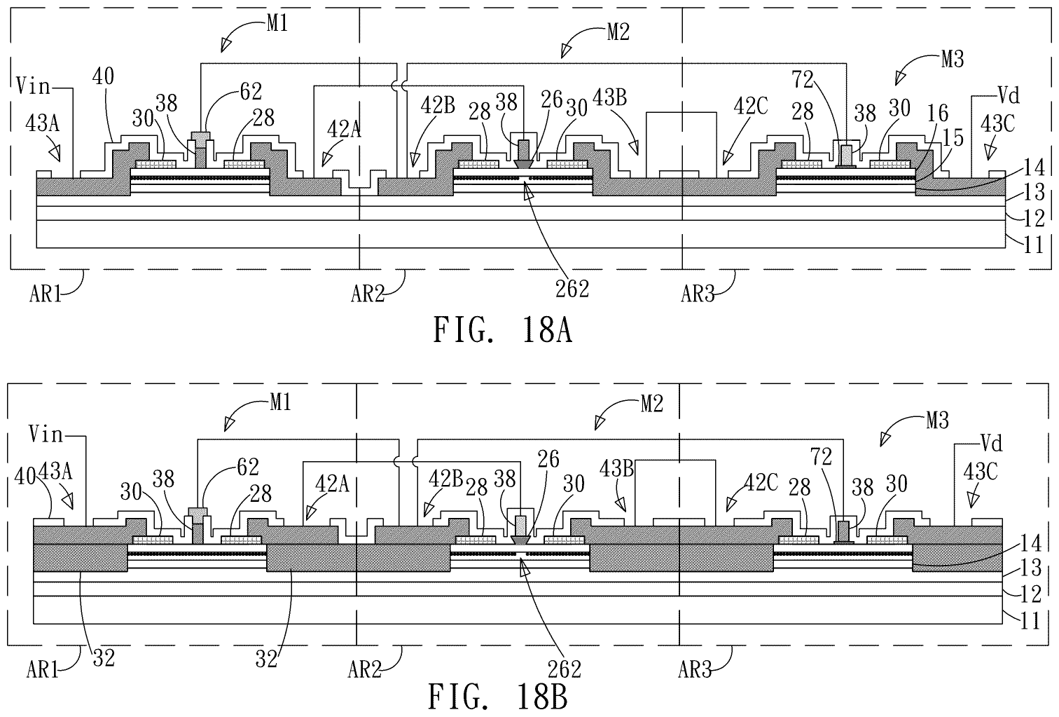

The process for fabricating Embodiment 9 will be described as follows. First, as shown in FIG. 17A, a Ga-face AlGaN/GaN epitaxy structure according to the present invention is provided. The first region ARI is set to fabricate the first D-mode AlGaN/GaN HEMT M1 without gate dielectric layer. The second region AR2 is set to fabricate the SEG p-GaN gate E-mode AlGaN/GaN HEMT M2. The third region AR3 on the right side is set to fabricate the second D-mode AlGaN/GaN HEMT M3 without gate dielectric layer. Next, as described in the previous fabrication method and shown in FIG. 17B, form a patterned silicon dioxide mask layer 20 having an inverted-trapezoidal-structure opening 24 on the Ga-face AlGaN/GaN epitaxy structure for defining the region for the SEG gate. The thickness of this silicon dioxide mask layer 20 is around 100 to 200 nm. Then, p-GaN is grown in the inverted-trapezoidal-structure opening 24 and forming a p-GaN inverted-trapezoidal gate structure 26. Afterwards, the patterned silicon dioxide mask layer 20 is removed. Then, as described above, because the p-GaN SEG region occupies only a small portion of the whole Ga-face AlGaN/GaN epitaxy structure, the p-type doping concentration in the p-GaN will be equal to ⅓ to ¼ of the expected.

Then, use the metal vapor deposition and metal lift-off methods to form the drain and source ohmic contacts 30, 28. Afterwards, a thermal treatment is performed at 700˜900° C. for 30 seconds to form the drain and source ohmic contacts ohmic contacts 28, 30, as shown in FIG. 17C.

Next, use the destructive ion implantation as shown in FIG. 17D or the dry etching to the highly resistive C-doped i-GaN buffer layer 13 as shown in FIG. 17E to isolate devices.

Afterwards, as shown in FIG. 17F and FIG. 17G, use the metal vapor deposition and metal lift-off methods to form the gate metal 38, the bonding pad regions 42, 43 for the source and drain ohmic contacts 28, 30, or the interconnection metal 36. Alternatively, in this step, the gate bonding pad region coupled electrically with the gate metal 38 may be formed concurrently, as the structures G1, G2 shown in FIG. 17L.

Then, a passivation layer 40 is grown by PECVD. The material may be SiOx, SiOxNy, or SiNx. Finally, the passivation layer 40 is patterned for exposing the bonding pad regions 42, 43 and the region above the gate metal 38 of the first D-mode HEMT M1 without gate dielectric layer, and thus forming the structures shown in FIG. 17H and FIG. 17I.

Finally, the metal vapor deposition and metal left-off methods are adopted to form the gate field-plate metal 62 of the first D-mode AlGaN/GaN HEMT M1 without gate dielectric layer in the first region AR1 and the second D-mode AlGaN/GaN HEMT M3 without gate dielectric layer in the third region AR3, as shown in the final structure in FIG. 17J and FIG. 17K.

Embodiment 10: As shown in FIG. 16C and FIG. 16D, the present provides a hybrid type AlGaN/GaN HEMT device formed by a first D-mode AlGaN/GaN HEMT M1 with a gate AlGaN micro-etched structure 154 and without gate dielectric layer as the gate protection device and an SEG p-GaN gate E-mode AlGaN/GaN HEMT cascoding to a second D-mode AlGaN/GaN HEMT M3 without gate dielectric layer. The gate AlGaN micro-etched structure 154 is mainly used to create positive shift of the threshold voltage Vth of the first D-mode AlGaN/GaN HEMT M1 without gate dielectric layer.

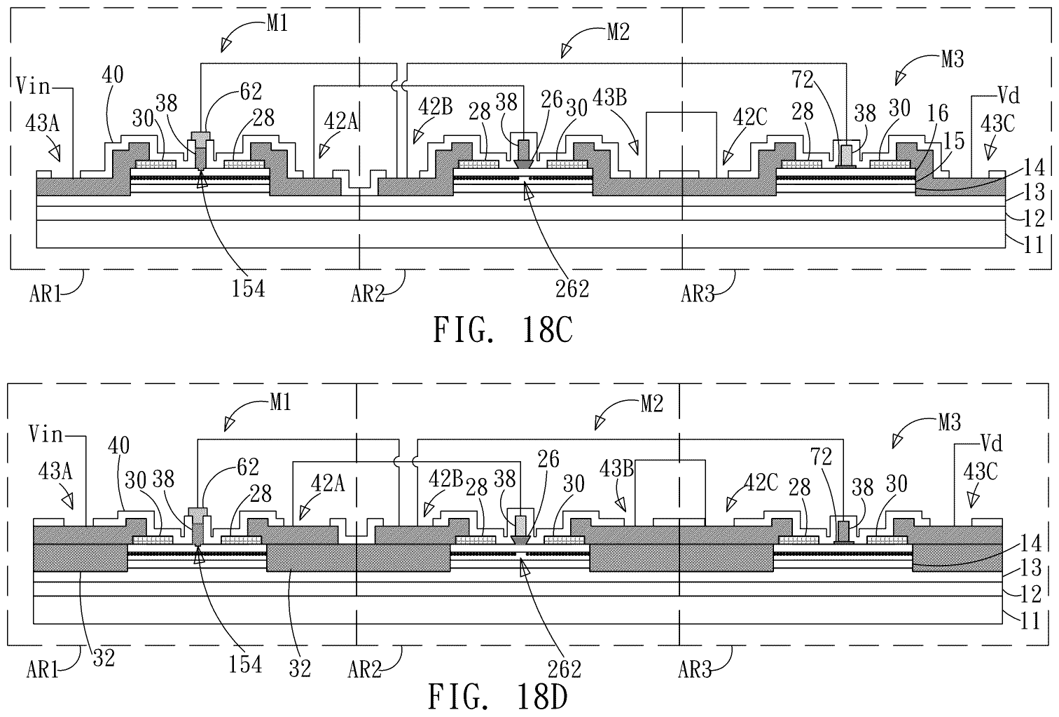

Embodiment 11: As shown in FIG. 18A and FIG. 18B, the present invention provides a hybrid type AlGaN/GaN HEMT device formed by the first D-mode AlGaN/GaN HEMT M1 without gate dielectric layer as the gate protection device and the SEG p-GaN gate E-mode AlGaN/GaN HEMT M2 cascoding to the second D-mode AlGaN/GaN HEMT M3 with the gate dielectric layer 72.

As shown in FIG. 18A and FIG. 18B, the hybrid type AlGaN/GaN HEMT device according to Embodiment 11 comprises the AlGaN/GaN epitaxy structure designed according to the present invention and is divided into the first region AR1, the second region AR2, and a third region AR3. In the first region AR1, a first D-mode AlGaN/GaN HEMT M1 without gate dielectric layer is formed. In the second region AR2, an SEG p-GaN gate E-mode AlGaN/GaN HEMT M2 is formed. This SEG p-GaN gate E-mode AlGaN/GaN HEMT M2 includes a p-GaN inverted-trapezoidal gate structure 26. In addition, although the 2DEG is formed in the i-GaN channel layer 15 at the junction between the i-AlₓGaN layer 16 and the i-GaN channel layer 15, due to the existence of the p-GaN inverted-trapezoidal gate structure 26, the 2DEG below the p-GaN inverted-trapezoidal gate structure 26 in the i-GaN channel layer 15 will be depleted, giving a depletion region 262 without 2DEG below the p-GaN inverted-trapezoidal gate structure 26. In the third region AR3, a second D-mode AlGaN/GaN HEMT M3 with the gate dielectric layer 72 is formed. The drain of the p-GaN gate E-mode AlGaN/GaN HEMT M2 cascode to the source S3 of the second D-mode AlGaN/GaN HEMT M3.

The first process steps of Embodiment 11 are identical to those shown in FIG. 17A to FIG. 17C for Embodiment 7. Hence, the details will not be repeated.

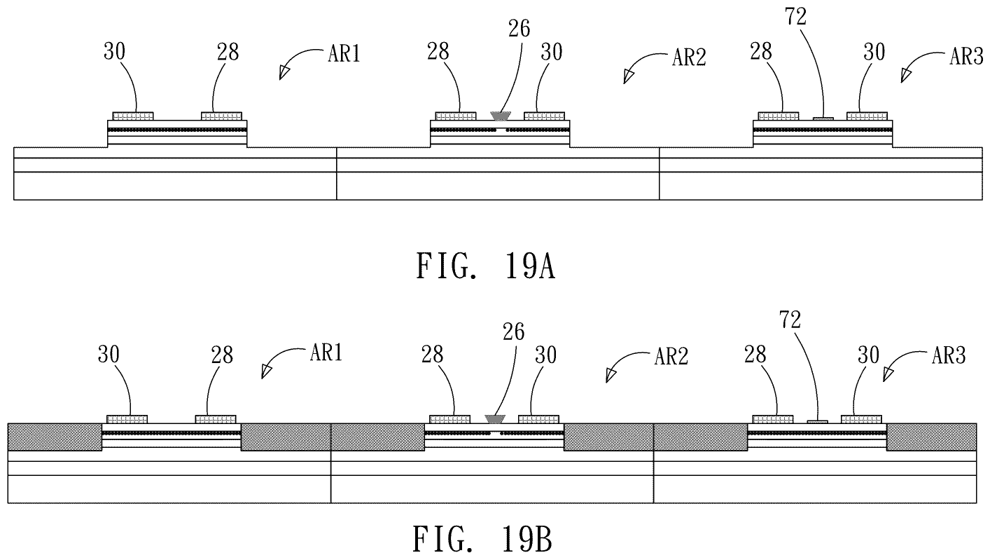

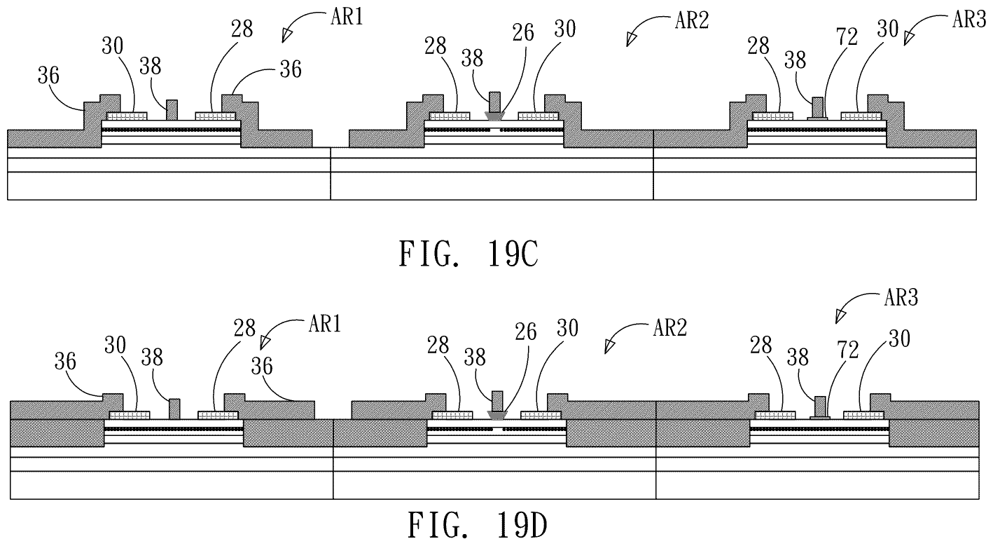

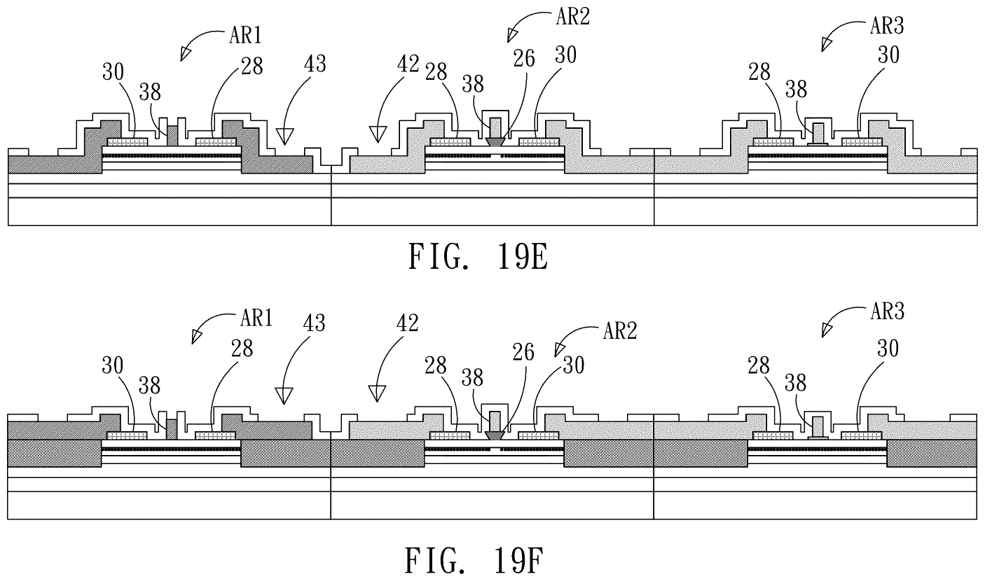

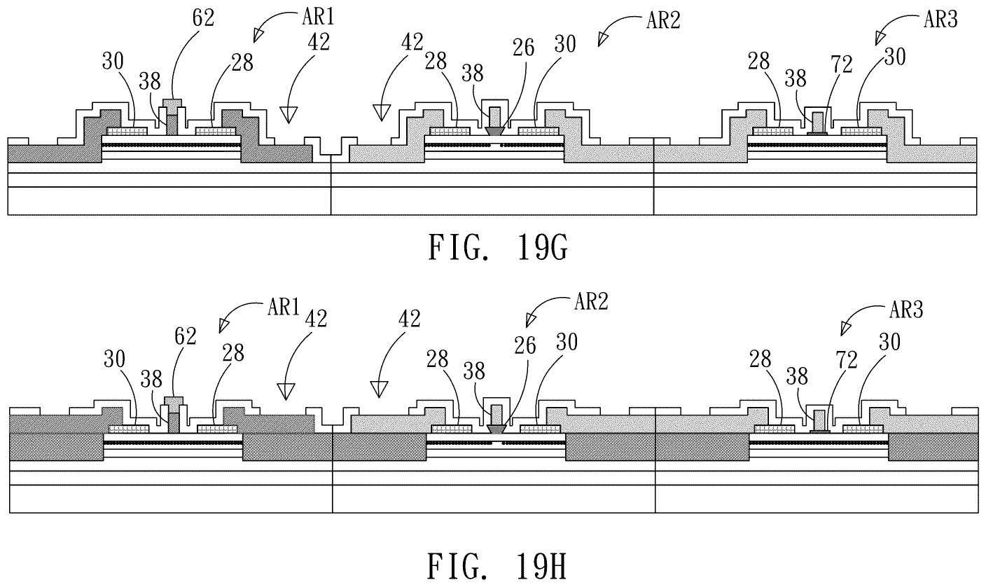

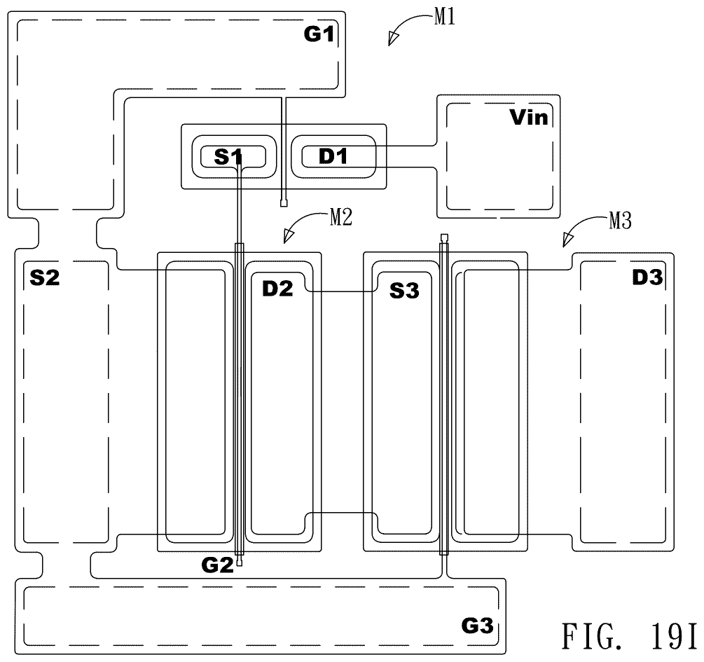

Step S114: The gate dielectric layer 72 for the second D-mode AlGaN/GaN HEMT M3 with the gate dielectric layer 72 in the third region AR3 is fabricated. A dielectric layer is deposited by PECVD. The material may be SiOx, SiOxNy, or SiNx; the thickness is 10 to 100 nm. Then, define the region of the gate dielectric layer 72 for the second D-mode AlGaN/GaN HEMT M3 by using photoresist and exposure method. Finally, the dielectric layer outside the region of the gate dielectric layer 72 is etched by the wet etching method using BOE; only the dielectric layer in the region of the gate dielectric layer 72 is reserved. Afterwards, the photoresist is stripped using stripper and forming the structure shown in FIG. 19A and FIG. 19B.

Step S115: Use the metal vapor deposition (normally Ni/Au) and metal lift-off methods to form the gate metal 38, the bonding pad regions for the drain and source, and the interconnection metal layer 36, as the structures shown in FIG. 19C and FIG. 19D. In addition, in this step, the metal wiring required for device operations may be formed concurrently. For example, the gate bonding pad region connected electrically with the gate metal 38 may be formed concurrently, as the gates G1, G2 shown in FIG. 191. Nonetheless, the present invention is not limited to the top views of the present invention.

Step S116: A passivation layer 40 is grown by PECVD. The material may be SiOx, SiOxNy, or SiNx. Finally, the passivation layer 40 is patterned for etching and exposing the bonding pad regions and the region above the gate metal of the first D-mode AlGaN/GaN HEMT M1 without gate dielectric layer in the first region AR1, and thus forming the structure shown in FIG. 19E and FIG. 19F.

Step S117: Finally, the metal vapor deposition and metal left-off methods are adopted to form the gate field-plate metal 62 of the first D-mode AlGaN/GaN HEMT M1 without gate dielectric layer in the first region AR1, as shown in the final structure in FIG. 19G and FIG. 19H.

Embodiment 12: As shown in FIG. 18C and FIG. 18D, the present provides a hybrid type AlGaN/GaN HEMT device formed by a first D-mode AlGaN/GaN HEMT M1 with a gate AlGaN micro-etched structure 154 and without gate dielectric layer as the gate protection device and an SEG p-GaN gate E-mode AlGaN/GaN HEMT M2 cascoding to a second D-mode AlGaN/GaN HEMT M3 with the gate dielectric layer 72. The gate AlGaN micro-etched structure 154 is mainly used to create positive shift of the threshold voltage Vth of the first D-mode AlGaN/GaN HEMT M1 without gate dielectric layer.

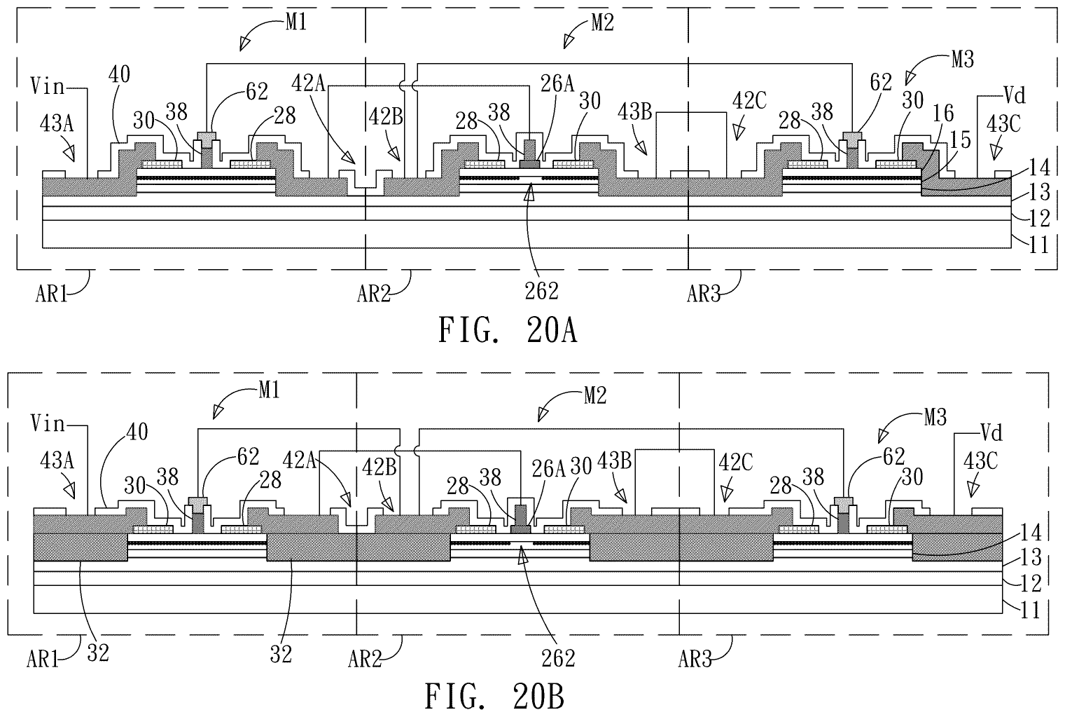

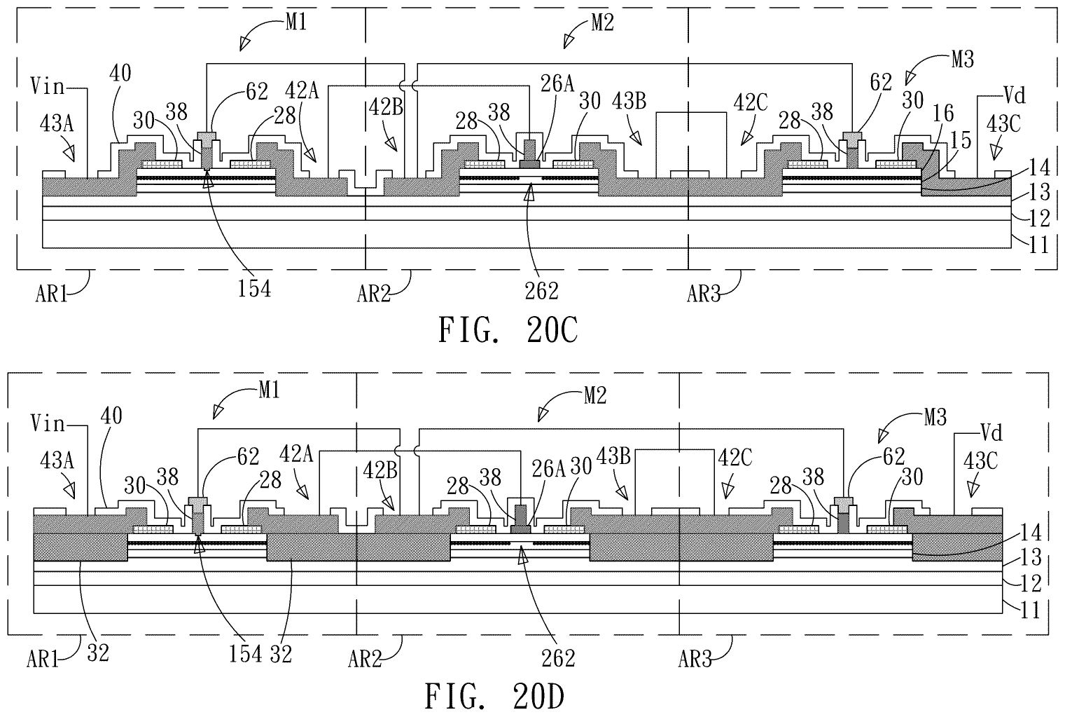

Embodiment 13: As shown in FIG. 20A and FIG. 20B, a hybrid type AlGaN/GaN HEMT device formed by a first D-mode AlGaN/GaN HEMT M1 without gate dielectric layer as the gate protection device and a p-GaN etched gate E-mode AlGaN/GaN HEMT M2 cascoding to a second D-mode AlGaN/GaN HEMT M3 without gate dielectric layer.

As shown in FIG. 20A and FIG. 20B, the hybrid type AlGaN/GaN HEMT device according to Embodiment 13 comprises the AlGaN/GaN epitaxy structure designed according to the present invention and is divided into the first region AR1, the second region AR2, and the third region AR3. In the first region AR1, a first D-mode AlGaN/GaN HEMT M1 without gate dielectric layer is formed. In the second region AR2, a p-GaN etched gate E-mode AlGaN/GaN HEMT M2 is formed. This p-GaN etched gate E-mode AlGaN/GaN HEMT M2 includes a p-GaN etched gate structure 26A. In addition, although the 2DEG is formed in the i-GaN channel layer 15 at the junction between the i-AlₓGaN layer 16 and the i-GaN channel layer 15, due to the existence of the p-GaN etched gate structure 26A, the 2DEG below the p-GaN inverted-trapezoidal gate structure 26 in the i-GaN channel layer 15 will be depleted, giving a depletion region 262 without 2DEG below the p-GaN etched gate structure 26A. In the third region AR3, a second D-mode AlGaN/GaN HEMT M3 without gate dielectric layer is formed.

Embodiment 14: As shown in FIG. 20C and FIG. 20D, the present provides a hybrid type AlGaN/GaN HEMT device formed by a first D-mode AlGaN/GaN HEMT M1 with a gate AlGaN micro-etched structure 154 and without gate dielectric layer as the gate protection device and a p-GaN etched gate E-mode AlGaN/GaN HEMT cascoding to a second D-mode AlGaN/GaN HEMT M3 with the gate dielectric layer 72. The gate AlGaN micro-etched structure 154 is mainly used to create positive shift of the threshold voltage Vth of the first D-mode AlGaN/GaN HEMT M1 without gate dielectric layer.

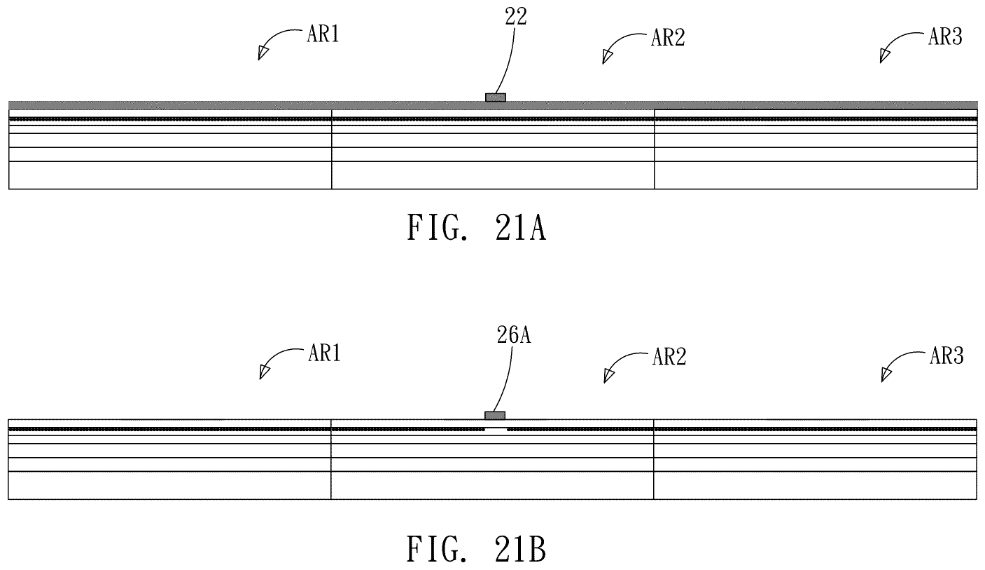

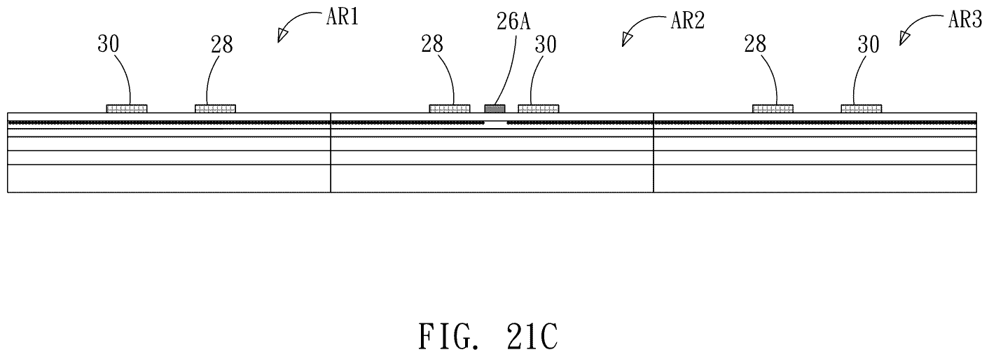

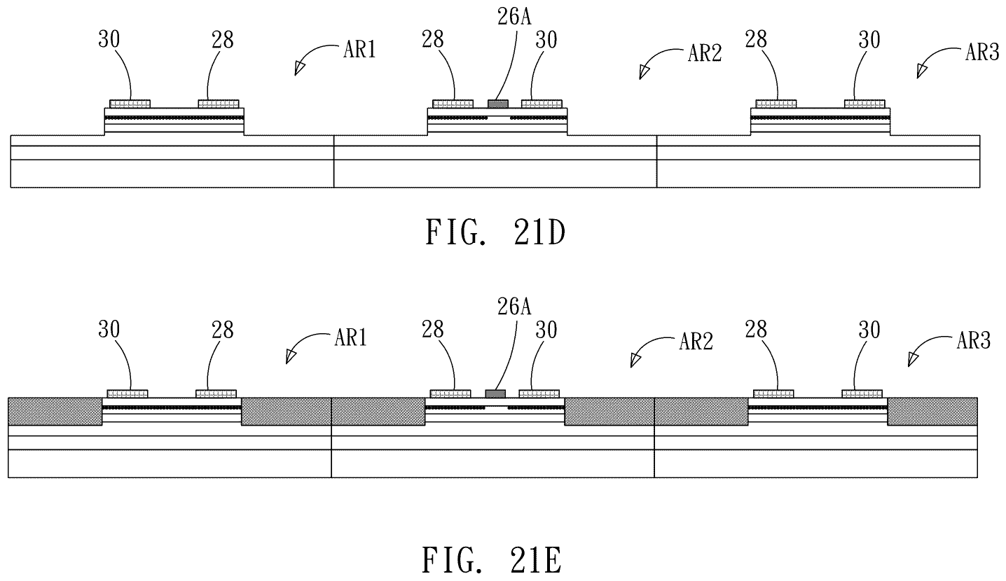

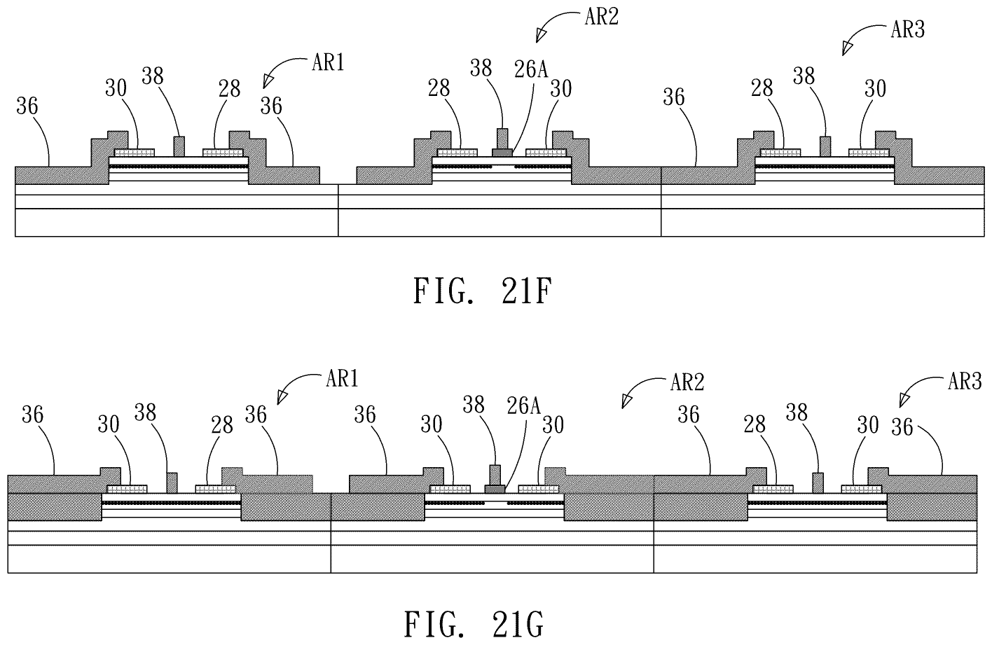

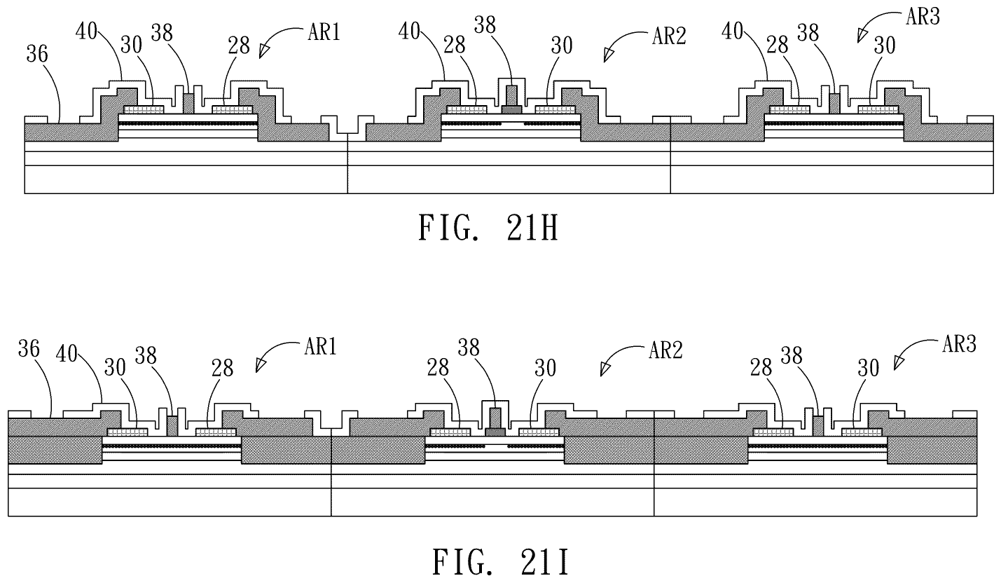

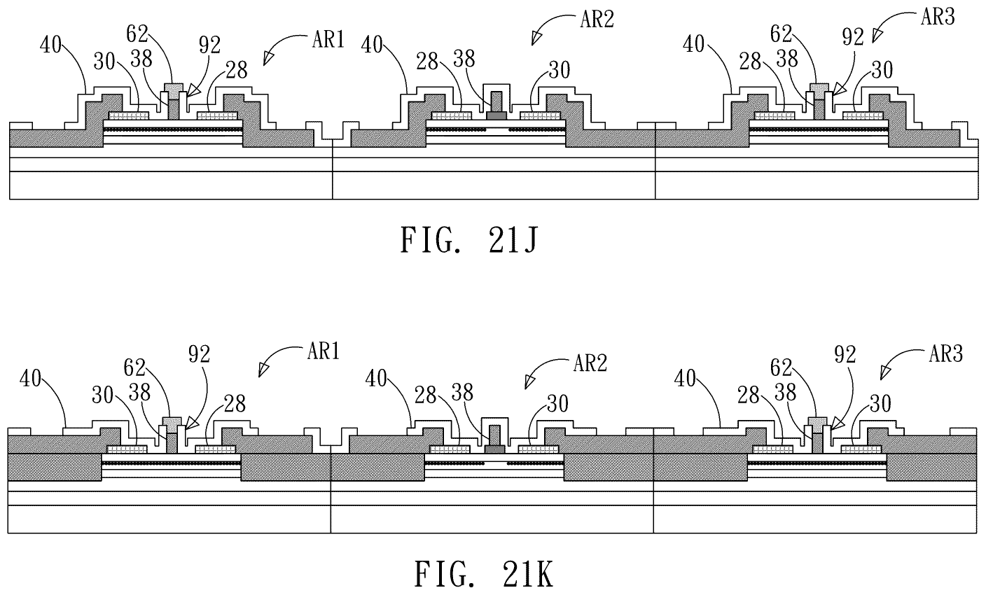

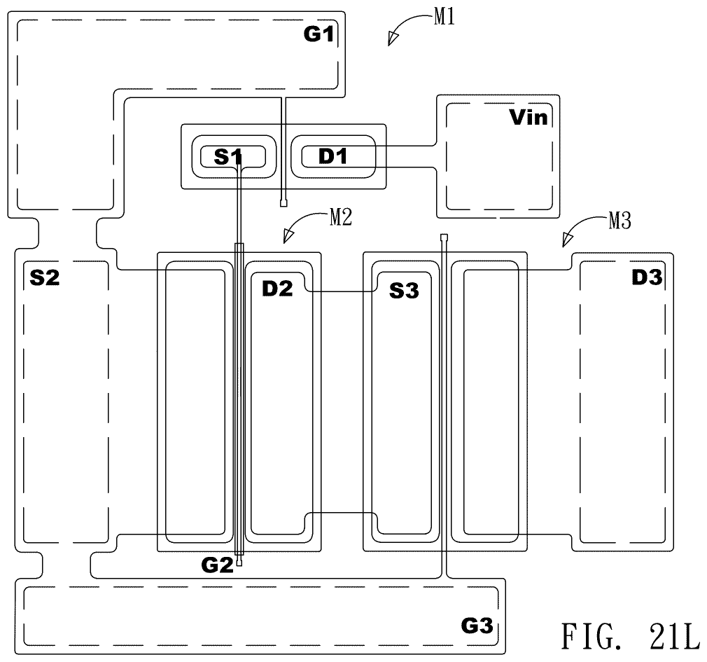

The process for fabricating Embodiment 13 will be described as follows. First, as shown in FIG. 21A, a Ga-face AlGaN/GaN epitaxy structure according to the present invention is provided. The first region AR1 is set to fabricate the first D-mode AlGaN/GaN HEMT without gate dielectric layer. The second region AR2 is set to fabricate the p-GaN etched gate E-mode AlGaN/GaN HEMT. The third region AR3 on the right side is set to fabricate the second D-mode AlGaN/GaN HEMT without gate dielectric layer.

Step S91: Fabricate the p-GaN etched gate structure 26A. First, as shown in FIG. 21A, a p-GaN layer is grown on the Ga-face AlGaN/GaN epitaxy structure according to the present invention using MOCVD. Next, define the p-GaN gate region by using the photoresist 22 and the exposure method. Finally, dry etching is adopted to etch the p-GaN outside the region to the AlGaN blocking layer of the Ga-face AlGaN/GaN epitaxy structure according to the present invention. Then, the photoresist 22 is stripped using stripper. Thereby, the p-GaN etched gate structure 26A is fabricated.

Step S92: Use the metal vapor deposition and metal lift-off methods to form the drain and source ohmic contacts 30, 28. Afterwards, a thermal treatment is performed at 700˜900° C. for 30 seconds to form the drain and source ohmic contacts ohmic contacts 28, 30, as shown in FIG. 21C.

Step S93: Use the destructive ion implantation as shown in FIG. 21 D or the dry etching to the highly resistive C-doped i-GaN buffer layer 13 as shown in FIG. 21E to isolate devices.

Step S94: As shown in FIG. 21F and FIG. 21G, use the metal vapor deposition and metal lift-off methods to form the gate metal 38, the bonding pad regions for the source and drain, or the interconnection metal 36. Alternatively, in this step, the gate bonding pad region coupled electrically with the gate metal 38 may be formed concurrently, as the structures G1, G2 shown in FIG. 21L.

Then, a passivation layer 40 is grown by PECVD. The material may be SiOx, SiOxNy, or SiNx. Finally, the passivation layer 40 is patterned for exposing the bonding pad regions 42, 43 and the region above the gate metal 38 of the first D-mode HEMT M1 without gate dielectric layer, and thus forming the structures shown in FIG. 21H and FIG. 21I.

Step S95: Finally, the metal vapor deposition and metal left-off methods are adopted to form the gate field-plate metal 62 of the first D-mode AlGaN/GaN HEMT M1 without gate dielectric layer, as shown in the final structure in FIG. 21J and FIG. 21K.

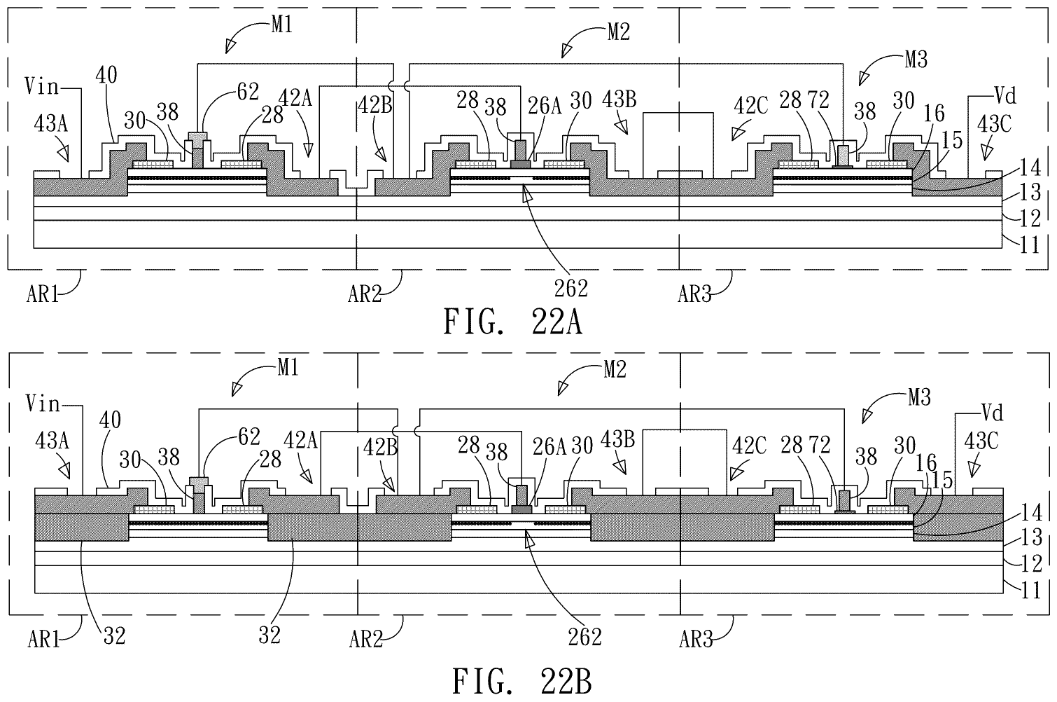

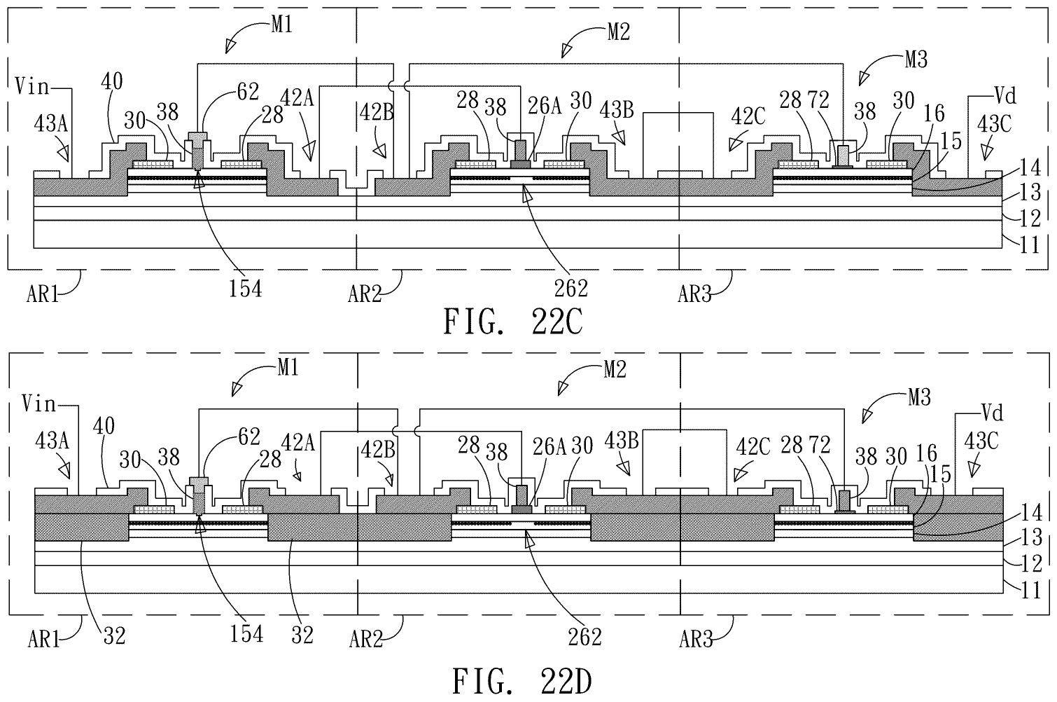

Embodiment 15: As shown in FIG. 22A and FIG. 22B, a hybrid type AlGaN/GaN HEMT device formed by a first D-mode AlGaN/GaN HEMT M1 without gate dielectric layer as the gate protection device and a p-GaN etched gate E-mode AlGaN/GaN HEMT M2 cascoding to a second D-mode AlGaN/GaN HEMT M3 with the gate dielectric layer 72.

As shown in FIG. 20A and FIG. 20B, the hybrid type AlGaN/GaN HEMT device according to Embodiment 13 comprises the AlGaN/GaN epitaxy structure designed according to the present invention and is divided into the first region AR1, the second region AR2, and the third region AR3. In the first region AR1, a first D-mode AlGaN/GaN HEMT M1 without gate dielectric layer is formed. In the second region AR2, a p-GaN etched gate E-mode AlGaN/GaN HEMT M2 is formed. This p-GaN etched gate E-mode AlGaN/GaN HEMT M2 includes a p-GaN etched gate structure 26A. In addition, although the 2DEG is formed in the i-GaN channel layer 15 at the junction between the i-AlₓGaN layer 16 and the i-GaN channel layer 15, due to the existence of the p-GaN etched gate structure 26A, the 2DEG below the p-GaN inverted-trapezoidal gate structure 26 in the i-GaN channel layer 15 will be depleted, giving a depletion region 262 without 2DEG below the p-GaN etched gate structure 26A. In the third region AR3, a second D-mode AlGaN/GaN HEMT M3 with the gate dielectric layer 72 is formed. The drain D2 of the p-GaN gate E-mode AlGaN/GaN HEMT M2 cascode to the source S3 and the gate G3 of the second D-mode AlGaN/GaN HEMT M3, as shown in FIG. 15B.

The first process steps of Embodiment 10 are identical to those shown in FIG. 21A to FIG. 21C for Embodiment 9. Hence, the details will not be repeated.

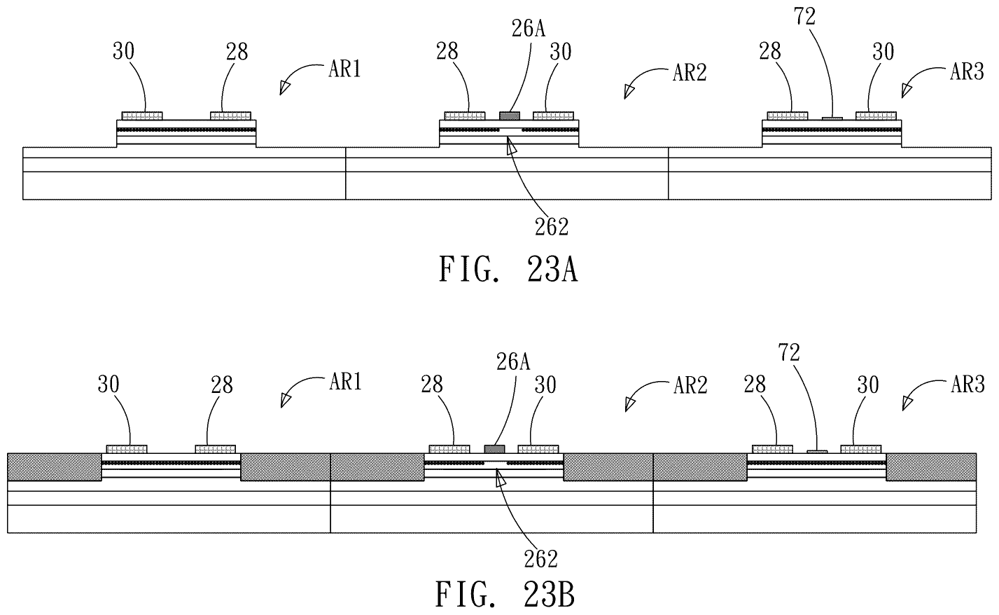

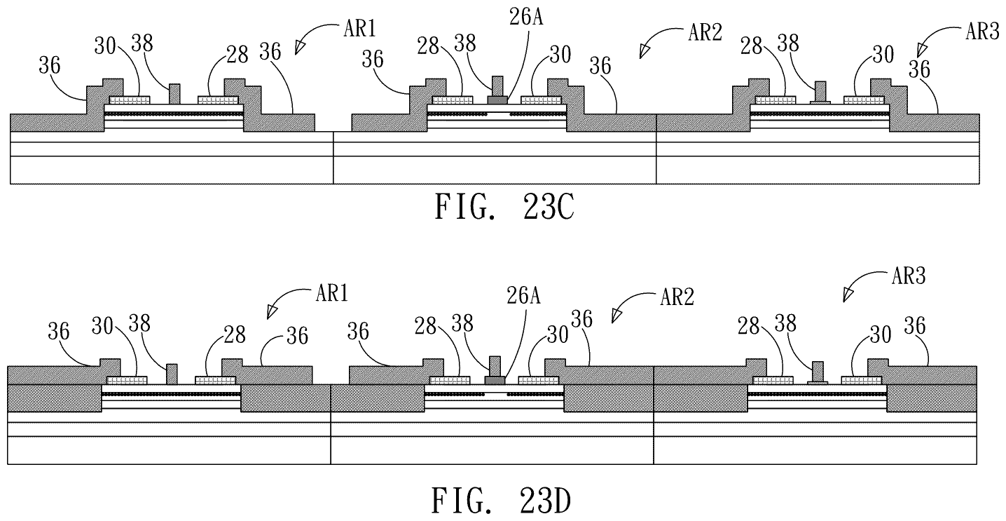

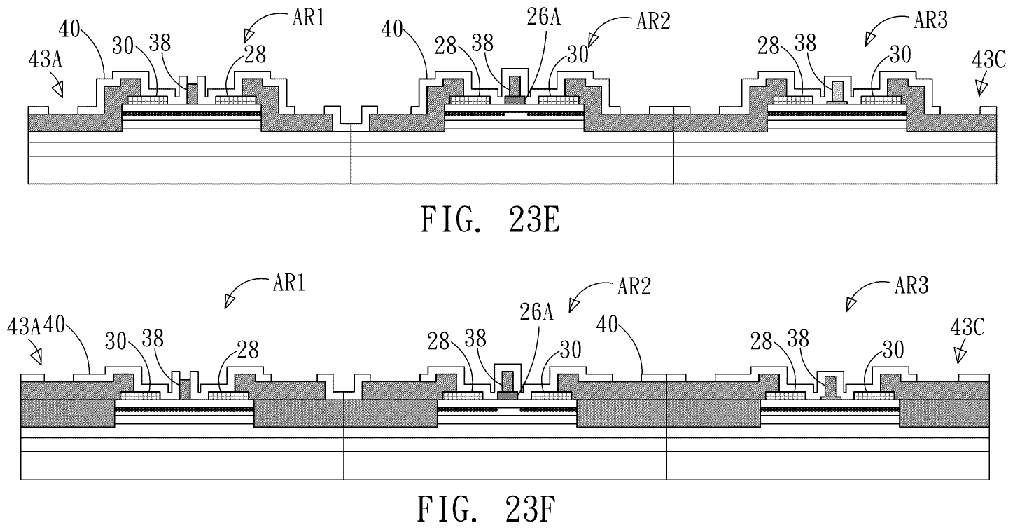

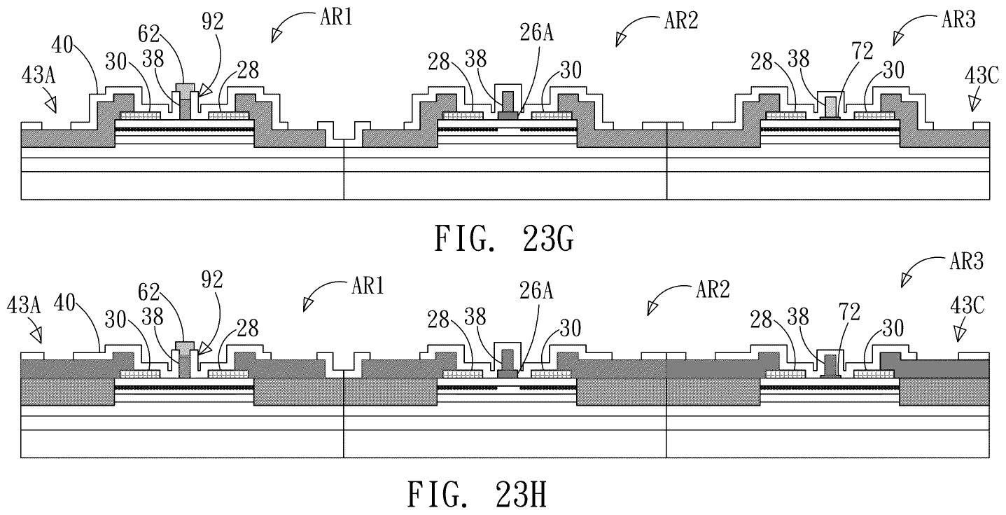

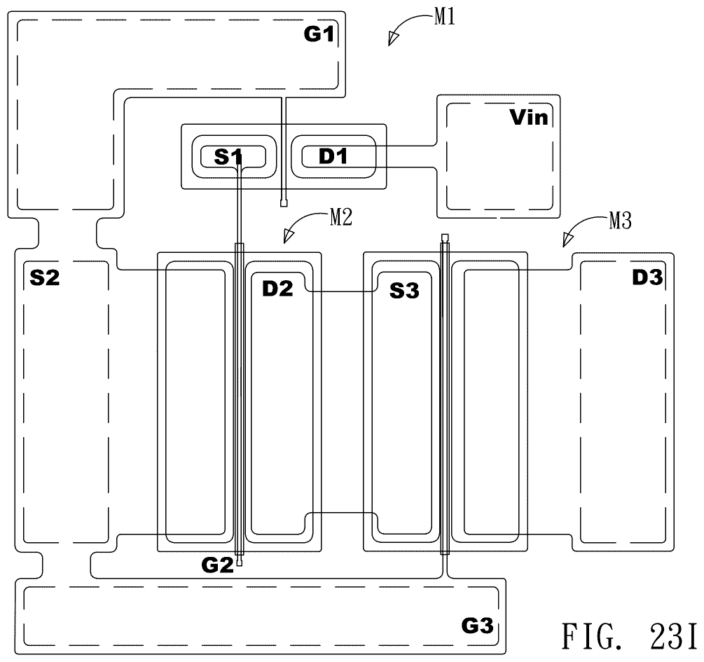

Step S154: The gate dielectric layer 72 for the second D-mode AlGaN/GaN HEMT M3 with the gate dielectric layer 72 in the third region AR3 is fabricated. A dielectric layer is deposited by PECVD. The material may be SiOx, SiOxNy, or SiNx; the thickness is 10 to 100 nm. Then, define the region of the gate dielectric layer 72 for the second D-mode AlGaN/GaN HEMT M3 by using photoresist and exposure method. Finally, the dielectric layer outside the region of the gate dielectric layer 72 is etched by the wet etching method using BOE; only the dielectric layer in the region of the gate dielectric layer 72 is reserved. Afterwards, the photoresist is stripped using stripper and forming the structure shown in FIG. 23A and FIG. 23B.

Step S155: Use the metal vapor deposition (normally Ni/Au) and metal lift-off methods to form the gate metal 38, the bonding pad regions for the drain and source, and the interconnection metal layer 36, as the structures shown in FIG. 23C and FIG. 23D. In addition, in this step, the metal wiring required for device operations may be formed concurrently. For example, the gate bonding pad region connected electrically with the gate metal 38 may be formed concurrently, as the structure shown in FIG. 23I. Nonetheless, the present invention is not limited to the top views of the present invention.

Step S156: A passivation layer 40 is grown by PECVD. The material may be SiOx, SiOxNy, or SiNx. Finally, the passivation layer 40 is patterned for etching and exposing the bonding pad regions 42, 43 and the region above the gate metal of the first D-mode AlGaN/GaN HEMT M1 without gate dielectric layer in the first region AR1, and thus forming the structure shown in FIG. 23E and FIG. 23F.

Step S157: Finally, the metal vapor deposition and metal left-off methods are adopted to form the gate field-plate metal 62 of the first D-mode AlGaN/GaN HEMT M1 without gate dielectric layer in the first region AR1, as shown in the final structure in FIG. 23G and FIG. 23H.

Embodiment 16: As shown in FIG. 22C and FIG. 22D, a hybrid type AlGaN/GaN HEMT device formed by the first D-mode AlGaN/GaN HEMT M1 with gate AlGaN micro-etched structure and without gate dielectric layer as the gate protection device and the p-GaN etched gate E-mode AlGaN/GaN HEMT M2 cascoding to the second D-mode AlGaN/GaN HEMT M3 with the gate dielectric layer 72.

As shown in FIG. 15C and FIG. 15D, the source S1 of the first D-mode AlGaN/GaN HEMT M1 without gate dielectric layer is connected to the gate G2 of the p-GaN etched gate E-mode AlGaN/GaN HEMT M2. The drain D2 of the p-GaN etched gate E-mode AlGaN/GaN HEMT M2 cascode to (1) a second D-mode AlGaN/GaN HEMT M3 without gate dielectric layer, or (2) a second D-mode AlGaN/GaN HEMT M3 with gate dielectric layer. The source S1 of the first D-mode AlGaN/GaN HEMT M1 without gate dielectric layer is connected to the gate G2 of the p-GaN etched gate E-mode AlGaN/GaN HEMT M2 by the fabrication method. The first D-mode AlGaN/GaN HEMT M1 acts as the gate protection device of the p-GaN etched gate E-mode AlGaN/GaN HEMT M2. The drain D2 of the p-GaN etched gate E-mode AlGaN/GaN HEMT M2 is connected electrically to the source S3 of the second D-mode AlGaN/GaN HEMT M3. The second D-mode AlGaN/GaN HEMT M3 is a D-mode HEMT without or with gate dielectric layer.

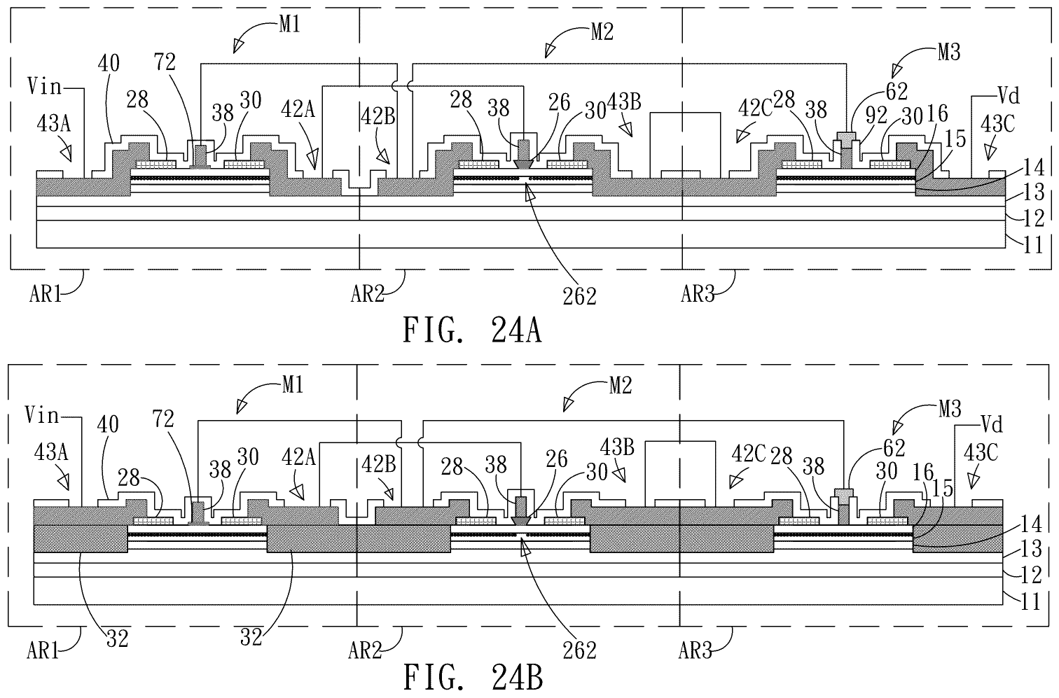

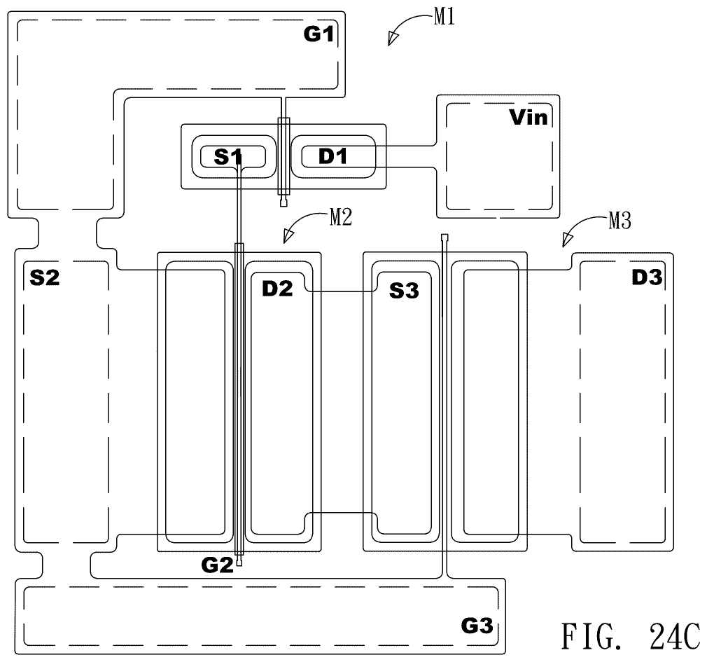

Embodiment 17: As shown in FIG. 24A and FIG. 24B, a hybrid type AlGaN/GaN HEMT device formed by the first D-mode AlGaN/GaN HEMT M1 with gate dielectric layer as the gate protection device and the SEG p-GaN gate E-mode AlGaN/GaN HEMT M2 cascoding to a second D-mode AlGaN/GaN HEMT M3 without gate dielectric layer.

As shown in FIG. 16A and FIG. 16B, the hybrid type AlGaN/GaN HEMT device according to Embodiment 7 comprises the AlGaN/GaN epitaxy structure designed according to the present invention and is divided into the first region AR1, the second region AR2, and the third region AR3. In the first region AR1, a first D-mode AlGaN/GaN HEMT M1 with gate dielectric layer is formed. In the second region AR2, an SEG p-GaN gate E-mode AlGaN/GaN HEMT M2 is formed. This SEG p-GaN gate E-mode AlGaN/GaN HEMT M2 includes a p-GaN inverted-trapezoidal gate structure 26. In addition, although the 2DEG is formed in the i-GaN channel layer 15 at the junction between the i-AlₓGaN layer 16 and the i-GaN channel layer 15, due to the existence of the p-GaN inverted-trapezoidal gate structure 26, the 2DEG below the p-GaN inverted-trapezoidal gate structure 26 in the i-GaN channel layer 15 will be depleted, giving a depletion region 262 without 2DEG below the p-GaN inverted-trapezoidal gate structure 26. In the third region AR3, a second D-mode AlGaN/GaN HEMT M3 without gate dielectric layer is formed. The source ohmic contact 28 of the second D-mode AlGaN/GaN HEMT M3 and the corresponding metal layer of the gate cascode to the corresponding metal layer of the p-GaN inverted-trapezoidal gate structure 26 of the p-GaN gate E-mode AlGaN/GaN HEMT M2.

The process steps as shown in FIG. 17A to FIG. 17K according to Embodiment 17 are identical to those according to Embodiment 9. The only difference is that between the steps of FIG. 17C and FIG. 17D, a step is added for fabricating the gate dielectric layer 72 of the first D-mode AlGaN/GaN HEMT M1 with the gate dielectric layer 72 in the first region AR1.

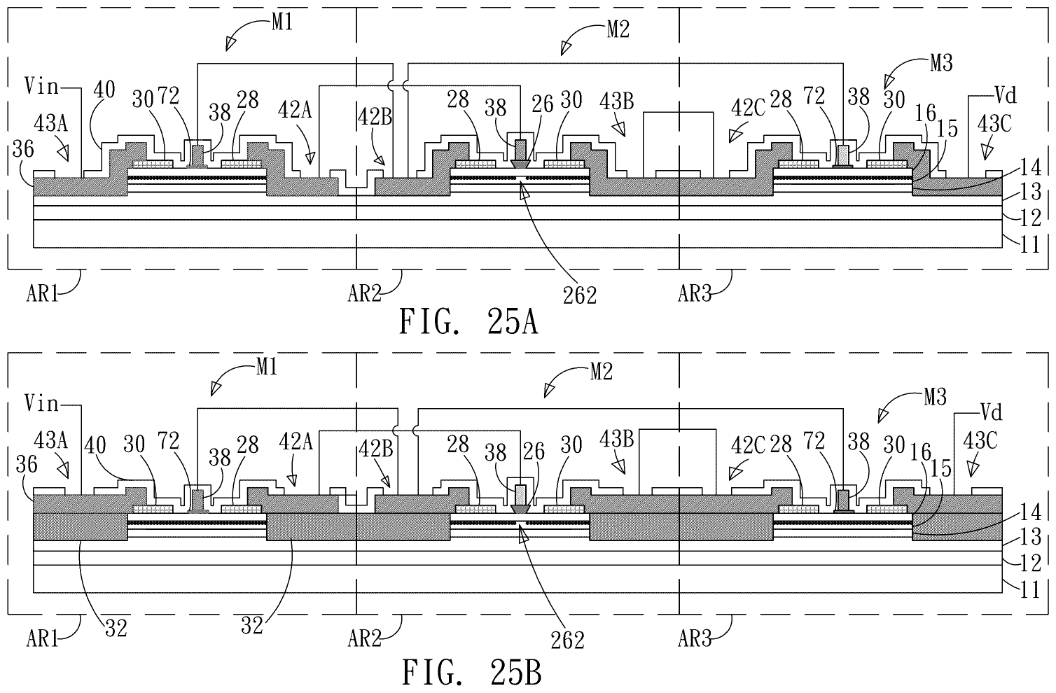

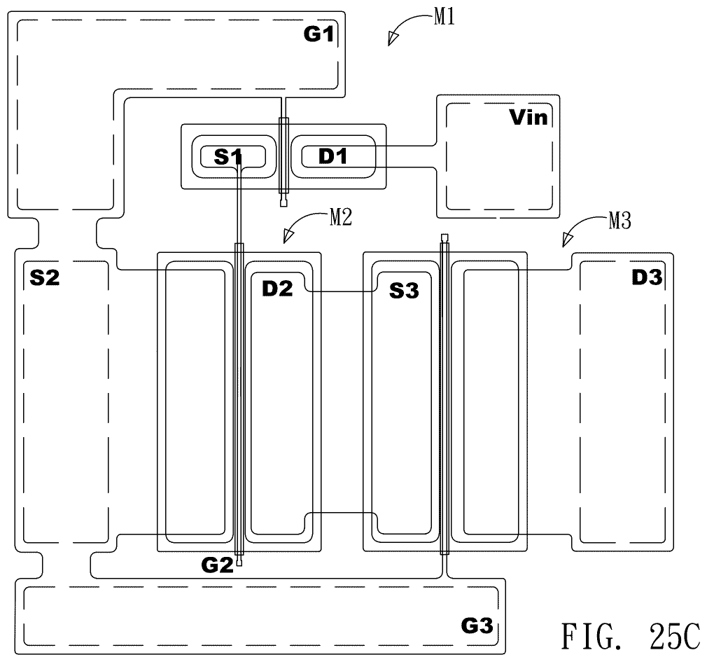

Embodiment 18: As shown in FIG. 25A and FIG. 25B, a hybrid type AlGaN/GaN HEMT device formed by the first D-mode AlGaN/GaN HEMT M1 with gate dielectric layer as the gate protection device and the SEG p-GaN gate E-mode AlGaN/GaN HEMT M2 cascoding to a second D-mode AlGaN/GaN HEMT M3 with the gate dielectric layer 72.

As shown in FIG. 25A and FIG. 25B, the hybrid type AlGaN/GaN HEMT device according to Embodiment 18 comprises the AlGaN/GaN epitaxy structure designed according to the present invention and is divided into the first region AR1, the second region AR2, and the third region AR3. In the first region AR1, a first D-mode AlGaN/GaN HEMT M1 with gate dielectric layer is formed. In the second region AR2, an SEG p-GaN gate E-mode AlGaN/GaN HEMT M2 is formed. This SEG p-GaN gate E-mode AlGaN/GaN HEMT M2 includes a p-GaN inverted-trapezoidal gate structure 26. In addition, although the 2DEG is formed in the i-GaN channel layer 15 at the junction between the i-AlₓGaN layer 16 and the i-GaN channel layer 15, due to the existence of the p-GaN inverted-trapezoidal gate structure 26, the 2DEG below the p-GaN inverted-trapezoidal gate structure 26 in the i-GaN channel layer 15 will be depleted, giving a depletion region 262 without 2DEG below the p-GaN inverted-trapezoidal gate structure 26. In the third region AR3, a second D-mode AlGaN/GaN HEMT M3 with the gate dielectric layer 72 is formed and cascoding to the p-GaN gate E-mode AlGaN/GaN HEMT M2.

The process steps as shown in FIG. 17A to FIG. 17K according to Embodiment 18 are identical to those according to Embodiment 9. The only difference is that between the steps of FIG. 17C and FIG. 17D, a step is added for fabricating the gate dielectric layer 72 of the first D-mode AlGaN/GaN HEMT M1 with the gate dielectric layer 72 in the first region ARI and the gate dielectric layer 72 of the second D-mode AlGaN/GaN HEMT M3 with the gate dielectric layer 72 in the third region AR3.

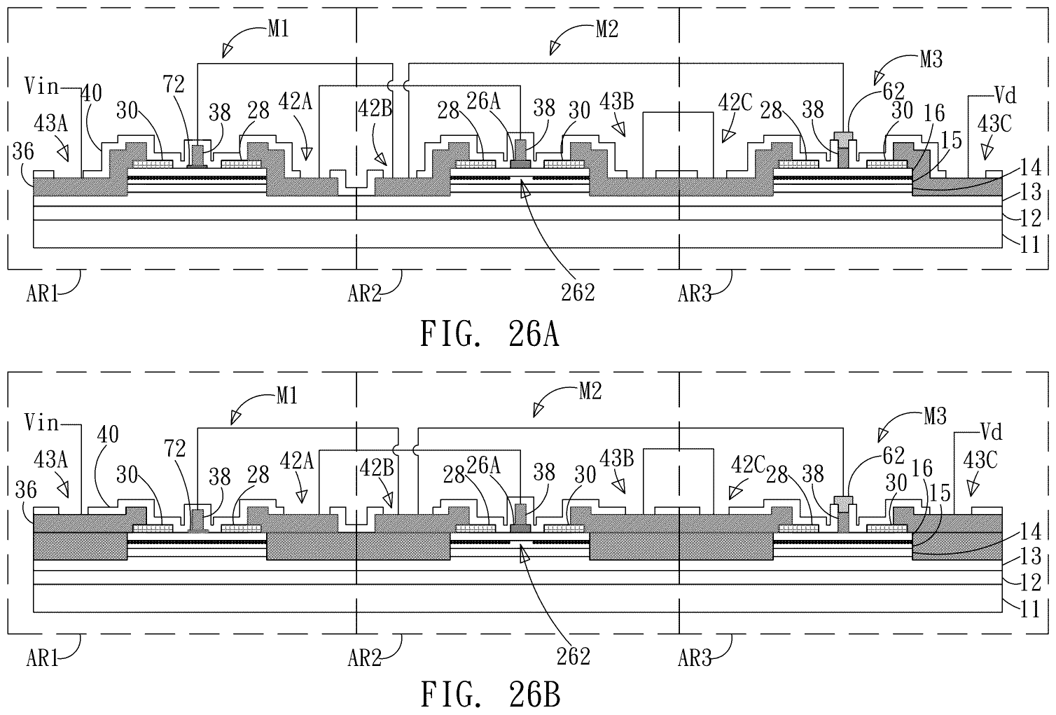

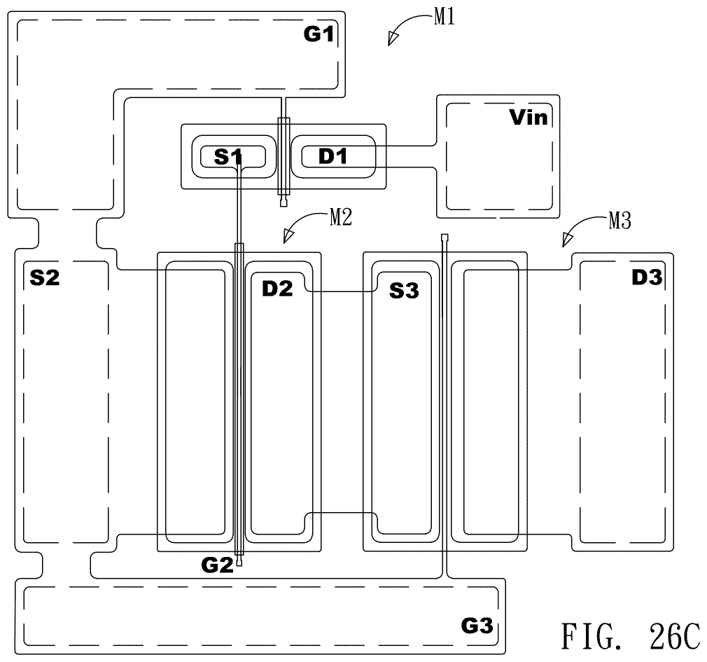

Embodiment 19: As shown in FIG. 26A and FIG. 26B, a hybrid type AlGaN/GaN HEMT device formed by the first D-mode AlGaN/GaN HEMT M1 with the gate dielectric layer 72 as the gate protection device and the p-GaN gate E-mode AlGaN/GaN HEMT M2 cascoding to a second D-mode AlGaN/GaN HEMT M3 without gate dielectric layer.

As shown in FIG. 26A and FIG. 26B, the hybrid type AlGaN/GaN HEMT device according to Embodiment 19 comprises the AlGaN/GaN epitaxy structure designed according to the present invention and is divided into the first region AR1, the second region AR2, and the third region AR3. In the first region AR1, a first D-mode AlGaN/GaN HEMT M1 with the gate dielectric layer 72 is formed. In the second region AR2, a p-GaN etched gate E-mode AlGaN/GaN HEMT M2 is formed. This p-GaN etched gate E-mode AlGaN/GaN HEMT M2 includes a p-GaN etched gate structure 26A. In addition, although the 2DEG is formed in the i-GaN channel layer 15 at the junction between the i-AlₓGaN layer 16 and the i-GaN channel layer 15, due to the existence of the p-GaN etched gate structure 26A, the 2DEG below the p-GaN inverted-trapezoidal gate structure 26 in the i-GaN channel layer 15 will be depleted, giving a depletion region 262 without 2DEG below the p-GaN etched gate structure 26A. In the third region AR3, a second D-mode AlGaN/GaN HEMT M3 without gate dielectric layer is formed. The source S3 and the gate G3 of the second D-mode AlGaN/GaN HEMT M3 cascodes to the p-GaN gate E-mode AlGaN/GaN HEMT M2, as shown in FIG. 15C.

The process steps as shown in FIG. 21A to FIG. 21F according to Embodiment 19 are identical to those according to Embodiment 13. The only difference is that between the steps of FIG. 21C and FIG. 21D, a step is added for fabricating the gate dielectric layer 72 of the first D-mode AlGaN/GaN HEMT M1 with the gate dielectric layer 72 in the first region AR1.

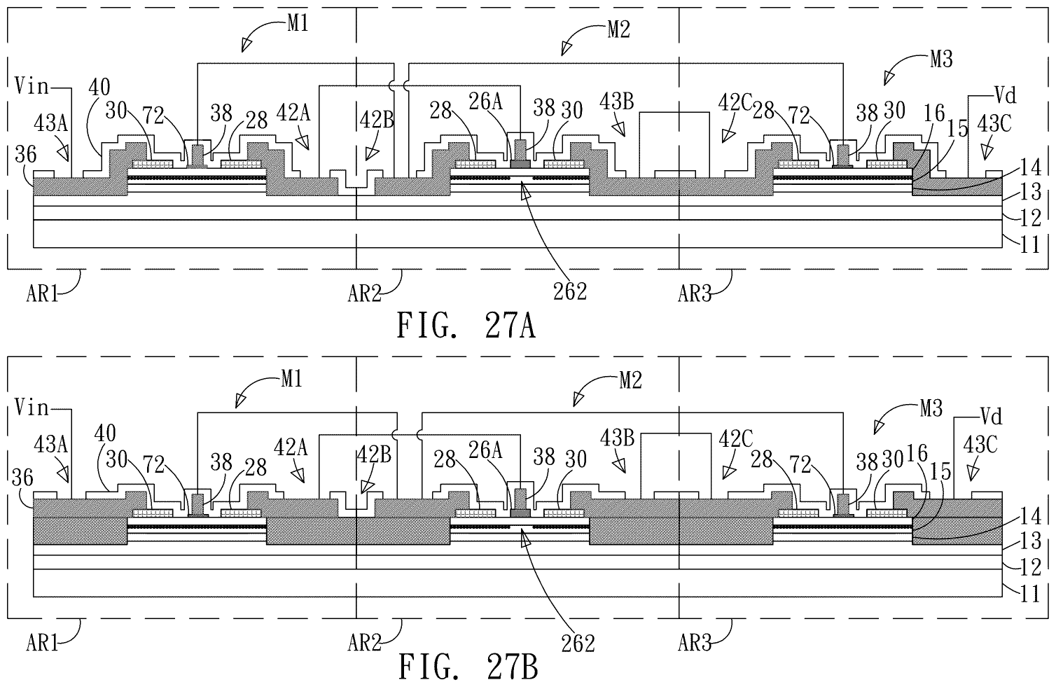

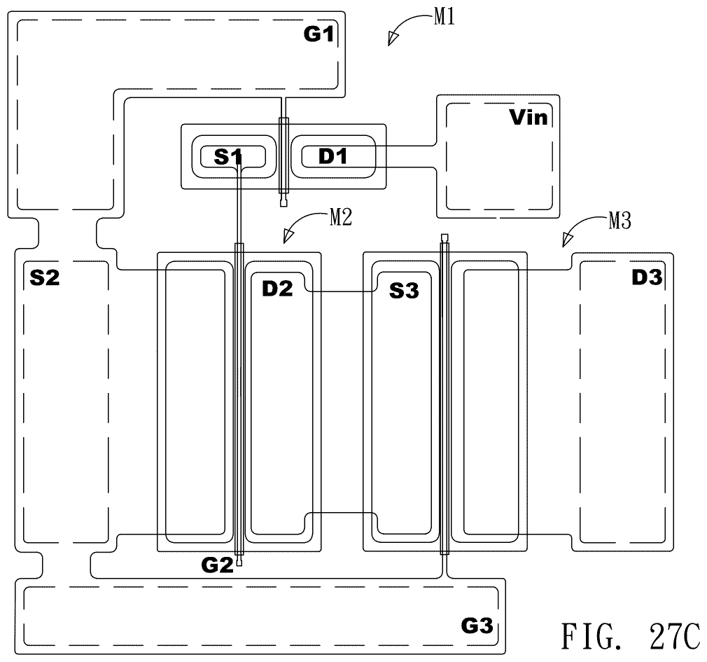

Embodiment 20: As shown in FIG. 27A and FIG. 27B, a hybrid type AlGaN/GaN HEMT device formed by the first D-mode AlGaN/GaN HEMT M1 with the gate dielectric layer 72 as the gate protection device and the p-GaN etched gate E-mode AlGaN/GaN HEMT M2 cascoding to a second D-mode AlGaN/GaN HEMT M3 with the gate dielectric layer 72.

As shown in FIG. 27A and FIG. 27B, the hybrid type AlGaN/GaN HEMT device according to Embodiment 18 comprises the AlGaN/GaN epitaxy structure designed according to the present invention and is divided into the first region AR1, the second region AR2, and the third region AR3. In the first region AR1, a first D-mode AlGaN/GaN HEMT M1 with the gate dielectric layer 72 is formed. In the second region AR2, a p-GaN etched gate E-mode AlGaN/GaN HEMT M2 is formed. This p-GaN etched gate E-mode AlGaN/GaN HEMT M2 includes a p-GaN etched gate structure 26A. In addition, although the 2DEG is formed in the i-GaN channel layer 15 at the junction between the i-AlₓGaN layer 16 and the i-GaN channel layer 15, due to the existence of the p-GaN etched gate structure 26A, the 2DEG below the p-GaN inverted-trapezoidal gate structure 26 in the i-GaN channel layer 15 will be depleted, giving a depletion region 262 without 2DEG below the p-GaN inverted-trapezoidal gate structure 26. In the third region AR3, a second D-mode AlGaN/GaN HEMT M3 with gate dielectric layer is formed and cascoding to the p-GaN gate E-mode AlGaN/GaN HEMT M2.

The process steps as shown in FIG. 21A to FIG. 21F according to Embodiment 20 are identical to those according to Embodiment 9. The only difference is that between the steps of FIG. 21C and FIG. 21D, a step is added for fabricating the gate dielectric layer 72 of the first D-mode AlGaN/GaN HEMT M1 with the gate dielectric layer 72 in the first region AR1 and the gate dielectric layer 72 of the second D-mode AlGaN/GaN HEMT M3 with the gate dielectric layer 72 in the third region AR3.

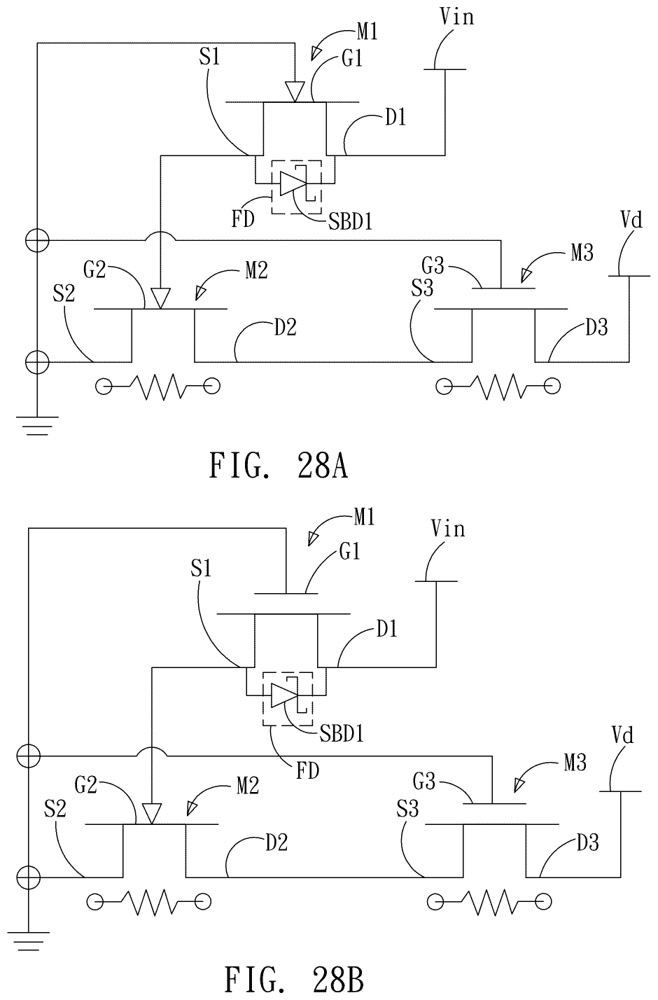

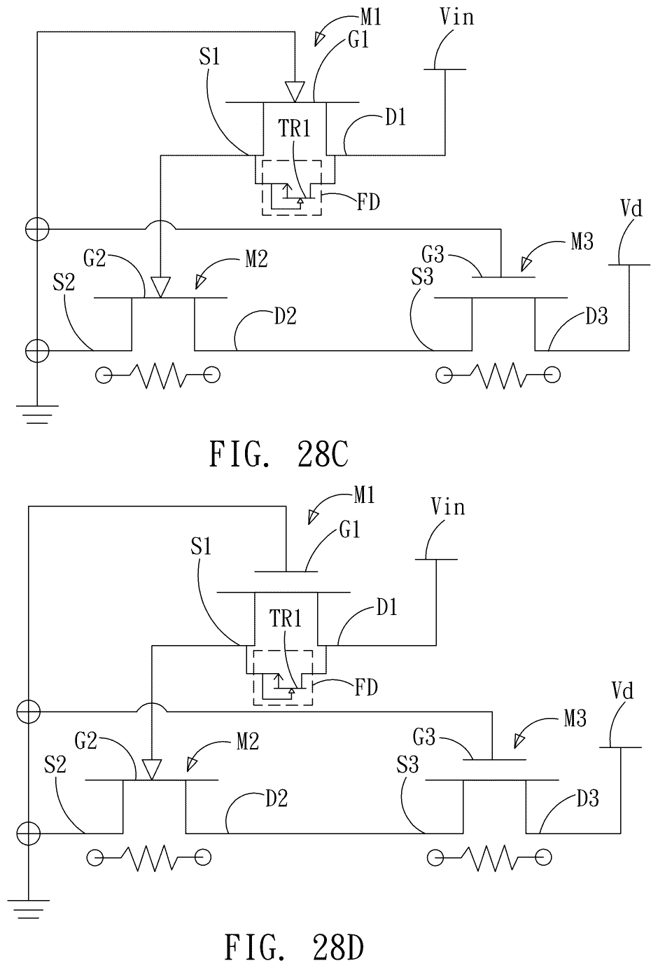

Embodiment 21: As shown in FIG. 28A and FIG. 28B, the discharging device FD of the hybrid type AlGaN/GaN HEMT device according to the present embodiment is the same as the one described in the embodiment of FIG. 12A and FIG. 12B. The difference is that the p-GaN gate E-mode AlGaN/GaN HEMT M2 in FIG. 28A and FIG. 28B further cascodes to the second D-mode AlGaN/GaN HEMT M3. Thereby, when the first D-mode AlGaN/GaN HEMT M1 of the hybrid type AlGaN/GaN HEMT device is in the off state, the source S1 to the drain D1 of the first D-mode AlGaN/GaN HEMT M1 and to the input voltage Vin will form a preferable discharging path. Fast discharging will be performed by the discharging device FD, for example, the Schottky barrier diode SBD1 or the discharging transistor TR1. The first gate G1 of the first D-mode AlGaN/GaN HEMT M1 further includes the gate dielectric layer, as shown in FIG. 25A and FIG. 25B or in FIG. 27A and FIG. 27B. The gate dielectric layer 72 is further disposed below the gate metal 38 of the first D-mode AlGaN/GaN HEMT M1.

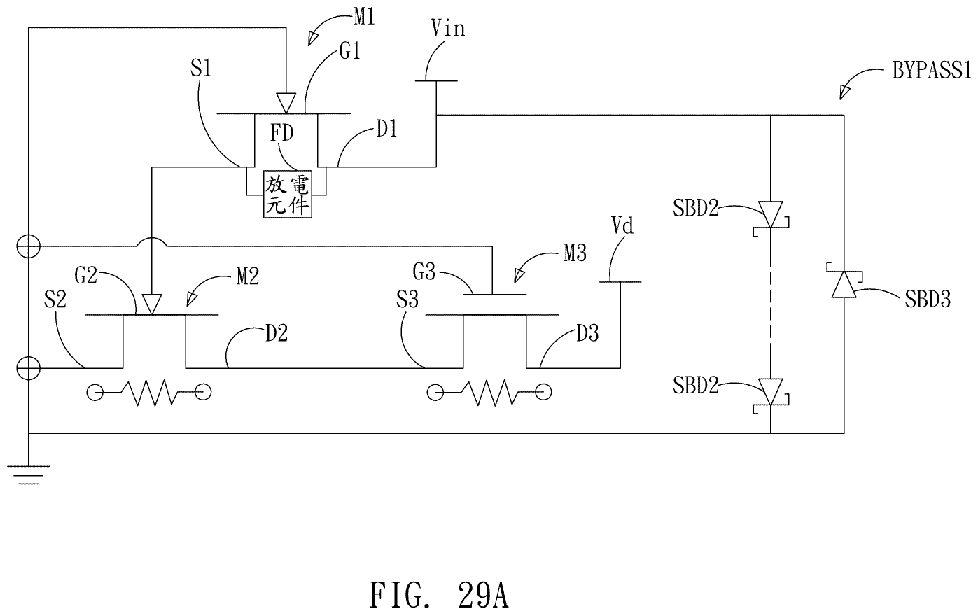

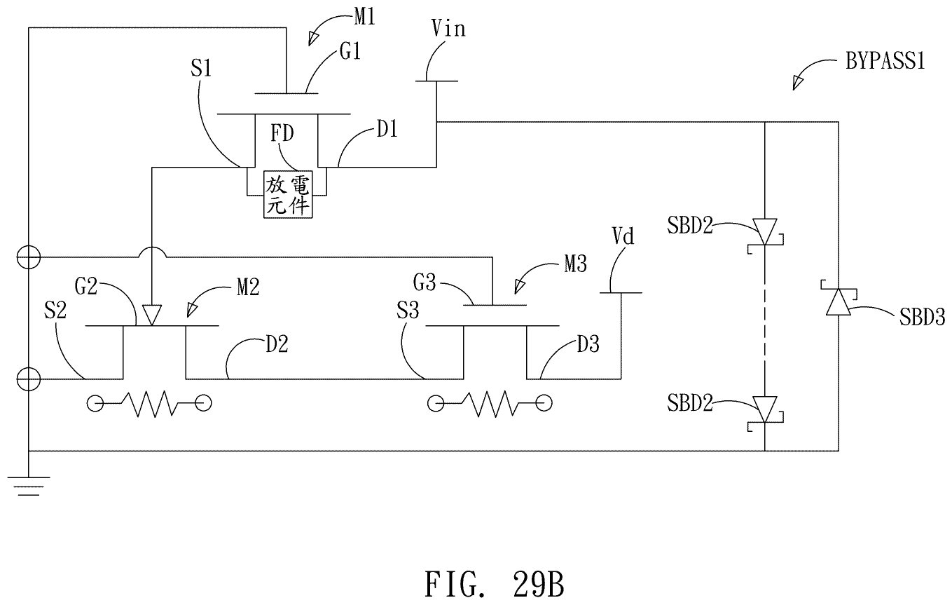

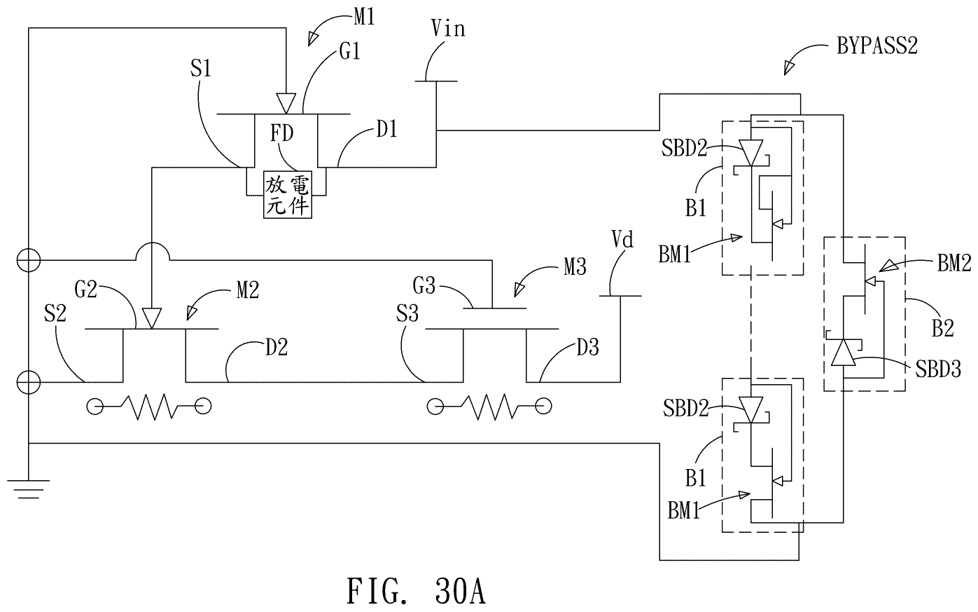

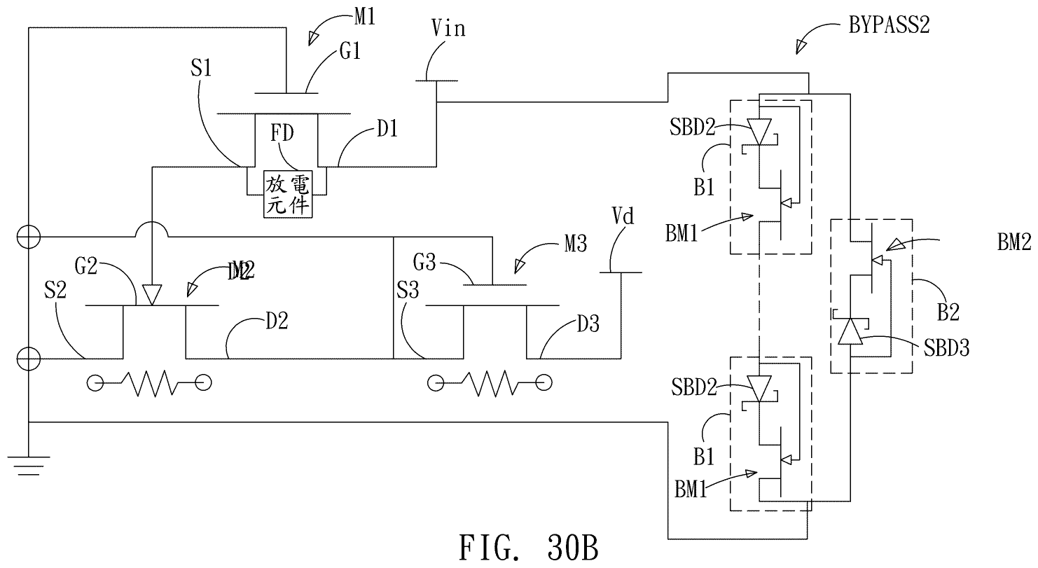

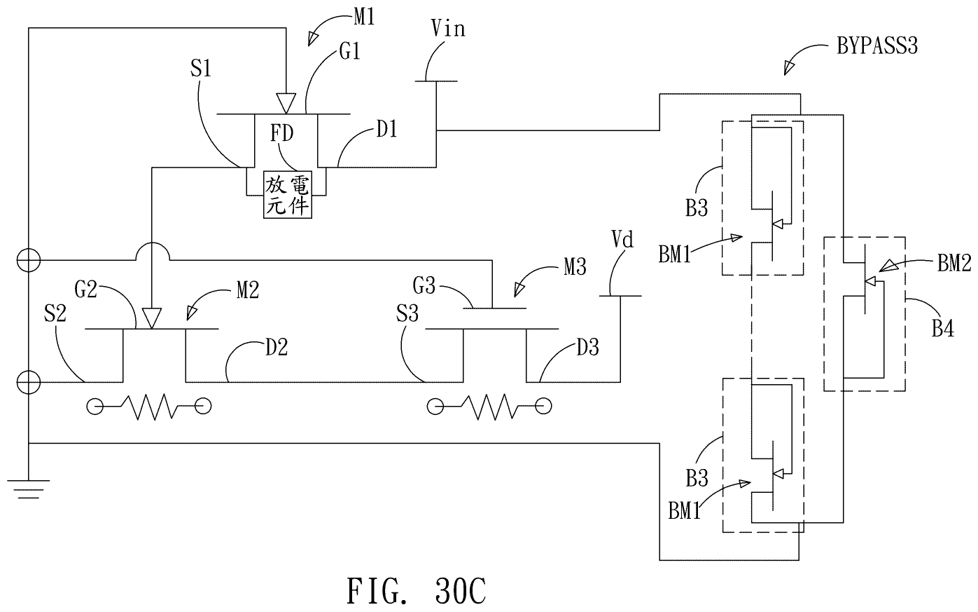

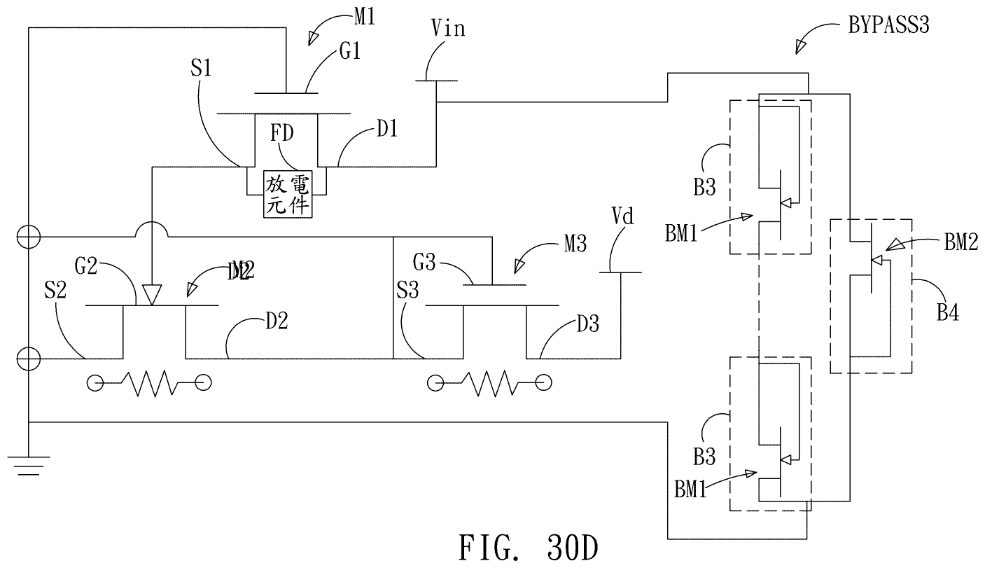

Embodiment 22: As shown in FIG. 29A to FIG. 30B, the hybrid type AlGaN/GaN HEMT according to the present invention further comprises a bypass circuit, such as the first bypass circuit BYPASS1 shown in FIG. 29A and FIG. 29B, the second bypass circuit BYPASS2 shown in FIG. 30A and FIG. 30B, or the third bypass circuit BYPASS3 shown in FIG. 30C and FIG. 30D. The first bypass circuit BYPASS1, the second bypass circuit BYPASS2, and the third bypass circuit BYPASS3 according to the present embodiment are disposed in the same way as the embodiment described in FIG. 13A and 13B. The plurality of first bypass diodes SBD2 and the second bypass diode SBD3 are Schottky barrier diodes, for example, D-mode field-effect transistors. The plurality of first bypass transistors BM1 are coupled to the anode of the corresponding first bypass diode SBD2, respectively; the gate of the second bypass transistor BM2 is coupled to the anode of the second bypass diode SBD3. In addition, the plurality of first bypass transistors BM1 and the second bypass transistor BM2 further may be E-mode transistors, for example, E-mode field-effect transistors. The details will not be described further.

1. A hybrid type AlGaN/GaN HEMT device, comprising:
a silicon substrate structure;
a first D-mode AlGaN/GaN HEMT, disposed on said silicon substrate structure; and
a p-GaN gate E-mode AlGaN/GaN HEMT, disposed on said silicon substrate structure and on one side of said first D-mode AlGaN/GaN HEMT, including a p-GaN gate structure, a 2DEG below said p-GaN gate structure being depleted while said first D-mode AlGaN/GaN HEMT is connected with an input voltage and said p-GaN gate E-mode AlGaN/GaN HEMT is connected with a drain voltage, said p-GaN gate structure coupled to said first D-mode AlGaN/GaN HEMT, and a source of said p-GaN gate E-mode AlGaN/GaN HEMT coupled to a gate of said first D-mode AlGaN/GaN HEMT.

2. The hybrid type AlGaN/GaN HEMT device of claim 1, wherein said p-GaN gate structure is a p-GaN inverted-trapezoidal gate structure or a p-GaN etched gate structure.

3. The hybrid type AlGaN/GaN HEMT device of claim 1, wherein said silicon substrate structure comprising:
a silicon substrate;
a C-doped buffer layer, disposed on said silicon substrate; and
a C-doped intrinsic GaN layer, disposed on said C-doped buffer layer.

4. The hybrid type AlGaN/GaN HEMT device of claim 1, wherein said first D-mode AlGaN/GaN HEMT comprising:
an i-Al_{y}GaN buffer layer, disposed on said silicon substrate structure;
an intrinsic GaN channel layer, disposed on said i-Al_{y}GaN buffer layer; and
an i-AlₓGaN blocking layer, disposed on said intrinsic GaN channel layer, and said 2DEG formed in said i-GaN channel layer at a junction between said i-AlₓGaN layer and said i-GaN channel layer where x=0.1-0.3 and y=0.05-0.75.

5. The hybrid type AlGaN/GaN HEMT device of claim 1, wherein said p-GaN gate E-mode AlGaN/GaN HEMT further comprising:
an i-Al_{y}GaN buffer layer, disposed on said C-doped intrinsic GaN layer. an intrinsic GaN channel layer, disposed on said i-Al_{y}GaN buffer layer, and said 2DEG formed in said intrinsic GaN channel layer; and
an i-AlₓGaN blocking layer, disposed on said intrinsic GaN channel layer, where x=0.1-0.3 and y=0.05-0.75.

6. The hybrid type AlGaN/GaN HEMT device of claim 1, wherein a gate voltage of said p-GaN gate E-mode AlGaN/GaN HEMT in a voltage rising stage is between a threshold voltage Vth and a cutoff voltage Vgs(off) of said first D-mode AlGaN/GaN HEMT.

7. The hybrid type AlGaN/GaN HEMT device of claim 1, wherein an i-Al_{z}GaN grading buffer layer is further disposed between said C-doped intrinsic GaN layer and said i-Al_{y}GaN buffer layer, where z=0.01-0.75.

8. The hybrid type AlGaN/GaN HEMT device of claim 1, wherein a source of said first D-mode AlGaN/GaN HEMT is coupled to said p-GaN gate structure of said p-GaN gate E-mode AlGaN/GaN HEMT.

9. The hybrid type AlGaN/GaN HEMT device of claim 1, wherein said first D-mode AlGaN/GaN HEMT further includes a gate dielectric layer disposed below the gate of said first D-mode AlGaN/GaN HEMT.

10. The hybrid type AlGaN/GaN HEMT device of claim 1, wherein said first D-mode AlGaN/GaN HEMT further includes an AlGaN micro-etched structure disposed below the gate of said first D-mode AlGaN/GaN HEMT.

11. The hybrid type AlGaN/GaN HEMT device of claim 1, further comprising a discharging device coupled to the source and the drain of said first D-mode AlGaN/GaN HEMT.

12. The hybrid type AlGaN/GaN HEMT device of claim 11, wherein said discharging device is a Schottky barrier diode or a discharging transistor; the gate and the source of said discharging transistor are short-circuited; said the source and the drain of said discharging transistor are coupled to said source and said drain of said first D-mode AlGaN/GaN HEMT, respectively.

13. The hybrid type AlGaN/GaN HEMT device of claim 1, further comprising a bypass circuit coupled to the drain of said first D-mode AlGaN/GaN HEMT and the source of the p-GaN gate E-mode AlGaN/GaN HEMT.

14. The hybrid type AlGaN/GaN HEMT device of claim 13, wherein said bypass circuit includes a plurality of first bypass diodes and a second bypass diode coupled in parallel and in opposite polarity; and said plurality of first bypass diodes are coupled in series.

15. The hybrid type AlGaN/GaN HEMT device of claim 13, wherein said bypass circuit includes a plurality of first bypass units and a second bypass unit coupled in parallel and in opposite polarity; said plurality of first bypass units are coupled in series; said plurality of first bypass units include a first bypass diode and a first bypass transistor, respectively; said plurality of second bypass units include a second bypass diode and a second bypass transistor; and said first bypass diode and said second bypass diode are in opposite polarity.

16. The hybrid type AlGaN/GaN HEMT device of claim 1, further comprising a second D-mode AlGaN/GaN HEMT disposed on said silicon substrate structure, and said second D-mode AlGaN/GaN HEMT coupled to said p-GaN gate E-mode AlGaN/GaN HEMT and forming a cascode circuit.

17. The hybrid type AlGaN/GaN HEMT device of claim 16, wherein said second D-mode AlGaN/GaN HEMT comprising:
an i-Al_{y}GaN buffer layer, disposed on said silicon substrate structure;
an intrinsic GaN channel layer, disposed on said i-Al_{y}GaN buffer layer, and said 2DEG formed in said intrinsic GaN channel layer; and
an i-AlₓGaN blocking layer, disposed on said intrinsic GaN channel layer, where x=0.1-0.3 and y=0.05-0.75.

18. The hybrid type AlGaN/GaN HEMT device of claim 16, wherein a gate of said second D-mode AlGaN/GaN HEMT further comprising a gate dielectric layer there below.
